(19) United States
(12) Patent Application Publication
(10) Pub. No.: US 2025/0324846 A1
(43) Pub. Date: Oct. 16, 2025

(54) ORGANIC ELECTROLUMINESCENT DEVICE, DISPLAY DEVICE AND ORGANIC LIGHT-EMITTING INK

(71) Applicant: BEIJING SUMMER SPROUT TECHNOLOGY CO., LTD., Beijing (CN)

(72) Inventors: Chunliang ZHAO, Beijing (CN); Chi Yuen Raymond KWONG, Beijing (CN); Chuanjun XIA, Beijing (CN)

(21) Appl. No.: 19/035,519

(22) Filed: Jan. 23, 2025

(30) Foreign Application Priority Data
Jan. 29, 2024 (CN) 202410121122.X

(51) Int. Cl. H10K 50/11; H10K 50/15; H10K 50/165; H10K 85/10; H10K 85/30; H10K 85/40; H10K 85/60; H10K 101/20

(52) U.S. Cl. CPC H10K 50/11; H10K 50/15; H10K 50/165; H10K 85/111; H10K 85/346; H10K 85/40; H10K 85/622; H10K 85/623; H10K 85/636; H10K 85/654; H10K 85/6572; H10K 85/6574; H10K 85/6576; H10K 85/658; H10K 2101/20

(57) ABSTRACT

Provided are an organic electroluminescent device, a display device and an organic light-emitting ink. The organic electroluminescent device comprises a thermally activated delayed fluorescence compound represented by a structure of Formula 1. The organic electroluminescent device of the present disclosure not only has the advantages of a low cost and a simple process but also can maintain a relatively narrow full width at half maximum and significantly improve device efficiency compared with a normal thermally activated delayed fluorescence (TADF) device without a platinum metal complex as a phosphorescence sensitizer, thereby exhibiting very excellent device performance. Therefore, the organic electroluminescent device has a broad application prospect. Further provided are a display device comprising the organic electroluminescent device, and an organic light-emitting ink.

### CROSS-REFERENCE TO RELATED APPLICATION(S)

This application claims priority to Chinese Patent Application No. 202410121122.X filed on Jan. 29, 2024, the disclosure of which is incorporated herein by reference in its entirety.

### TECHNICAL FIELD

The present disclosure relates to organic electronic devices, for example, organic electroluminescent devices. More particularly, the present disclosure relates to an organic electroluminescent device whose light-emitting layer is prepared through a solution method, a display device comprising the organic electroluminescent device, and an organic light-emitting ink.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation (VTE method). Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

During the preparation of an organic electroluminescent device, when an organic functional layer has such a multiplex system comprising multiple compounds, the preparation through an evaporation method needs multiple evaporation sources (for example, a light-emitting layer comprises two host materials, a phosphorescence sensitizer and a thermally activated delayed fluorescence material, and four evaporation sources are needed), resulting in a significantly increased industrialized cost and a complex process. Moreover, when the organic functional layer is prepared through the evaporation method, an evaporation temperature of the evaporated compound cannot be too high, otherwise energy consumption is significantly increased or the organic functional layer cannot be prepared through the evaporation method, thereby limiting a range of selectable compounds. According to the solution method, the multiple compounds only need to be dissolved or dispersed in a solvent to prepare an organic ink that can be spin-coated or printed for the functional layer. Therefore, the solution method has the advantages of a low cost and a simple process. Preparing an organic functional layer of an organic electroluminescent device through a solution method is disclosed in the related art. For example, a hole injection layer, a hole transport layer and a light-emitting layer can be prepared. However, what is disclosed in the related art is that some materials having particular structures are used in the organic functional layer.

CN116023402A discloses a boron-nitrogen compound with General Formula I of

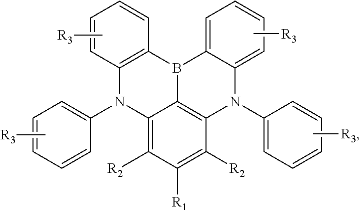

wherein R₂ is selected from a weak-electron-donating or electron-withdrawing large-steric-hindrance linear group and is specifically a substituent such as

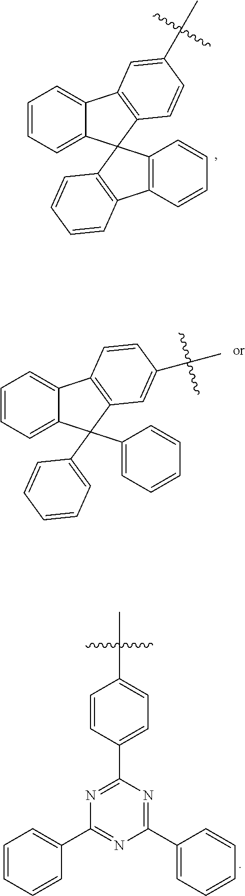 [SMILES: *c1ccc2c(c1)-c1ccccc1C21c2ccccc2-c2ccccc21 ; *c1ccc2c(c1)C(c1ccccc1)(c1ccccc1)c1ccccc1-2 ; *c1ccc(-c2nc(-c3ccccc3)nc(-c3ccccc3)n2)cc1]

It can be seen that the application discloses the boron-nitrogen compound having the particular R₂ large-steric-hindrance linear group and has neither disclosed nor taught other boron-nitrogen compounds and applications of the boron-nitrogen compounds in the organic electroluminescent devices. In addition, in a device example, a hole injection layer, a hole transport layer and a light-emitting layer of an organic electroluminescent device are prepared through a solution method in the application. A particular poly(3,4-ethylenedioxythiophene) polystyrene sulfonate (PEDOT/PSS) combination is used in the hole injection layer, a particular poly-HTL material is used in the hole transport layer, and the light-emitting layer comprises dual host materials, a phosphorescence sensitizer and the particular compound represented by Formula I. However, the application has neither disclosed nor taught that a device uses other boron-nitrogen compounds, the dual host materials and the phosphorescence sensitizer as a light-emitting layer when a hole injection layer or a hole transport layer comprises a polymer.

CN115440903A discloses an organic light-emitting material composition including a host material, a phosphorescent material and a thermally activated delayed fluorescence material and specifically discloses that the phosphorescent material is an iridium metal complex such as

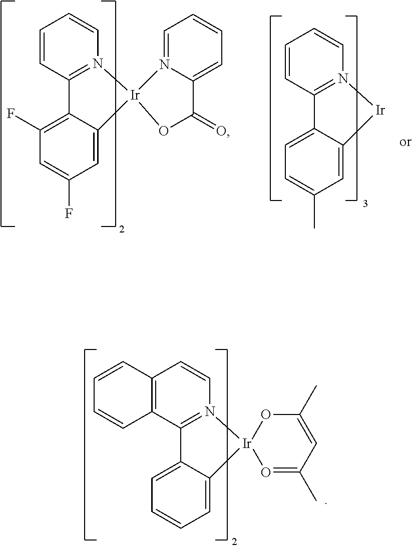

The application further discloses an organic light-emitting ink comprising the organic light-emitting material composition and an organic electroluminescent device prepared by using the organic light-emitting ink. In a device example, a hole injection layer, a hole transport layer and a light-emitting layer of the organic electroluminescent device are prepared through a solution method in the application. A particular PEDOT/PSS combination is used in the hole injection layer, a particular polyvinylcarbazole (PVK) material is used in the hole transport layer, and the light-emitting layer comprises dual host materials, the thermally activated delayed fluorescence material and the iridium metal complex as a phosphorescence sensitizer. However, the application has neither disclosed nor taught that a device uses other phosphorescence sensitizers, the dual host materials and the thermally activated delayed fluorescence material as a light-emitting layer when a hole injection layer or a hole transport layer comprises a polymer.

At present, in a sensitized delayed fluorescence device prepared through the solution method, combinations between organic functional layers such as a combination between a hole injection layer and/or a hole transport layer and a light-emitting layer and combinations between organic materials used in a light-emitting layer needs continuous research and development, and device performance such as device efficiency still needs to be improved.

### SUMMARY

The present disclosure aims to provide a new organic electroluminescent device to solve at least part of the above problems. This new organic electroluminescent device comprises an anode, a cathode, a light-emitting layer disposed between the anode and the cathode and a first organic layer disposed between the anode and the light-emitting layer, wherein the first organic layer comprises a polymer, and the light-emitting layer is prepared through a solution method and comprises a first host compound, a second host compound, a platinum metal complex and a thermally activated delayed fluorescence compound represented by a structure of Formula 1. The light-emitting layer of the organic electroluminescent device of the present disclosure is prepared through the solution method. Therefore, the organic functional layer between the anode and the light-emitting layer, for example, the first organic layer, needs to comprise the polymer and cannot only comprise small molecules, otherwise an interface/film of the organic functional layer between the anode and the light-emitting layer may be destroyed in a process of preparing the device through the solution method. The organic electroluminescent device of the present disclosure not only has the advantages of a low cost and a simple process brought through the solution method but also can maintain a relatively narrow full width at half maximum and significantly improve device efficiency compared with a normal TADF device without a platinum metal complex as a phosphorescence sensitizer, thereby exhibiting very excellent device performance. Therefore, the organic electroluminescent device has a broad application prospect.

According to an embodiment of the present disclosure, disclosed is an organic electroluminescent device comprising:
an anode,
a cathode,
a light-emitting layer disposed between the anode and the cathode and a first organic layer disposed between the anode and the light-emitting layer;
wherein the first organic layer comprises a polymer;
the light-emitting layer is prepared through a solution method and comprises a first host compound, a second host compound, a platinum metal complex and a thermally activated delayed fluorescence compound;
the thermally activated delayed fluorescence compound has a structure represented by Formula 1:

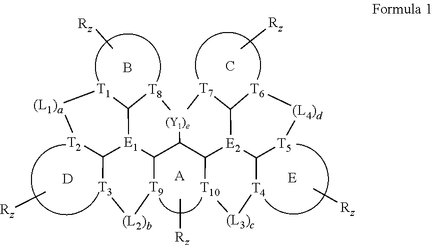

wherein,
the ring A, the ring B, the ring C, the ring D and the ring E are each independently selected from an unsaturated carbocyclic ring having 5 to 30 carbon atoms or an unsaturated heterocyclic ring having 3 to 30 carbon atoms;
Y₁, E₁ and E₂ are each independently selected from B, N, P, P═O, P═S, As, As═O, As═S, SiR′ or GeR′;
T₁ to T₈ are each independently selected from C, CR_{z} or N;
T₉ and T₁₀ are each independently selected from C, CR_{z}, CRₜ or N;
L₁, L₂, L₃ and L₄ are, at each occurrence identically or differently, selected from a single bond, O, S, Se, BRᵥ or NRᵥ;
a, b, c, d and e are each independently selected from 0 or 1;
when e is 1, b is 0 and c is 0, T₉ and T₁₀ are each independently selected from CRₜ or N;
R_{z} represents, at each occurrence identically or differently, mono-substitution, multiple substitutions or non-substitution;
Rₜ is, at each occurrence identically or differently, selected from a small-steric-hindrance group;
Rᵥ, R_{z} and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″ and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₜ, Rᵥ, R_{z}, R′ and R″ can be optionally joined to form a ring.

According to another embodiment of the present disclosure, further disclosed is a display device comprising the organic electroluminescent device described above.

According to another embodiment of the present disclosure, further disclosed is an organic light-emitting ink comprising a solvent, a first host compound, a second host compound, a platinum metal complex and a thermally activated delayed fluorescence compound;
wherein the thermally activated delayed fluorescence compound has a structure represented by Formula 1:

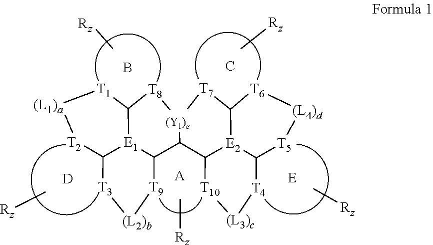

wherein,
the ring A, the ring B, the ring C, the ring D and the ring E are each independently selected from an unsaturated carbocyclic ring having 5 to 30 carbon atoms or an unsaturated heterocyclic ring having 3 to 30 carbon atoms;
Y₁, E₁ and E₂ are each independently selected from B, N, P, P═O, P═S, As, As═O, As═S, SiR′ or GeR′;
T₁ to T₈ are each independently selected from C, CR_{z} or N;
T₉ and T₁₀ are each independently selected from C, CR_{z}, CRₜ or N;
L₁, L₂, L₃ and L₄ are, at each occurrence identically or differently, selected from a single bond, O, S, Se, BRᵥ or NRᵥ;
a, b, c, d and e are each independently selected from 0 or 1;
when e is 1, b is 0 and c is 0, T₉ and T₁₀ are each independently selected from CRₜ or N;
R_{z} represents, at each occurrence identically or differently, mono-substitution, multiple substitutions or non-substitution;
Rₜ is, at each occurrence identically or differently, selected from a small-steric-hindrance group;
Rᵥ, R_{z} and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″ and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₜ, Rᵥ, R_{z}, R′ and R″ can be optionally joined to form a ring.

The present disclosure aims to provide the new organic electroluminescent device. This new organic electroluminescent device comprises the anode, the cathode, the light-emitting layer disposed between the anode and the cathode and the first organic layer disposed between the anode and the light-emitting layer, wherein the first organic layer comprises the polymer, and the light-emitting layer is prepared through the solution method and comprises the first host compound, the second host compound, the platinum metal complex and the thermally activated delayed fluorescence compound represented by the structure of Formula 1. The light-emitting layer of the organic electroluminescent device of the present disclosure is prepared through the solution method. Therefore, the organic functional layer between the anode and the light-emitting layer, for example, the first organic layer, needs to comprise the polymer and cannot only comprise small molecules, otherwise the interface/film of the organic functional layer between the anode and the light-emitting layer may be destroyed in the process of preparing the device through the solution method. The organic electroluminescent device of the present disclosure not only has the advantages of the low cost and the simple process brought through the solution method but also can maintain the relatively narrow full width at half maximum and significantly improve the device efficiency compared with the normal TADF device without the platinum metal complex as the phosphorescence sensitizer, thereby exhibiting very excellent device performance. Therefore, the organic electroluminescent device has the broad application prospect.

### BRIEF DESCRIPTION OF DRAWINGS

FIG. 1 is a schematic diagram of an organic light-emitting apparatus that may include an organic electroluminescent device disclosed herein.

FIG. 2 is a schematic diagram of another organic light-emitting apparatus that may include an organic electroluminescent device disclosed herein.

### DETAILED DESCRIPTION

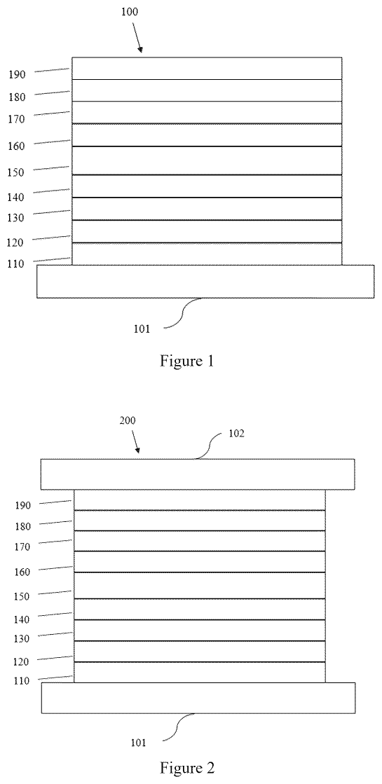

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

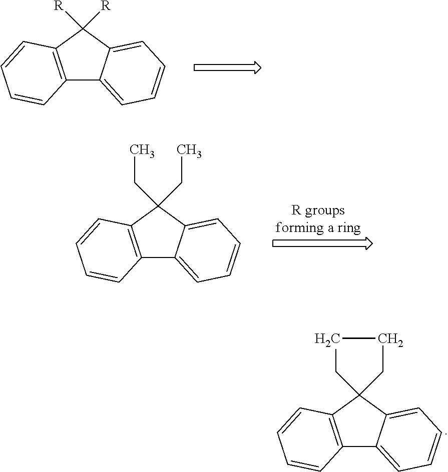

The expression that adjacent substituents can be optionally joined to form a ring is also intended to mean that two substituents bonded to carbon atoms which are directly bonded to each other are joined to each other via a chemical bond to form a ring, which can be exemplified by the following formula:

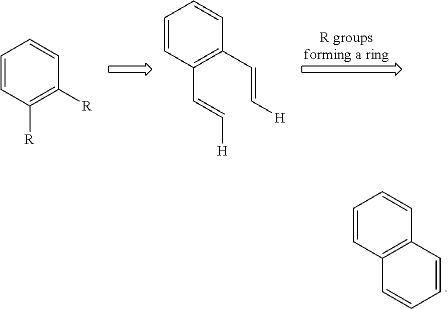

The expression that adjacent substituents can be optionally joined to form a ring is also intended to mean that two substituents bonded to further distant carbon atoms are joined to each other via a chemical bond to form a ring, which can be exemplified by the following formula:

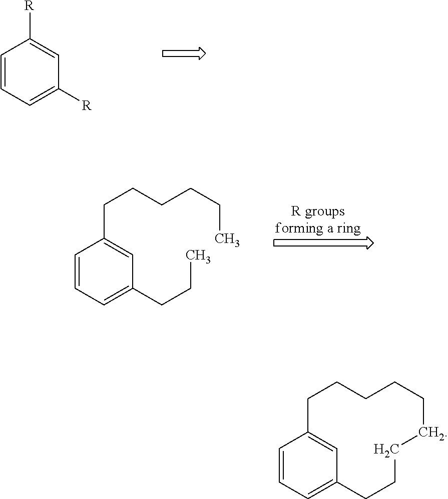

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

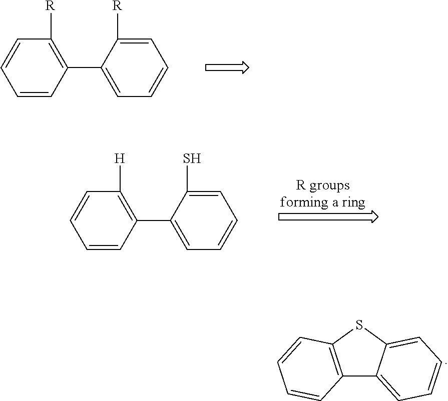

According to an embodiment of the present disclosure, disclosed is an organic electroluminescent device comprising:
an anode,
a cathode,
a light-emitting layer disposed between the anode and the cathode and a first organic layer disposed between the anode and the light-emitting layer;
wherein the first organic layer comprises a polymer;
the light-emitting layer is prepared through a solution method and comprises a first host compound, a second host compound, a platinum metal complex and a thermally activated delayed fluorescence compound;
the thermally activated delayed fluorescence compound has a structure represented by Formula 1:

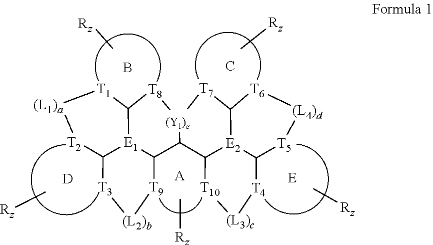

wherein,
the ring A, the ring B, the ring C, the ring D and the ring E are each independently selected from an unsaturated carbocyclic ring having 5 to 30 carbon atoms or an unsaturated heterocyclic ring having 3 to 30 carbon atoms;
Y₁, E₁ and E₂ are each independently selected from B, N, P, P═O, P═S, As, As═O, As═S, SiR′ or GeR′;
T₁ to T₈ are each independently selected from C, CR_{z} or N;
T₉ and T₁₀ are each independently selected from C, CR_{z}, CRₜ or N;
L₁, L₂, L₃ and L₄ are, at each occurrence identically or differently, selected from a single bond, O, S, Se, BRᵥ or NRᵥ;
a, b, c, d and e are each independently selected from 0 or 1;
when e is 1, b is 0 and c is 0, T₉ and T₁₀ are each independently selected from CRₜ or N;
R_{z} represents, at each occurrence identically or differently, mono-substitution, multiple substitutions or non-substitution;
Rₜ is, at each occurrence identically or differently, selected from a small-steric-hindrance group;
Rᵥ, R_{z} and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″ and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₜ, Rᵥ, R_{z}, R′ and R″ can be optionally joined to form a ring.

In this embodiment, the expression that “a, b, c, d and e are each independently selected from 0 or 1” is intended to mean that L₁, L₂, L₃, L₄ and Y₁ corresponding to a, b, c, d and e are present or absent. For example, when a is 1, L₁ is present, and T₁ is joined to T₂ via L₁; when a is 0, L₁ is absent, and T₁ is not joined to T₂; when b, c and d are each independently selected from 0 or 1, the situation is similar to that of a. When e is 1, Y₁ is present, and the ring A is joined to T& on the ring B and T₇ on the ring C via Y₁; when e is 0, Y₁ is absent, and the ring A, the ring B and the ring C are not joined to each other.

Herein, the expression that “adjacent substituents Rₜ, Rᵥ, R_{z}, R′ and R” can be optionally joined to form a ring″ is intended to mean that any one or more of groups of adjacent substituents, such as two substituents R_{z}, two substituents R″, substituents R_{z} and Rᵥ, substituents R_{z} and R′, and substituents R_{z} and Rₜ, can be joined to form a ring. Obviously, it is also possible that none of these groups of adjacent substituents are joined to form a ring.

Herein, the “unsaturated carbocyclic ring” comprises an aromatic unsaturated carbocyclic ring (an aromatic ring) and a non-aromatic unsaturated carbocyclic ring; and the “unsaturated heterocyclic ring” comprises an aromatic unsaturated heterocyclic ring (a heteroaromatic ring) and a non-aromatic unsaturated heterocyclic ring.

Herein, the “small-steric-hindrance group” is intended to represent a substituent having less than or equal to 6 carbon atoms and is selected from the group consisting of: hydrogen, deuterium, halogen, unsubstituted alkyl having 1 to 6 carbon atoms, unsubstituted cycloalkyl having 3 to 6 ring carbon atoms, unsubstituted heteroalkyl having 1 to 6 carbon atoms, an unsubstituted heterocyclic group having 3 to 6 ring atoms, unsubstituted alkoxy having 1 to 6 carbon atoms, unsubstituted alkenyl having 2 to 6 carbon atoms, phenyl, pyridyl, pyrimidinyl, triazinyl, unsubstituted alkylsilyl having 3 to 6 carbon atoms, unsubstituted alkylgermanyl having 3 to 6 carbon atoms, unsubstituted amino having 0 to 6 carbon atoms, an acyl group, a carbonyl group, a carboxylic acid group, an ester group, a cyano group, an isocyano group, a hydroxyl group, a sulfanyl group, a sulfinyl group, a sulfonyl group and a phosphino group.

According to an embodiment of the present disclosure, the ring A, the ring B, the ring C, the ring D and the ring E are each independently selected from a five-membered unsaturated carbocyclic ring, an aromatic ring having 6 to 30 carbon atoms or a heteroaromatic ring having 3 to 30 carbon atoms.

According to an embodiment of the present disclosure, the ring A, the ring B, the ring C, the ring D and the ring E are each independently selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring or a silole ring.

According to an embodiment of the present disclosure, the ring A, the ring B, the ring C, the ring D and the ring E are selected from a benzene ring.

According to an embodiment of the present disclosure, in Formula 1, e is 1, Y₁ is independently selected from B, P═O or P═S, and E₁ and E₂ are each independently selected from N or P.

According to an embodiment of the present disclosure, in Formula 1, e is 1, Y₁ is selected from B, and E₁ and E₂ are selected from N.

According to an embodiment of the present disclosure, in Formula 1, e is 1, a is 0, b is 0, c is 0, and d is 0.

According to an embodiment of the present disclosure, in Formula 1, e is 1, a is 1, b is 0, c is 0, and d is 1.

According to an embodiment of the present disclosure, in Formula 1, e is 1, a is 0, b is 1, c is 0, and d is 1.

According to an embodiment of the present disclosure, in Formula 1, e is 0, and E₁ and E₂ are each independently selected from B or N.

According to an embodiment of the present disclosure, in Formula 1, e is 0, and E₁ and E₂ are selected from B.

According to an embodiment of the present disclosure, in Formula 1, e is 0, a is 1, b is 1, c is 1, and d is 1.

According to an embodiment of the present disclosure, the thermally activated delayed fluorescence compound has a structure represented by Formula 1-1 or Formula 1-2:

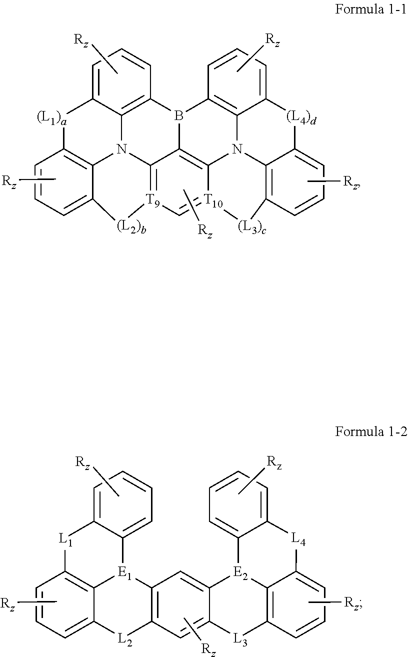

wherein,
a, b, c and d are each independently selected from 0 or 1;
T₉ and T₁₀ are each independently selected from C, CR_{z} or CRₜ;
when b is 0 and c is 0, T₉ and T₁₀ are each independently selected from CRₜ;
E₁ and E₂ are each independently selected from B or N;
L₁, L₂, L₃ and L₄ are, at each occurrence identically or differently, selected from a single bond, O, S, BRᵥ or NRᵥ;
R_{z} represents, at each occurrence identically or differently, mono-substitution, multiple substitutions or non-substitution;
Rₜ is, at each occurrence identically or differently, selected from a small-steric-hindrance group;
Rᵥ and R_{z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″ and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₜ, Rᵥ, R_{z} and R″ can be optionally joined to form a ring.

In this embodiment, the expression that “adjacent substituents Rₜ, Rᵥ, R_{z} and R″ can be optionally joined to form a ring” is intended to mean that on the same ring, two adjacent substituents R_{z} can be joined to form an unsaturated carbocyclic ring or an unsaturated heterocyclic ring comprising one or more of O, S, Se, Si, Ge and P, two substituents R″ can be joined to form a ring, substituents R_{z} and Rᵥ can be joined to form a ring and substituents R_{z} and Rₜ can be joined to form a ring. Obviously, it is also possible that on the same ring, two adjacent substituents R_{z} may not be joined to form a ring, two substituents R″ may not be joined to form a ring, substituents R_{z} and Rᵥ may not be joined to form a ring and substituents R_{z} and Rₜ may not be joined to form a ring.

According to an embodiment of the present disclosure, in Formula 1-1, a is 0, b is 0, c is 0, and d is 0.

According to an embodiment of the present disclosure, in Formula 1-1, a+b+c+d is greater than or equal to 1.

According to an embodiment of the present disclosure, in Formula 1-1, a is 1, b is 0, c is 0, and d is 1.

According to an embodiment of the present disclosure, in Formula 1-1, a is 0, b is 1, c is 0, and d is 1.

According to an embodiment of the present disclosure, in Formula 1, Formula 1-1 and Formula 1-2, L₁, L₂, L₃ and L₄ are, at each occurrence identically or differently, selected from a single bond, O, BRᵥ or NRᵥ, and Rᵥ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms or substituted and unsubstituted arylgermanyl having 6 to 20 carbon atoms.

According to an embodiment of the present disclosure, in Formula 1-1, L₁, L₂, L₃ and L₄ are, at each occurrence identically or differently, selected from a single bond.

According to an embodiment of the present disclosure, in Formula 1-2, L₁, L₂, L₃ and L₄ are, at each occurrence identically or differently, selected from O or NRᵥ, and Rᵥ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms and substituted or unsubstituted heteroaryl having 3 to 30 carbon atoms.

According to an embodiment of the present disclosure, in Formula 1-2, E₁ and E₂ are each independently selected from B.

According to an embodiment of the present disclosure, the Ry is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group and combinations thereof.

According to an embodiment of the present disclosure, the R_{z} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, a cyano group and combinations thereof.

According to an embodiment of the present disclosure, the thermally activated delayed fluorescence compound has a plurality of R_{z}, and at least one (for example, one, two, three or four) of the plurality of R_{z} is selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms and combinations thereof.

According to an embodiment of the present disclosure, the substituent R_{z} on the ring A is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted aryl having 6 to 30 carbon atoms, substituted or unsubstituted heteroaryl having 5 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group and combinations thereof.

According to an embodiment of the present disclosure, the substituent R_{z} on the ring A is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 5 to 30 carbon atoms, substituted or unsubstituted amino having 0 to 20 carbon atoms and combinations thereof.

According to an embodiment of the present disclosure, the Rₜ is, at each occurrence identically or differently, selected from the group consisting of: hydrogen, deuterium, halogen, unsubstituted alkyl having 1 to 6 carbon atoms, unsubstituted cycloalkyl having 3 to 6 ring carbon atoms, unsubstituted heteroalkyl having 1 to 6 carbon atoms, an unsubstituted heterocyclic group having 3 to 6 ring atoms, unsubstituted alkylsilyl having 3 to 6 carbon atoms, unsubstituted amino having 0 to 6 carbon atoms, phenyl and combinations thereof.

According to an embodiment of the present disclosure, the Rₜ is, at each occurrence identically or differently, selected from the group consisting of: hydrogen, deuterium, halogen, unsubstituted alkyl having 1 to 6 carbon atoms, unsubstituted cycloalkyl having 3 to 6 ring carbon atoms, unsubstituted amino having 0 to 6 carbon atoms and combinations thereof.

According to an embodiment of the present disclosure, the Rₜ is, at each occurrence identically or differently, selected from hydrogen, deuterium or halogen.

According to an embodiment of the present disclosure, the thermally activated delayed fluorescence compound is selected from the group consisting of Compound BD1 to Compound BD53, wherein the specific structures of Compound BD1 to Compound BD53 are referred to claim 9.

According to an embodiment of the present disclosure, hydrogens in Compound BD1 to Compound BD53 can be partially or fully substituted with deuterium.

According to an embodiment of the present disclosure, a maximum emission wavelength λ_{max-PL} in a photoluminescence spectrum of the thermally activated delayed fluorescence compound is 450-500 nm.

According to an embodiment of the present disclosure, the maximum emission wavelength λ_{max-PL} in the photoluminescence spectrum of the thermally activated delayed fluorescence compound is 450-470 nm.

According to an embodiment of the present disclosure, the maximum emission wavelength λ_{max-PL} in the photoluminescence spectrum of the thermally activated delayed fluorescence compound is 455-470 nm.

According to an embodiment of the present disclosure, a full width at half maximum FWHM-_{PL} in the photoluminescence spectrum of the thermally activated delayed fluorescence compound is less than or equal to 45 nm.

According to an embodiment of the present disclosure, the full width at half maximum FWHM-_{PL} in the photoluminescence spectrum of the thermally activated delayed fluorescence compound is less than or equal to 35 nm.

According to an embodiment of the present disclosure, the full width at half maximum FWHM-_{PL} in the photoluminescence spectrum of the thermally activated delayed fluorescence compound is less than or equal to 25 nm.

According to an embodiment of the present disclosure, the full width at half maximum FWHM-_{PL} in the photoluminescence spectrum of the thermally activated delayed fluorescence compound is less than or equal to 20 nm.

In the present disclosure, a method for testing the maximum emission wavelength λ_{max-PL} and the full width at half maximum FWHM-PL in the photoluminescence spectrum is described below.

The photoluminescence (PL) spectrum data of a compound to be tested were measured using a fluorescence spectrophotometer LENGGUANG F98 produced by SHANGHAI LENGGUANG TECHNOLOGY CO., LTD. The compound to be tested was dissolved in a toluene solvent to prepare a solution with a concentration of 1×10⁻⁶ mol/L, nitrogen was introduced into the prepared solution to be tested to remove oxygen for 5 min, the solution to be tested was placed in a quartz sample tube and was excited by light with a wavelength of 350 nm at room temperature (298 K), and an emission spectrum of the solution to be tested was measured. The emission spectrum had the maximum emission wavelength λ_{max-PL} and the full width at half maximum FWHM-_{PL} (that is, a peak width at a position of half a height of a maximum emission peak, that is, a distance between two points where a straight line passing through a midpoint of the height of the peak and being parallel to a horizontal axis intersects two sides of the peak).

As an example, maximum emission wavelength λ_{max-PL} and full width at half maximum FWHM-_{PL} data in photoluminescence spectra of the following thermally activated delayed fluorescence compounds were measured through the above method. The specific results are shown in Table 1:

TABLE 1
Maximum emission wavelengths and full widths at half
maximum in photoluminescence spectra of compounds

| Compound No. | λ_{max-PL} (nm) | FWHM-_{PL} (nm) |
|---|---|---|
| BD2 | 459 | 25.3 |
| BD44 | 466 | 18.7. |

According to an embodiment of the present disclosure, the platinum metal complex has a structure represented by Formula 2:

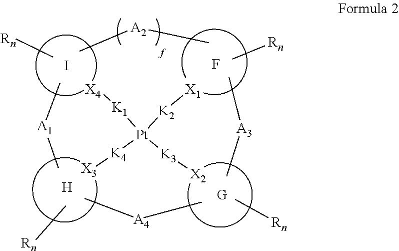

wherein in Formula 2,
the ring F, the ring G, the ring H and the ring I are each independently selected from an unsaturated carbocyclic ring having 5 to 30 carbon atoms, an unsaturated heterocyclic ring having 1 to 30 carbon atoms or a combination thereof;
f is selected from 0 or 1;
A₁ to A₄ are, at each occurrence identically or differently, selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof, wherein y is, at each occurrence identically or differently, selected from 1, 2, 3, 4 or 5;
X₁ to X₄ are each independently selected from C or N;
K₁ to K₄ are each independently selected from a single bond, O or S;
Rₙ represents, at each occurrence identically or differently, mono-substitution, multiple substitutions or non-substitution;
R_{q} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{q} and Rₙ can be optionally joined to form a ring.

In this embodiment, the expression that “adjacent substituents R_{q} and Rₙ can be optionally joined to form a ring” is intended to mean that any one or more of groups of adjacent substituents, such as two substituents R_{q}, two substituents Rₙ, and substituents R_{q} and Rₙ, can be joined to form a ring. Obviously, it is also possible that none of these groups of adjacent substituents are joined to form a ring.

According to an embodiment of the present disclosure, the platinum metal complex has a structure represented by Formula 2-1:

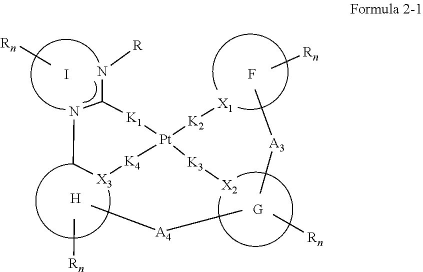

wherein in Formula 2-1,
the ring F, the ring G and the ring H are each independently selected from an unsaturated carbocyclic ring having 5 to 30 carbon atoms, an unsaturated heterocyclic ring having 3 to 30 carbon atoms or a combination thereof, and the ring I is selected from an unsaturated heterocyclic ring having 1 to 30 carbon atoms;
A₃ and A₄ are each independently selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof, wherein y is, at each occurrence identically or differently, selected from 1, 2, 3, 4 or 5;
K₁ to K₄ are each independently selected from a single bond, O or S;
X₁ to X₃ are each independently selected from C or N;
Rₙ represents, at each occurrence identically or differently, mono-substitution, multiple substitutions or non-substitution;
R, R_{q} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R, R_{q} and Rₙ can be optionally joined to form a ring.

In this embodiment, the expression that “adjacent substituents R, R_{q} and Rₙ can be optionally joined to form a ring” is intended to mean that any one or more of groups of adjacent substituents, such as two substituents R_{q}, two substituents Rₙ, substituents R_{q} and Rₙ, and substituents R and Rₙ, can be joined to form a ring. Obviously, it is also possible that none of these groups of adjacent substituents are joined to form a ring.

According to an embodiment of the present disclosure, the platinum metal complex has a structure represented by a general formula of Pt(Lₐ)(L_{b}), wherein Lₐ and L_{b} are a first ligand and a second ligand coordinated to the metal Pt, respectively, Lₐ has a structure represented by Formula A:

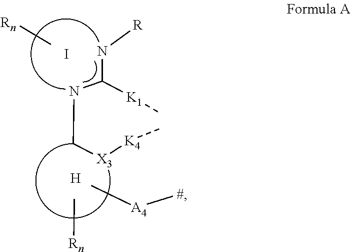

wherein in Formula A, “#” represents a position where L_{b} is joined;
L_{b} has a structure represented by Formula B:

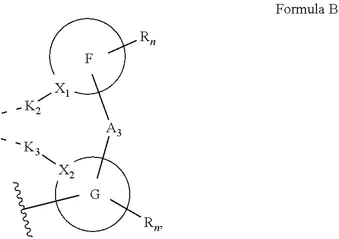

wherein in Formula B, “ [symbol] ” represents a position where Lₐ is joined.

According to an embodiment of the present disclosure, the ring F, the ring G and the ring H are each independently selected from a five-membered unsaturated carbocyclic ring, an aromatic ring having 6 to 30 carbon atoms or a heteroaromatic ring having 3 to 30 carbon atoms, and the ring I is, at each occurrence identically or differently, selected from an unsaturated heterocyclic ring having 3 to 30 carbon atoms.

According to an embodiment of the present disclosure, the ring F, the ring G and the ring H are each independently selected from a five-membered unsaturated carbocyclic ring, an aromatic ring having 6 to 18 carbon atoms or a heteroaromatic ring having 3 to 18 carbon atoms, and the ring I is, at each occurrence identically or differently, selected from an unsaturated heterocyclic ring having 3 to 18 carbon atoms.

According to an embodiment of the present disclosure, the ring F, the ring G and the ring H are each independently selected from a benzene ring, a pyridine ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring or a silole ring, and the ring I is, at each occurrence identically or differently, selected from an imidazolecarbene ring or a benzimidazolecarbene ring.

According to an embodiment of the present disclosure, K₁ to K₄ are selected from a single bond.

According to an embodiment of the present disclosure, the platinum metal complex has a structure represented by one of Formula 3-1 to Formula 3-18:

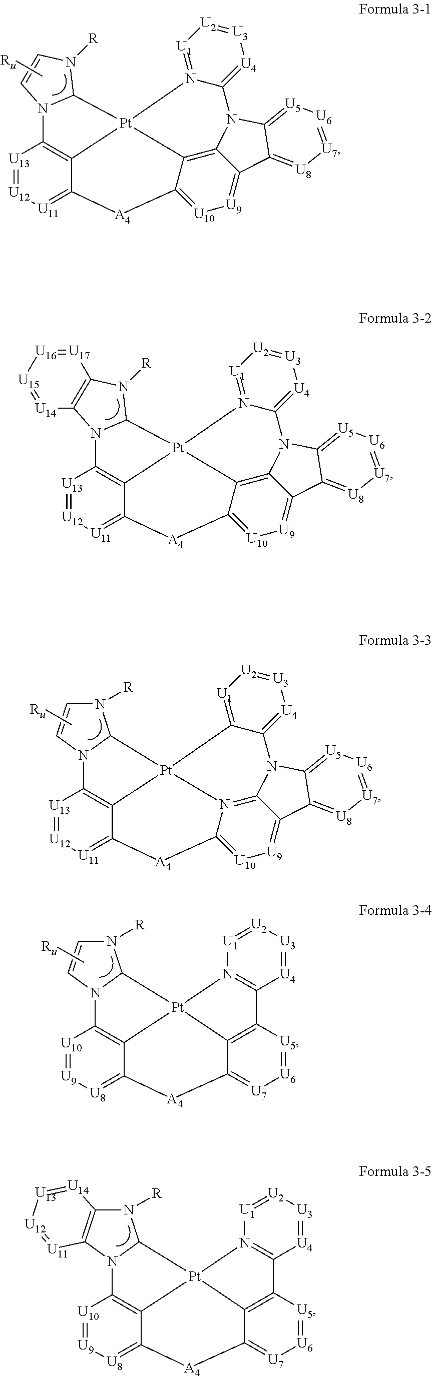

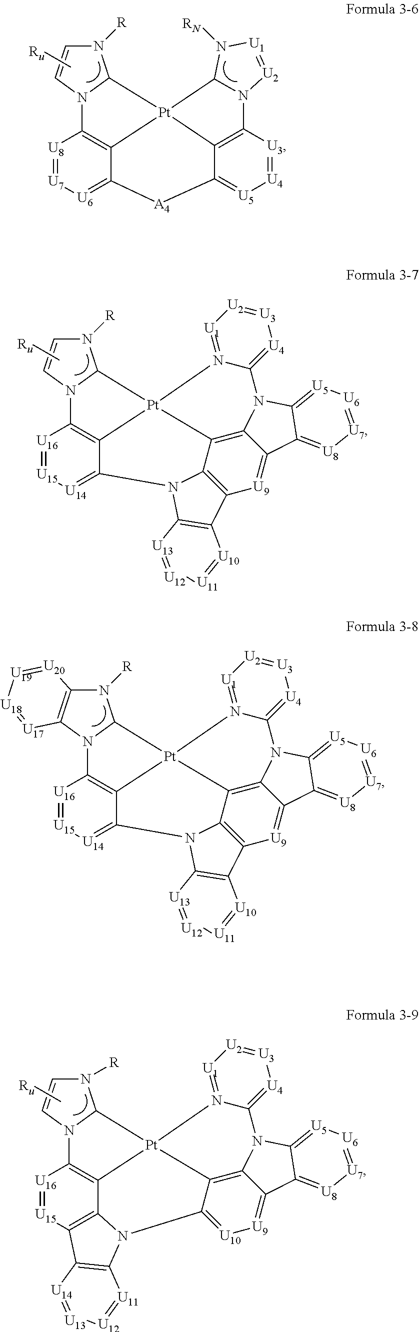

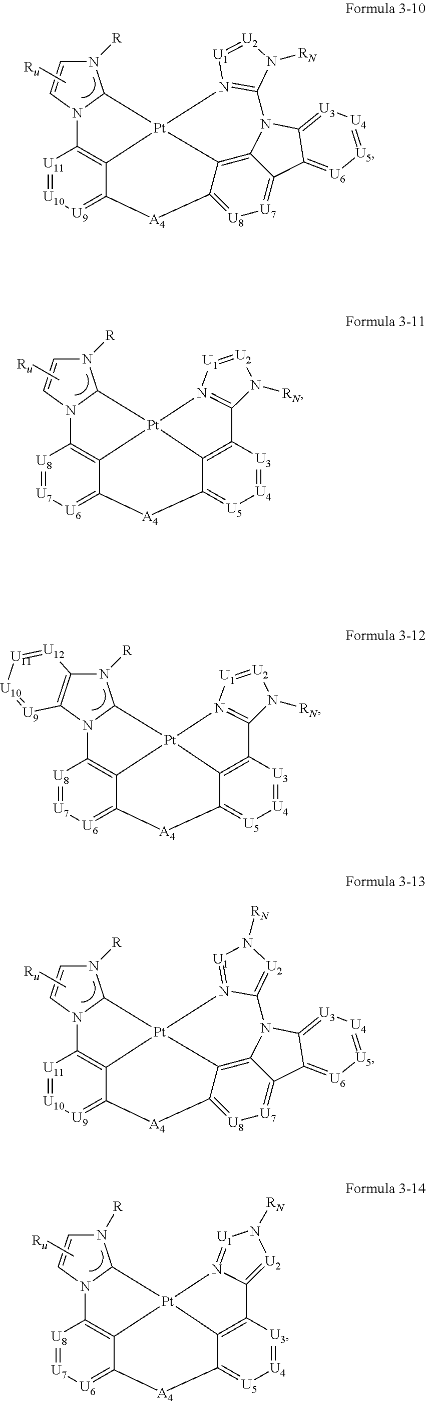

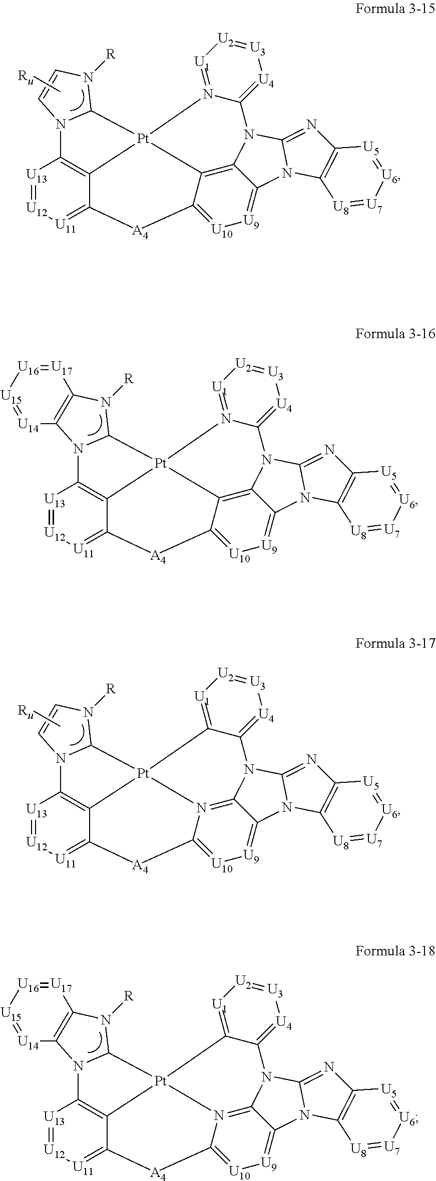

wherein,
A₄ is, at each occurrence identically or differently, selected from a single bond, O, S, Se, (SiR_{q}R_{q})_{y}, PR_{q}, NR_{q}, substituted or unsubstituted arylene having 6 to 30 carbon atoms, substituted or unsubstituted heteroarylene having 3 to 30 carbon atoms or a combination thereof, wherein y is, at each occurrence identically or differently, selected from 1, 2 or 3;
U₁ to U₂₀ are, at each occurrence identically or differently, selected from CRₙ or N;
Rᵤ represents, at each occurrence identically or differently, mono-substitution, multiple substitutions or non-substitution;
R, R_{N}, R_{q}, Rᵤ and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R, R_{N}, R_{q}, Rᵤ and Rₙ can be optionally joined to form a ring.

In this embodiment, the expression that “adjacent substituents R, R_{N}, R_{q}, Rᵤ and Rₙ can be optionally joined to form a ring” is intended to mean that any one or more of groups of adjacent substituents, such as two substituents R_{q}, two substituents Rᵤ, two substituents Rₙ, substituents R and Rᵤ, substituents R and Rₙ, substituents R_{N} and Rₙ, and substituents R_{q} and Rₙ, can be joined to form a ring. Obviously, it is also possible that none of these groups of adjacent substituents are joined to form a ring.

According to an embodiment of the present disclosure, the platinum metal complex has a structure represented by Formula 3-1 or Formula 3-2.

According to an embodiment of the present disclosure, the A₄ is selected from a single bond, O or S.

According to an embodiment of the present disclosure, the A₄ is selected from O.

According to an embodiment of the present disclosure, the U₁ to U₂₀ are, at each occurrence identically or differently, selected from CRₙ, and the Rₙ is, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, the Rₙ is, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, cyclopentyl, cyclohexyl, phenyl, trimethylsilyl, carbazolyl, indolyl, benzofuranyl, dibenzofuranyl, benzosilolyl, dibenzosilolyl, benzothienyl, dibenzothienyl, dibenzoselenophenyl and combinations thereof.

According to an embodiment of the present disclosure, the substituent R has a structure represented by Formula 4:

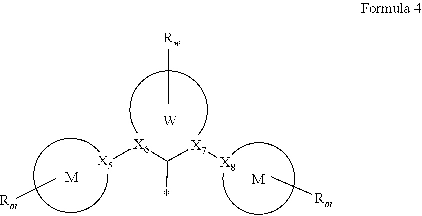

wherein in Formula 4,
the ring M and the ring W are, at each occurrence identically or differently, selected from an unsaturated carbocyclic ring having 5 to 30 carbon atoms, an unsaturated heterocyclic ring having 3 to 30 carbon atoms or a combination thereof;
X₅ to X₈ are, at each occurrence identically or differently, selected from C or N;
“*” represents a position where Formula 4 is joined;
Rₘ and R_{w} represent, at each occurrence identically or differently, mono-substitution, multiple substitutions or non-substitution;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₘ and R_{w} can be optionally joined to form a ring.

In this embodiment, the expression that “adjacent substituents Rₘ and R_{w} can be optionally joined to form a ring” is intended to mean that any one or more of groups of adjacent substituents, such as two substituents Rₘ, two substituents R_{w}, and substituents Rₘ and R_{w}, can be joined to form a ring. Obviously, it is also possible that none of these groups of adjacent substituents are joined to form a ring.

According to an embodiment of the present disclosure, the substituent R has a structure represented by Formula 4-1:

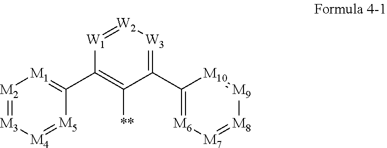

wherein in Formula 4-1,
M₁ to M₁₀ are each independently selected from CRₘ or N;
W₁ to W₃ are each independently selected from CR_{w} or N;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₘ and R_{w} can be optionally joined to form a ring.

According to an embodiment of the present disclosure, in Formula 4 or Formula 4-1, at least one R_{w} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, the M₁ to M₁₀ are each independently selected from CRₘ.

According to an embodiment of the present disclosure, the W₁ to W₃ are each independently selected from CR_{w}.

According to an embodiment of the present disclosure, the Rₘ and R_{w} are, at each occurrence identically or differently, selected from the group consisting of: hydrogen, deuterium, halogen, a cyano group, a hydroxyl group, a sulfanyl group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, the M₁ to M₁₀ are selected from CH or CD.

According to an embodiment of the present disclosure, the W₂ is selected from CR_{w}, and the R_{w} is selected from the group consisting of: deuterium, halogen, a cyano group, a hydroxyl group, a sulfanyl group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, the platinum metal complex has the structure represented by Pt(Lₐ)(L_{b}), wherein Lₐ and L_{b} are the first ligand and the second ligand coordinated to the metal Pt, respectively, Lₐ is selected from the group consisting of Lₐ1-1 to Lₐ1-25 and Lₐ2-1 to Lₐ2-6, and L_{b} is selected from the group consisting of L_{b}1-1 to L_{b}1-8 and L_{b}2-1 to L_{b}2-22, wherein the specific structures of Lₐ1-1 to Lₐ1-25, Lₐ2-1 to Lₐ2-6, L_{b}1-1 to L_{b}1-8 and L_{b}2-1 to L_{b}2-22 are referred to claim 14.

According to an embodiment of the present disclosure, the platinum metal complex is selected from the group consisting of Pt1 to Pt81, and Pt1 to Pt81 have the structure represented by Pt(Lₐ)(L_{b}), wherein the specific structures of Pt1 to Pt81 are referred to claim 14.

According to an embodiment of the present disclosure, the first host compound has a structure represented by one of Formula 5 to Formula 7:

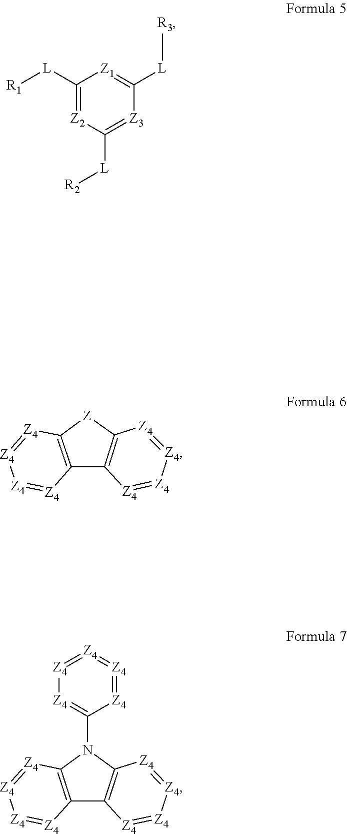

wherein in Formula 5, Z₁ to Z₃ are, at each occurrence identically or differently, selected from CR₄ or N, and at least one of Z₁ to Z₃ is N;
L is, at each occurrence identically or differently, selected from the group consisting of: a single bond, substituted or unsubstituted arylene having 6 to 30 carbon atoms, substituted or unsubstituted heteroarylene having 3 to 30 carbon atoms and combinations thereof;
in Formula 6 and Formula 7, Z₄ is, at each occurrence identically or differently, selected from CR₄ or N, and at least one Z₄ is N;
Z is, at each occurrence identically or differently, selected from O or S;
R₁ to R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₄ can be optionally joined to form a ring.

Herein, the expression that “adjacent substituents R₄ can be optionally joined to form a ring” is intended to mean that two adjacent substituents R₄ can be joined to form a ring. Obviously, it is also possible that two adjacent substituents R₄ are not joined to form a ring.

According to an embodiment of the present disclosure, the first host compound has a structure represented by Formula 5-1 or Formula 6-1:

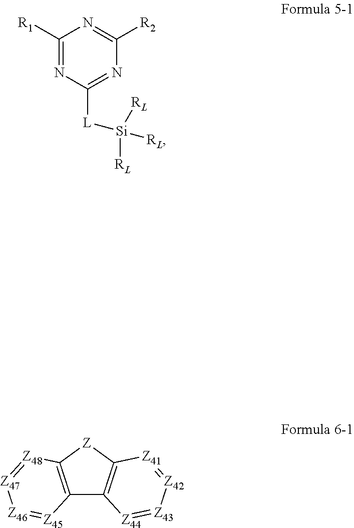

wherein in Formula 5-1,
R₁ and R₂ are each independently selected from substituted or unsubstituted heteroaryl having 3 to 30 carbon atoms;
L is selected from a single bond, substituted or unsubstituted arylene having 6 to 30 carbon atoms, substituted or unsubstituted heteroarylene having 3 to 30 carbon atoms or a combination thereof;
in Formula 6-1,
Z is selected from O or S;
Z₄₁ to Z₄₈ are, at each occurrence identically or differently, selected from CR₄, CR₄′ or N, at least one of Z₄₁ to Z₄₈ is selected from N, and at least one of Z₄₁ to Z₄₈ is selected from CR₄′;
R₄′ is, at each occurrence identically or differently, selected from substituted or unsubstituted aryl having 6 to 30 carbon atoms, substituted or unsubstituted heteroaryl having 3 to 30 carbon atoms or a combination thereof;
R_{L} and R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₄ can be optionally joined to form a ring.

According to an embodiment of the present disclosure, the L is, at each occurrence identically or differently, selected from the group consisting of: a single bond, substituted or unsubstituted arylene having 6 to 18 carbon atoms, substituted or unsubstituted heteroarylene having 3 to 18 carbon atoms and combinations thereof.

According to an embodiment of the present disclosure, the L is, at each occurrence identically or differently, selected from the group consisting of: a single bond, phenylene, biphenylene, fluorenylene, triphenylenylene, furanylene, thienylene, dibenzofuranylene, dibenzothienylene and combinations thereof.

According to an embodiment of the present disclosure, the R_{L} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, the R_{L} is, at each occurrence identically or differently, selected from substituted or unsubstituted aryl having 6 to 30 carbon atoms.

According to an embodiment of the present disclosure, the R_{L} is, at each occurrence identically or differently, selected from the group consisting of: phenyl, biphenyl, triphenylenyl, indenyl, fluorenyl, indolyl, carbazolyl, benzofuranyl, dibenzofuranyl, benzosilolyl, dibenzosilolyl, benzothienyl, dibenzothienyl, dibenzoselenophenyl and combinations thereof.

According to an embodiment of the present disclosure, the R₁ to R₄ are, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, the R₁ to R₄ are, at each occurrence identically or differently, selected from the group consisting of: hydrogen, deuterium, halogen, a cyano group, substituted or unsubstituted aryl having 6 to 18 carbon atoms, substituted or unsubstituted heteroaryl having 3 to 18 carbon atoms and combinations thereof.

According to an embodiment of the present disclosure, the R₁ to R₄ are, at each occurrence identically or differently, selected from the group consisting of: hydrogen, deuterium, fluorine, a cyano group, phenyl, biphenyl, triphenylenyl, indenyl, fluorenyl, indolyl, carbazolyl, benzofuranyl, dibenzofuranyl, benzosilolyl, dibenzosilolyl, benzothienyl, dibenzothienyl, dibenzoselenophenyl, triazinyl and combinations thereof.

According to an embodiment of the present disclosure, in Formula 6-1, at least one of Z₄₁ to Z₄₈ is selected from N, and at least two of Z₄₁ to Z₄₈ are selected from CR₄′.

According to an embodiment of the present disclosure, in Formula 6-1, only one of Z₄₁ to Z₄₈ is selected from N, and only two of Z₄₁ to Z₄₈ are selected from CR₄′.

According to an embodiment of the present disclosure, in Formula 6-1, Z₄₂ is selected from N, and Z₄₁ to Z₄₆ are selected from CR₄′.

According to an embodiment of the present disclosure, the first host compound is selected from the group consisting of Compound N-1-1 to Compound N-1-60, Compound N-2-1 to Compound N-2-35 and Compound N-3-1 to Compound N-3-9, wherein the specific structures of Compound N-1-1 to Compound N-1-60, Compound N-2-1 to Compound N-2-35 and Compound N-3-1 to Compound N-3-9 are referred to claim 15.

According to an embodiment of the present disclosure, hydrogens in the structures of Compound N-1-1 to Compound N-1-53, Compound N-1-58, Compound N-2-1 to Compound N-2-32 and Compound N-3-1 to Compound N-3-7 can be partially or fully substituted with deuterium.

According to an embodiment of the present disclosure, wherein the second host compound has a structure represented by Formula 8:

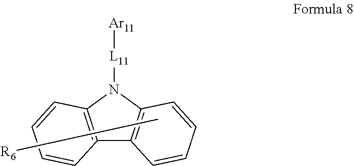

wherein in Formula 8,
L₁₁ is selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₆ can be optionally joined to form a ring.

Herein, the expression that “adjacent substituents R₆ can be optionally joined to form a ring” is intended to mean that two adjacent substituents R₆ can be joined to form a ring. Obviously, it is also possible that two adjacent substituents R₆ are not joined to form a ring.

According to an embodiment of the present disclosure, the second host compound has a structure represented by Formula 8-1 or Formula 8-2:

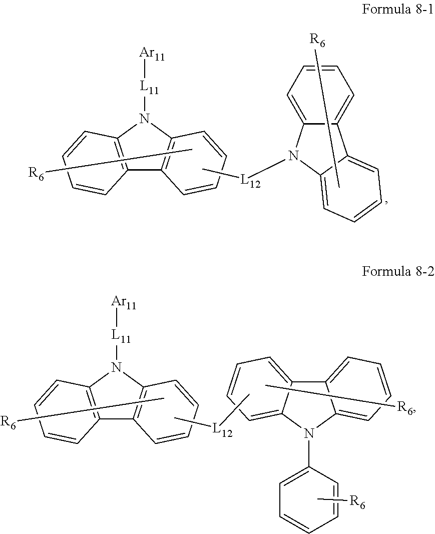

wherein L₁₁ and L₁₂ are selected from a single bond, substituted or unsubstituted arylene having 6 to 30 carbon atoms, substituted or unsubstituted heteroarylene having 3 to 30 carbon atoms or a combination thereof;

Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;

R₆ represents, at each occurrence identically or differently, mono-substitution, multiple substitutions or non-substitution;

R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₆ can be optionally joined to form a ring.

According to an embodiment of the present disclosure, the second host compound has a structure represented by Formula 8-3 or Formula 8-4:

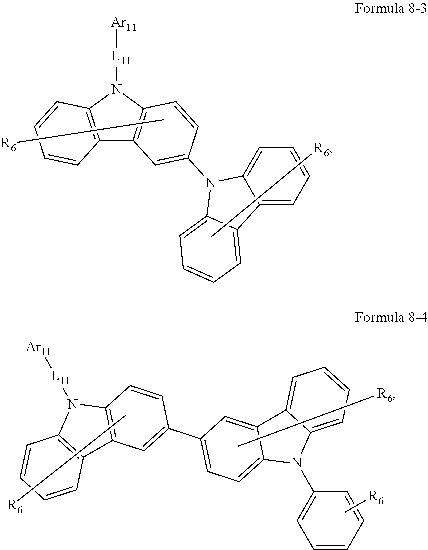

wherein Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
L₁₁ is selected from a single bond, substituted or unsubstituted arylene having 6 to 30 carbon atoms, substituted or unsubstituted heteroarylene having 3 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₆ can be optionally joined to form a ring.

According to an embodiment of the present disclosure, R₆ is, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, the R₆ is, at each occurrence identically or differently, selected from the group consisting of: hydrogen, deuterium, halogen, a cyano group, substituted or unsubstituted aryl having 6 to 18 carbon atoms, substituted or unsubstituted heteroaryl having 3 to 18 carbon atoms and combinations thereof.

According to an embodiment of the present disclosure, the R₆ is, at each occurrence identically or differently, selected from the group consisting of: hydrogen, deuterium, fluorine, a cyano group, phenyl, biphenyl, triphenylenyl, indenyl, fluorenyl, indolyl, carbazolyl, benzofuranyl, dibenzofuranyl, benzosilolyl, dibenzosilolyl, benzothienyl, dibenzothienyl, dibenzoselenophenyl and combinations thereof.

According to an embodiment of the present disclosure, the second host compound is selected from the group consisting of Compound P-1 to Compound P-39, wherein the specific structures of Compound P-1 to Compound P-39 are referred to claim 16.

According to an embodiment of the present disclosure, hydrogens in the structures of Compound P-1 to Compound P-23 and Compound P-27 to Compound P-39 can be partially or fully substituted with deuterium.

According to an embodiment of the present disclosure, the first host compound and the second host compound are host materials, the platinum metal complex is a phosphorescence sensitizer, and the thermally activated delayed fluorescence compound is a light-emitting material.

According to an embodiment of the present disclosure, a weight of the first host compound and the second host compound accounts for 65% to 98.9% of a total weight of a material of the light-emitting layer, a weight of the platinum metal complex accounts for 1% to 30% of the total weight of the material of the light-emitting layer, and a weight of the thermally activated delayed fluorescence compound accounts for 0.1% to 5% of the total weight of the material of the light-emitting layer.

According to an embodiment of the present disclosure, the weight of the first host compound and the second host compound accounts for 82% to 94.5% of the total weight of the material of the light-emitting layer, the weight of the platinum metal complex accounts for 5% to 15% of the total weight of the material of the light-emitting layer, and the weight of the thermally activated delayed fluorescence compound accounts for 0.5% to 3% of the total weight of the material of the light-emitting layer.

According to an embodiment of the present disclosure, the weight of the first host compound and the second host compound accounts for 86.5% to 91.5% of the total weight of the material of the light-emitting layer, the weight of the platinum metal complex accounts for 8% to 12% of the total weight of the material of the light-emitting layer, and the weight of the thermally activated delayed fluorescence compound accounts for 0.5% to 1.5% of the total weight of the material of the light-emitting layer.

According to an embodiment of the present disclosure, before the organic electroluminescent device is manufactured, the polymer comprised in the first organic layer is a polymer.

According to an embodiment of the present disclosure, before the organic electroluminescent device is manufactured, the polymer comprised in the first organic layer is a polymerizable monomer, and the polymerizable monomer experiences a post-polymerization process during the manufacture of the organic electroluminescent device to form the polymer.

According to an embodiment of the present disclosure, the polymer may further experience annealing and cross-linking processes during the manufacture of the organic electroluminescent device.

According to an embodiment of the present disclosure, a molecular weight of the polymer comprised in the first organic layer is 10000 to 200000, preferably, the molecular weight is 50000 to 150000, and more preferably, the molecular weight is 80000 to 110000.

According to an embodiment of the present disclosure, the first organic layer is a hole injection layer, the polymer is a polymer with hole transport performance/hole injection performance, and the hole injection layer may be formed by the polymer or may further comprise a p-type dopant.

In this embodiment, the organic electroluminescent device may further comprise a second organic layer, wherein the second organic layer is a hole transport layer and comprises a second polymer, and the second polymer may be the same as or different from the polymer in the first organic layer.

According to an embodiment of the present disclosure, the first organic layer may also be a hole transport layer, the polymer is a polymer with hole transport performance, the organic electroluminescent device may further comprise a second organic layer, the second organic layer is a hole injection layer and comprises a second polymer, the second polymer is a polymer with hole transport performance/hole injection performance, and preferably, the second organic layer further comprises a p-type dopant. Preferably, the p-type dopant is an ionic-type dopant.

According to an embodiment of the present disclosure, the polymer comprises a triarylamine structure and may comprise a crosslinking group. The crosslinking group is well known in the art. Preferably, the crosslinking group is selected from the group consisting of: substituted or unsubstituted vinyl, substituted or unsubstituted styryl, a substituted or unsubstituted acrylate, substituted or unsubstituted methyl acrylate, a substituted or unsubstituted epoxide, substituted or unsubstituted oxetane, substituted or unsubstituted benzocyclobutene, a substituted or unsubstituted siloxane, substituted or unsubstituted maleimide and combinations thereof.

According to an embodiment of the present disclosure, the p-type dopant comprises fluorine atoms.

According to an embodiment of the present disclosure, the p-type dopant has a structure represented by Formula 9:

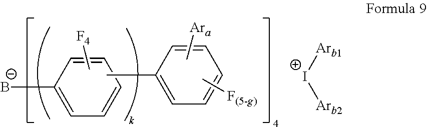

wherein in Formula 9,
Arₐ is, at each occurrence identically or differently, selected from substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, a hydroxyl group, a sulfanyl group, substituted or unsubstituted aryl having 6 to 30 carbon atoms or a combination thereof;
Ar_{b1} and Ar_{b2} are each independently selected from substituted or unsubstituted aryl having 6 to 30 carbon atoms;
g and k are each independently selected from an integer from 0 to 5;
F₄ means that four fluorine atoms are used for substitution;
F_{5-g} means that (5-g) fluorine atoms are used for substitution; and
k+g≥1.

According to an embodiment of the present disclosure, the p-type dopant is selected from the group consisting of Compound HI-1 to Compound HI-14:

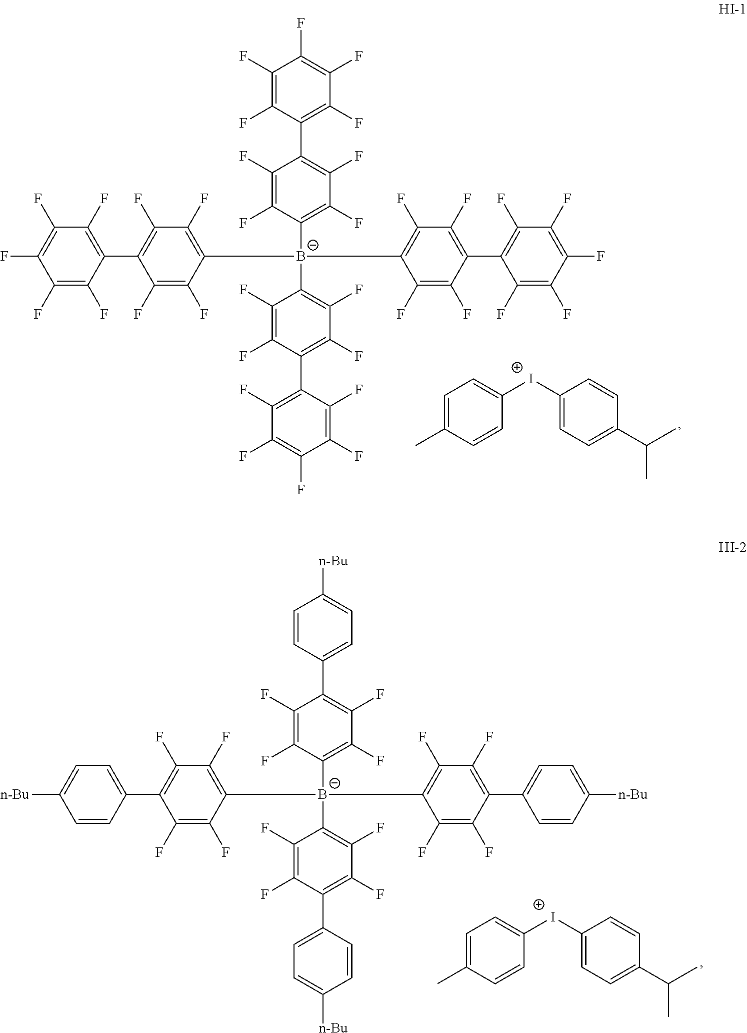

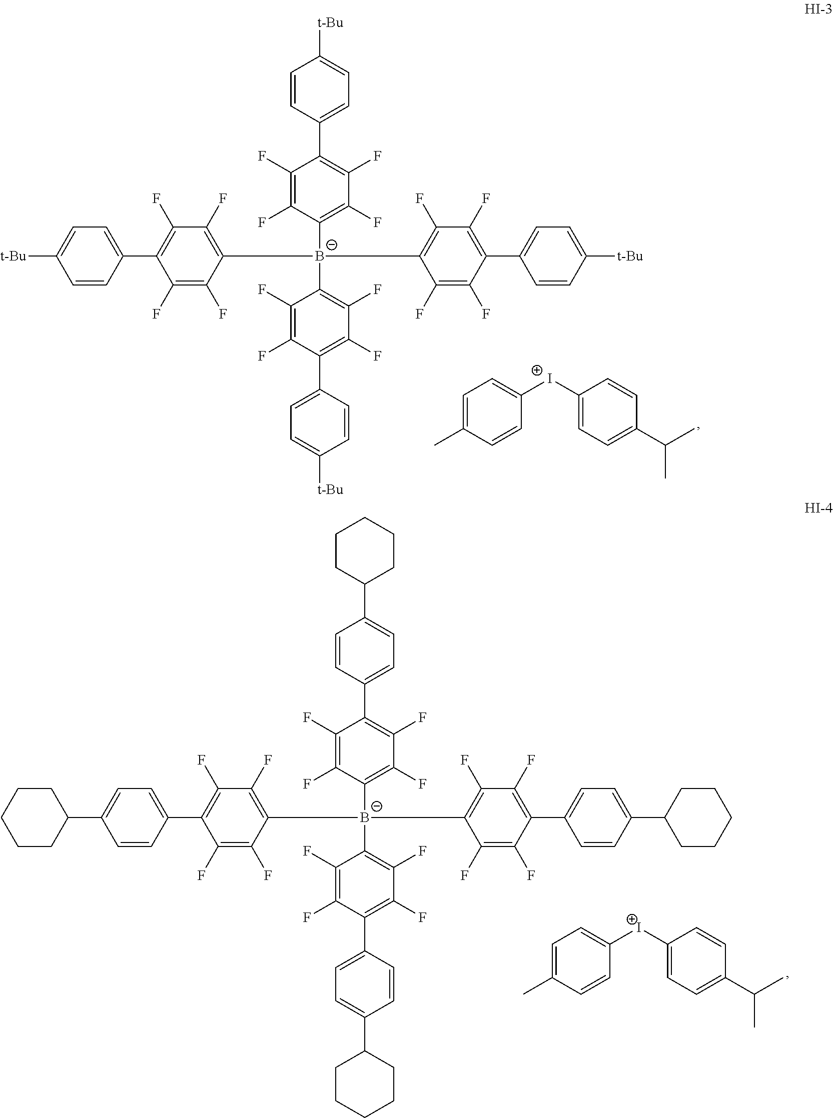 [SMILES: CC(C)(C)c1ccc(-c2c(F)c(F)c([B-](c3c(F)c(F)c(-c4ccc(C(C)(C)C)cc4)c(F)c3F)(c3c(F)c(F)c(-c4ccc(C(C)(C)C)cc4)c(F)c3F)c3c(F)c(F)c(-c4ccc(C(C)(C)C)cc4)c(F)c3F)c(F)c2F)cc1 ; Cc1ccc([I+]c2ccc(C(C)C)cc2)cc1 ; Fc1c(F)c([B-](c2c(F)c(F)c(-c3ccc(C4CCCCC4)cc3)c(F)c2F)(c2c(F)c(F)c(-c3ccc(C4CCCCC4)cc3)c(F)c2F)c2c(F)c(F)c(-c3ccc(C4CCCCC4)cc3)c(F)c2F)c(F)c(F)c1-c1ccc(C2CCCCC2)cc1 ; Cc1ccc([I+]c2ccc(C(C)C)cc2)cc1]

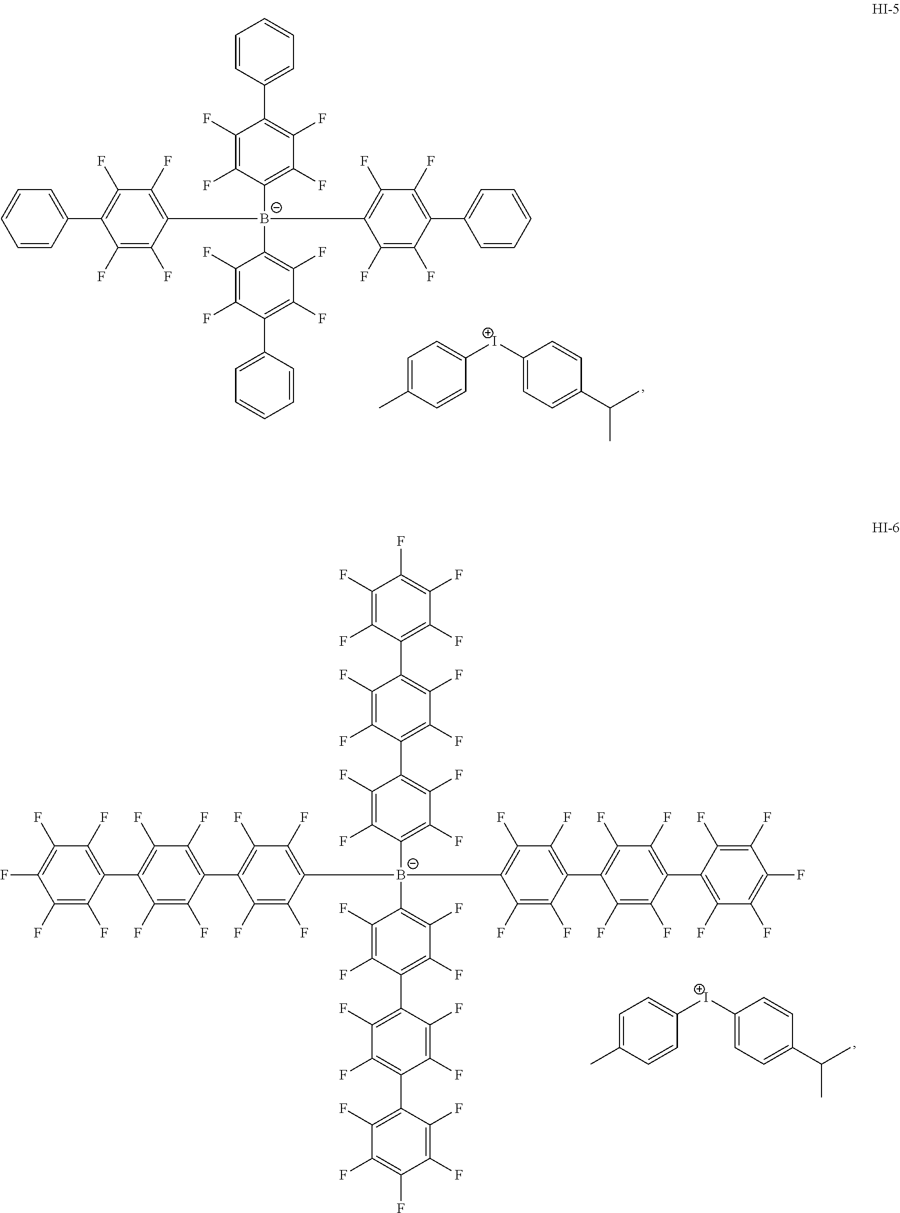 [SMILES: Fc1c(F)c([B-](c2c(F)c(F)c(-c3ccccc3)c(F)c2F)(c2c(F)c(F)c(-c3ccccc3)c(F)c2F)c2c(F)c(F)c(-c3ccccc3)c(F)c2F)c(F)c(F)c1-c1ccccc1 ; Cc1ccc([I+]c2ccc(C(C)C)cc2)cc1 ; Fc1c(F)c(F)c(-c2c(F)c(F)c(-c3c(F)c(F)c([B-](c4c(F)c(F)c(-c5c(F)c(F)c(-c6c(F)c(F)c(F)c(F)c6F)c(F)c5F)c(F)c4F)(c4c(F)c(F)c(-c5c(F)c(F)c(-c6c(F)c(F)c(F)c(F)c6F)c(F)c5F)c(F)c4F)c4c(F)c(F)c(-c5c(F)c(F)c(-c6c(F)c(F)c(F)c(F)c6F)c(F)c5F)c(F)c4F)c(F)c3F)c(F)c2F)c(F)c1F ; Cc1ccc([I+]c2ccc(C(C)C)cc2)cc1]

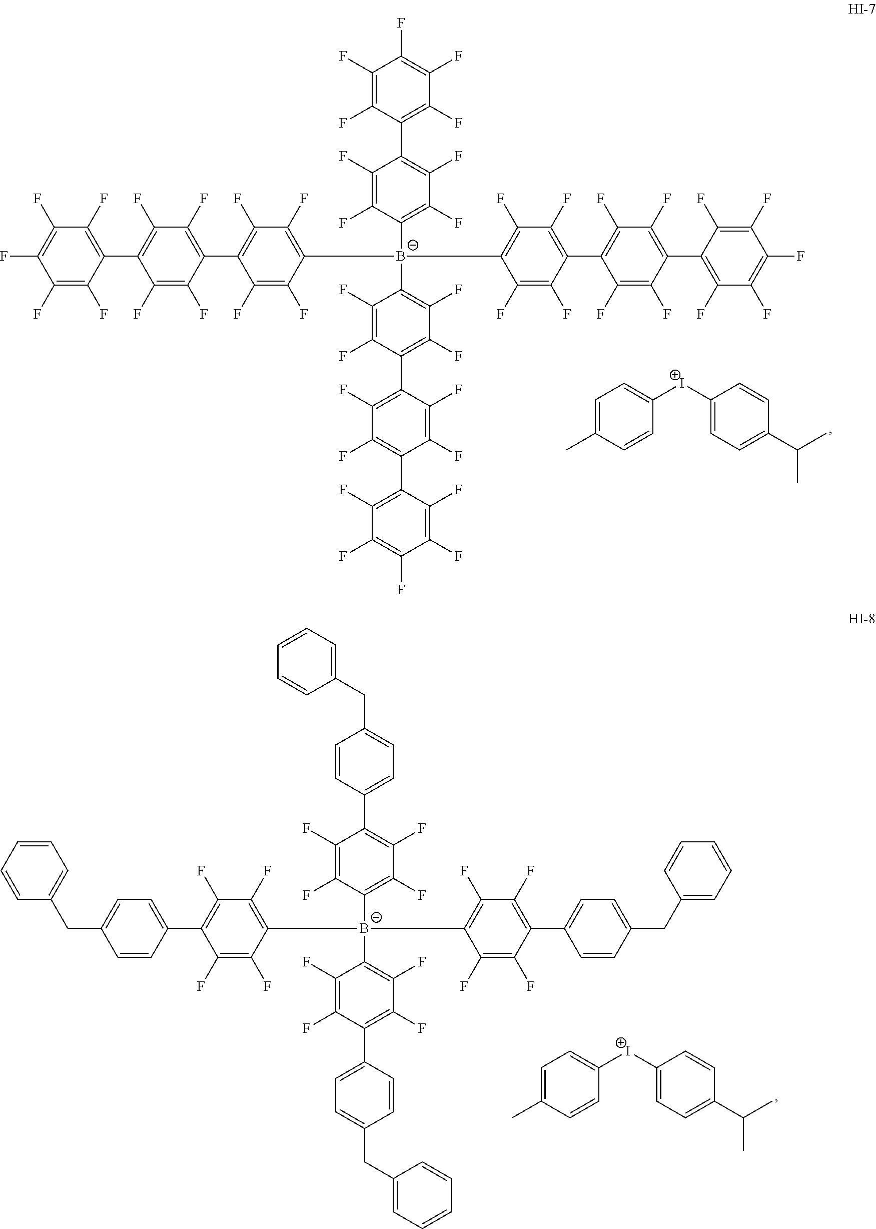 [SMILES: Fc1c(F)c(F)c(-c2c(F)c(F)c(-c3c(F)c(F)c([B-](c4c(F)c(F)c(-c5c(F)c(F)c(F)c(F)c5F)c(F)c4F)(c4c(F)c(F)c(-c5c(F)c(F)c(-c6c(F)c(F)c(F)c(F)c6F)c(F)c5F)c(F)c4F)c4c(F)c(F)c(-c5c(F)c(F)c(-c6c(F)c(F)c(F)c(F)c6F)c(F)c5F)c(F)c4F)c(F)c3F)c(F)c2F)c(F)c1F ; Cc1ccc([I+]c2ccc(C(C)C)cc2)cc1 ; Fc1c(F)c([B-](c2c(F)c(F)c(-c3ccc(Cc4ccccc4)cc3)c(F)c2F)(c2c(F)c(F)c(-c3ccc(Cc4ccccc4)cc3)c(F)c2F)c2c(F)c(F)c(-c3ccc(Cc4ccccc4)cc3)c(F)c2F)c(F)c(F)c1-c1ccc(Cc2ccccc2)cc1 ; Cc1ccc([I+]c2ccc(C(C)C)cc2)cc1]

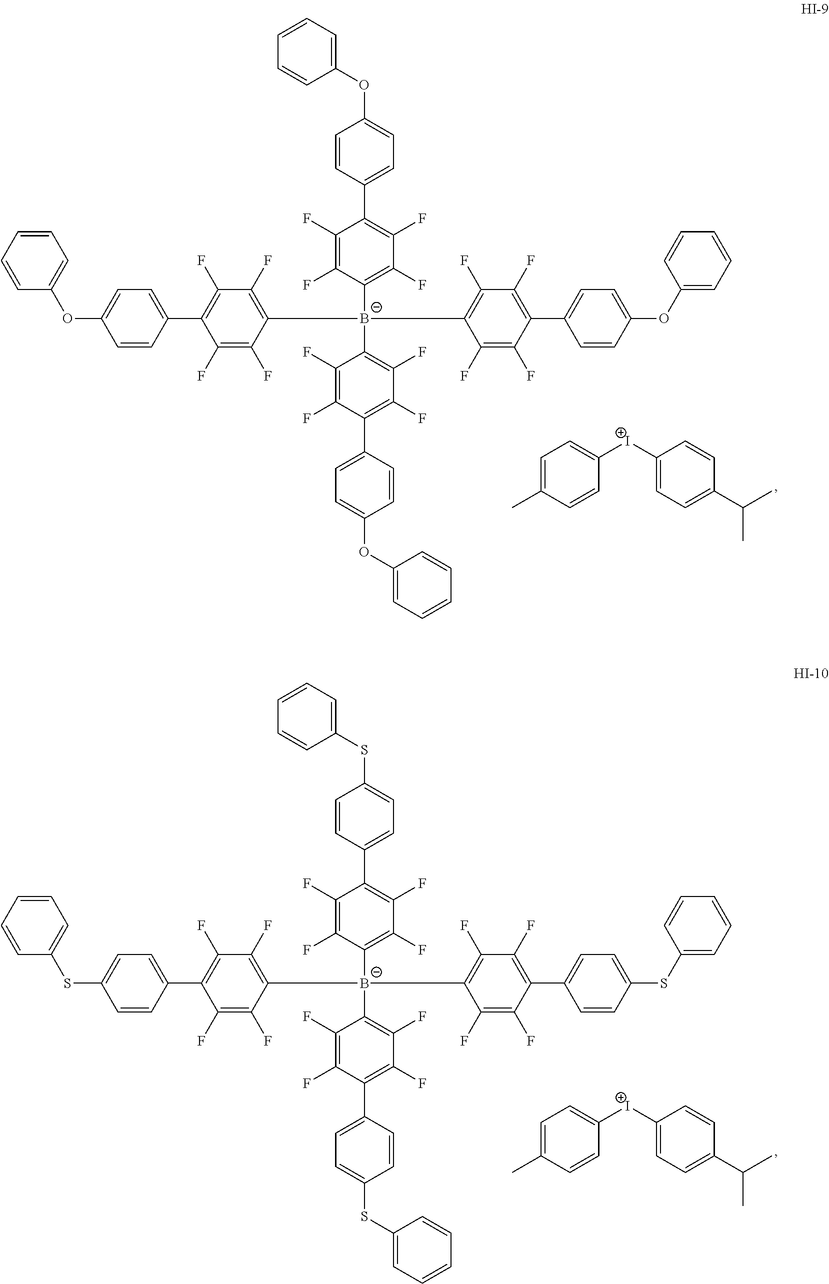 [SMILES: Fc1c(F)c([B-](c2c(F)c(F)c(-c3ccc(Oc4ccccc4)cc3)c(F)c2F)(c2c(F)c(F)c(-c3ccc(Oc4ccccc4)cc3)c(F)c2F)c2c(F)c(F)c(-c3ccc(Oc4ccccc4)cc3)c(F)c2F)c(F)c(F)c1-c1ccc(Oc2ccccc2)cc1 ; Cc1ccc([I+]c2ccc(C(C)C)cc2)cc1 ; Fc1c(F)c([B-](c2c(F)c(F)c(-c3ccc(Sc4ccccc4)cc3)c(F)c2F)(c2c(F)c(F)c(-c3ccc(Sc4ccccc4)cc3)c(F)c2F)c2c(F)c(F)c(-c3ccc(Sc4ccccc4)cc3)c(F)c2F)c(F)c(F)c1-c1ccc(Sc2ccccc2)cc1 ; Cc1ccc([I+]c2ccc(C(C)C)cc2)cc1]

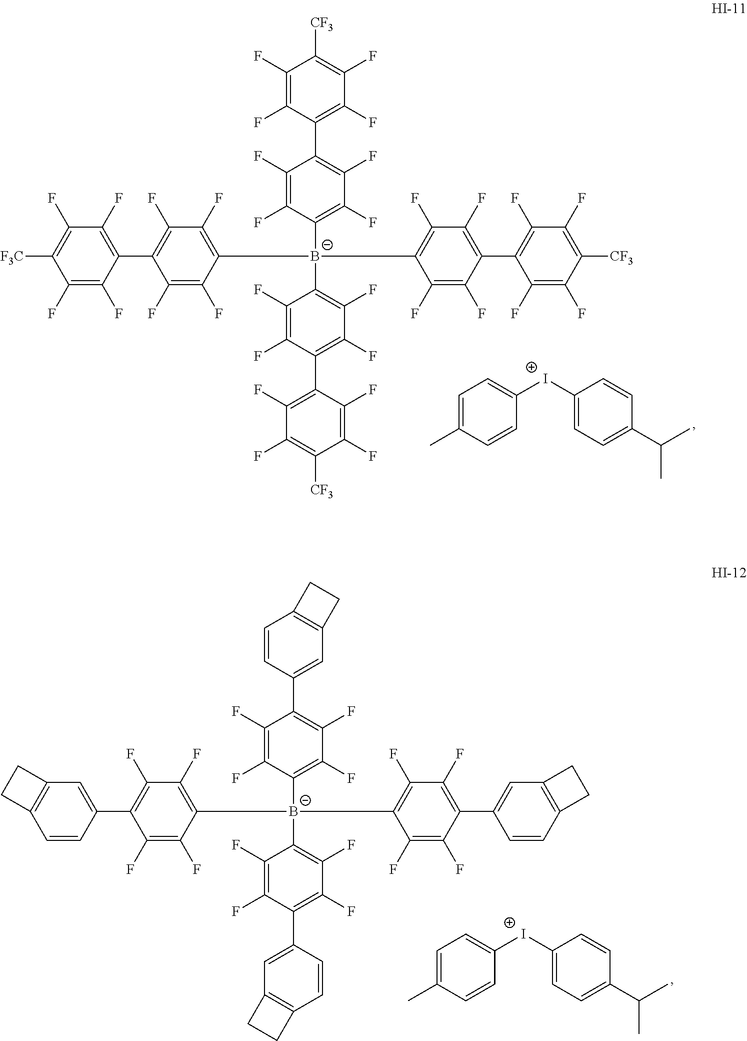 [SMILES: Fc1c(F)c([B-](c2c(F)c(F)c(-c3c(F)c(F)c(C(F)(F)F)c(F)c3F)c(F)c2F)(c2c(F)c(F)c(-c3c(F)c(F)c(C(F)(F)F)c(F)c3F)c(F)c2F)c2c(F)c(F)c(-c3c(F)c(F)c(C(F)(F)F)c(F)c3F)c(F)c2F)c(F)c(F)c1-c1c(F)c(F)c(C(F)(F)F)c(F)c1F ; Cc1ccc([I+]c2ccc(C(C)C)cc2)cc1 ; Fc1c(F)c([B-](c2c(F)c(F)c(-c3ccc4c(c3)CC4)c(F)c2F)(c2c(F)c(F)c(-c3ccc4c(c3)CC4)c(F)c2F)c2c(F)c(F)c(-c3ccc4c(c3)CC4)c(F)c2F)c(F)c(F)c1-c1ccc2c(c1)CC2 ; Cc1ccc([I+]c2ccc(C(C)C)cc2)cc1]

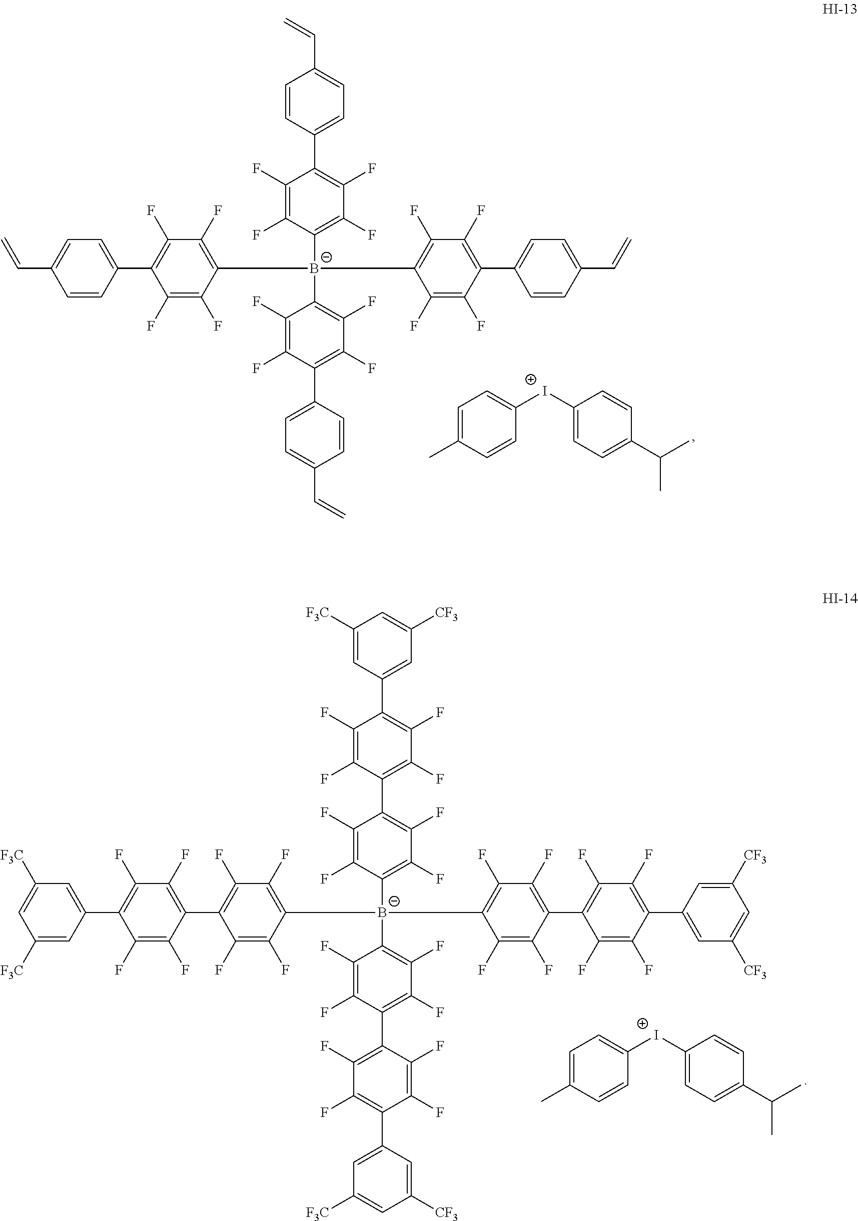

According to an embodiment of the present disclosure, the first organic layer is prepared through the solution method.

According to an embodiment of the present disclosure, the organic electroluminescent device comprises an anode, a cathode, a light-emitting layer disposed between the anode and the cathode and a first organic layer and a second organic layer that are disposed between the anode and the light-emitting layer, wherein the light-emitting layer, the first organic layer and the second organic layer are all prepared through the solution method.

According to an embodiment of the present disclosure, the organic electroluminescent device emits blue light.

According to an embodiment of the present disclosure, disclosed is a display device including the organic electroluminescent device according to any one of the preceding embodiments.

According to an embodiment of the present disclosure, disclosed is an organic light-emitting ink comprising a solvent, a first host compound, a second host compound, a platinum metal complex and a thermally activated delayed fluorescence compound, wherein the first host compound, the second host compound, the platinum metal complex and the thermally activated delayed fluorescence compound are shown in any one of the preceding embodiments.

According to an embodiment of the present disclosure, in the organic light-emitting ink, a total content range of the first host compound, the second host compound, the platinum metal complex and the thermally activated delayed fluorescence compound is 0.5 wt % to 7.5 wt %, and a content range of the solvent is 92.5 wt % to 99.5 wt %.

According to an embodiment of the present disclosure, a boiling point of the solvent is 100-350° C.

According to an embodiment of the present disclosure, in the organic light-emitting ink, the solvent is selected from at least one solvent in the group consisting of an ether-based solvent, an ester-based solvent and an alkyl-substituted aromatic benzene solvent.

According to an embodiment of the present disclosure, in the organic light-emitting ink, the solvent is selected from two or more solvents in the group consisting of the ether-based solvent, the ester-based solvent and the alkyl-substituted aromatic benzene solvent.

According to an embodiment of the present disclosure, the ether-based solvent is selected from the group consisting of: anisole, phenetole, 3-phenoxytoluene, 2,5-dimethoxytoluene, 4-ethylphenetole, 1,3-dimethoxybenzene, dibenzyl ether, 1,2-dimethoxybenzene, 1-methoxynaphthalene, diphenyl ether and 2-phenoxymethyl ether.

According to an embodiment of the present disclosure, the ester-based solvent is a benzoic ester-based solvent.

According to an embodiment of the present disclosure, the benzoic ester-based solvent is selected from the group consisting of: methyl benzoate, ethyl benzoate, ethyl p-methyl benzoate, isobutyl benzoate and ethylhexyl benzoate.

According to an embodiment of the present disclosure, the alkyl-substituted aromatic benzene solvent is selected from the group consisting of: cyclohexylbenzene, 1-hexylbenzene, 1-heptylbenzene, 1-octylbenzene, 1-decylbenzene, 4,4′-diethylbiphenyl, 3,4′-diisopropylbiphenyl and 4,4′-diisopropylbiphenyl.

According to an embodiment of the present disclosure, in the organic electroluminescent device, the light-emitting layer is prepared by using the organic light-emitting ink through the solution method.

Combination with Other Materials

The materials described in the present disclosure for a particular layer in an organic light emitting device can be used in combination with various other materials present in the device. The combinations of these materials are described in more detail in U.S. patent application No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of hosts, transport layers, blocking layers, injection layers, electrodes and other layers that may be present. The combination of these materials is described in detail in paragraphs 0080-0101 of U.S. patent application No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

Reference may be made to preparation methods in the related art to easily obtain the first host compound, the second host compound, the platinum metal complex and the thermally activated delayed fluorescence compound that are used in the present disclosure, and preparation methods are not repeated here.

A method for preparing an organic electroluminescent device is not limited herein. The preparation methods in the following examples are merely examples and are not to be construed as limiting. Based on the related art, those skilled in the art can make reasonable improvements on the preparation methods in the following examples. For example, the proportions of various materials in an emissive layer are not particularly limited. Those skilled in the art can reasonably select the proportions within a certain range based on the related art. For example, taking the total weight of the materials in the emissive layer for reference, two host compounds may account for 65% to 98.9%, a platinum metal complex may account for 1% to 30% and a thermally activated delayed fluorescence compound may account for 0.1% to 5%; or the two host compounds may account for 82% to 94.5%, the platinum metal complex may account for 5% to 15% and the thermally activated delayed fluorescence compound may account for 0.5% to 3%; or the two host compounds may account for 86.5% to 91.5%, the platinum metal complex may account for 8% to 12% and the thermally activated delayed fluorescence compound may account for 0.5% to 1.5%. Further, the ratio of the two host compounds may be 99:1 to 1:99; or the ratio may be 80:20 to 20:80; or the ratio may be 70:30 to 30:70. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art.

### Device Example

The first organic layer of the organic electroluminescent device of the present disclosure comprises a polymer. Therefore, the first organic layer cannot be prepared through an evaporation method but must be prepared through a solution method. For a method for preparing the organic electroluminescent device of the present disclosure, reference may be made to methods commonly used in the related art. For example, reference may be made to the related art CN116023402A, CN115440903A and CN108884114A to complete the preparation by using a combination of preparation processes of the solution method and the evaporation method. A hole injection layer, a hole transport layer and an emissive layer are prepared through the solution method commonly used in the related art, and a hole blocking layer, an electron transport layer, an electron injection layer and a cathode are prepared through the evaporation method commonly used in the related art. The method for preparing the organic electroluminescent device is provided exemplarily without limitation. Device Example 1 is used as an example and is specifically described below.

(1) Treatment of substrate: A glass substrate having an indium tin oxide (ITO) anode with a thickness of 450 Å was cleaned and then treated with oxygen plasma and UV ozone, and after the treatment, the substrate was dried in a glovebox to remove moisture for later use.

(2) Preparation of hole injection layer: Compound HT and Compound HI-14 were dissolved in butyl benzoate to obtain a prepared solution (a weight ratio of Compound HT to Compound HI-14 was 5:1), the solution was spin-coated on the above substrate, and a solvent was removed through heating to prepare a uniform thin film with a thickness of 210 Å.

(3) Preparation of hole transport layer: Compound HT1 was dissolved in cyclohexylbenzene to obtain a prepared solution, the solution was spin-coated on the above hole injection layer, and a solvent was removed through heating to prepare a uniform thin film with a thickness of 210 Å.

(4) Preparation of emissive layer: First Host Compound N-1-15, Second Host Compound P-22, Platinum Metal Complex Pt27 as a phosphorescence sensitizer and Thermally Activated Delayed Fluorescence Compound BD2 were dissolved in methyl benzoate to obtain a prepared solution (a weight ratio of Compound N-1-15: Compound P-22: Platinum Metal Complex Pt27: Compound BD2 was 62.3:26.7:10:1), the solution was spin-coated on the above hole transport layer, and a solvent was removed through heating to prepare a uniform thin film with a thickness of 350 Å.

(5) Preparation of hole blocking layer, electron transport layer, electron injection layer and cathode: Compound N-3-2 was evaporated on the above emissive layer as the hole blocking layer with a thickness of 50 Å, Compound ET and 8-hydroxyquinolinolato-lithium (Liq) were co-evaporated on the hole blocking layer as the electron transport layer with a thickness of 310 Å (a weight ratio of Compound ET to Liq was 40:60), LiF with a thickness of 15 Å was evaporated on the electron transport layer as the electron injection layer, and 1200 Å aluminum continued to be evaporated on the electron injection layer as the cathode.

Finally, the device was transferred back to the glovebox and encapsulated with a glass lid and a moisture getter to complete the device.

### Device Example 2

Device Example 2 was prepared by the same method as Device Example 1, except that Platinum Metal Complex Pt27 was replaced with Platinum Metal Complex Pt11 in the emissive layer (EML).

### Device Example 3

Device Example 3 was prepared by the same method as Device Example 1, except that Compound BD2 was replaced with Compound BD44 in the emissive layer (EML).

### Device Example 4

Device Example 4 was prepared by the same method as Device Example 3, except that Platinum Metal Complex Pt27 was replaced with Platinum Metal Complex Pt11 in the emissive layer (EML).

### Device Example 5

Device Example 5 was prepared by the same method as Device Example 1, except that Compound N-1-15 was replaced with Compound N-3-2 in the emissive layer (EML).

### Device Example 6

Device Example 6 was prepared by the same method as Device Example 5, except that Platinum Metal Complex Pt27 was replaced with Platinum Metal Complex Pt11 in the emissive layer (EML).

### Device Example 7

Device Example 7 was prepared by the same method as Device Example 5, except that Compound BD2 was replaced with Compound BD44 in the emissive layer (EML).

### Device Example 8

Device Example 8 was prepared by the same method as Device Example 7, except that Platinum Metal Complex Pt27 was replaced with Platinum Metal Complex Pt11 in the emissive layer (EML).

### Device Comparative Example 1

Device Comparative Example 1 was prepared by the same method as Device Example 1, except that only First Host Compound N-1-15, Second Host Compound P-22 and Thermally Activated Delayed Fluorescence Compound BD2 were used as the emissive layer (EML) and a weight ratio of Compound N-1-15 to Compound P-22 to Compound BD2 was 69.3:29.7:1.

### Device Comparative Example 2

Device Comparative Example 2 was prepared by the same method as Device Comparative Example 1, except that Compound BD2 was replaced with Compound BD44 in the emissive layer (EML).

### Device Comparative Example 3

Device Comparative Example 3 was prepared by the same method as Device Comparative Example 1, except that Compound N-1-15 was replaced with Compound N-3-2 in the emissive layer (EML).

### Device Comparative Example 4

Device Comparative Example 4 was prepared by the same method as Device Comparative Example 3, except that Compound BD2 was replaced with Compound BD44 in the emissive layer (EML).

The materials used in the above devices have the following structures:

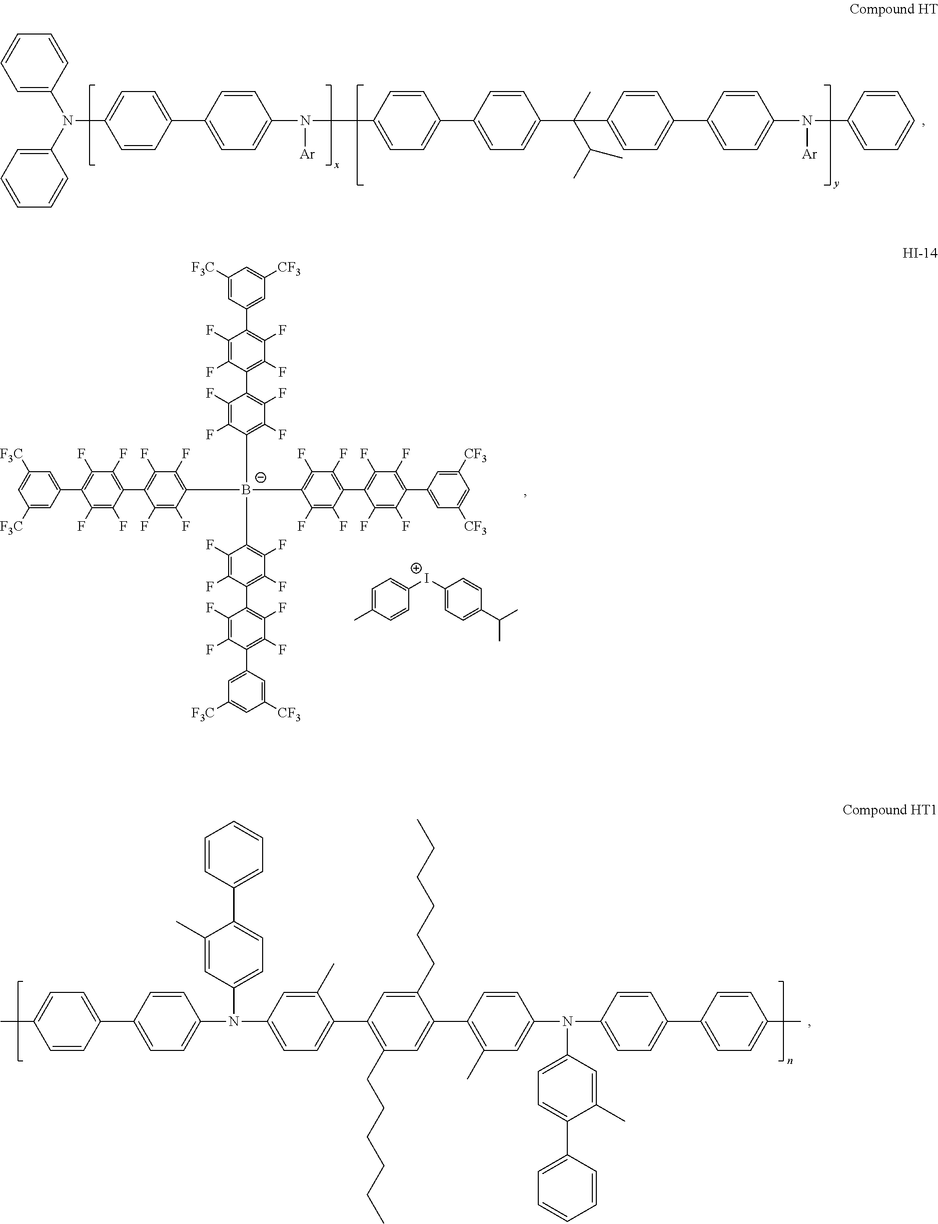

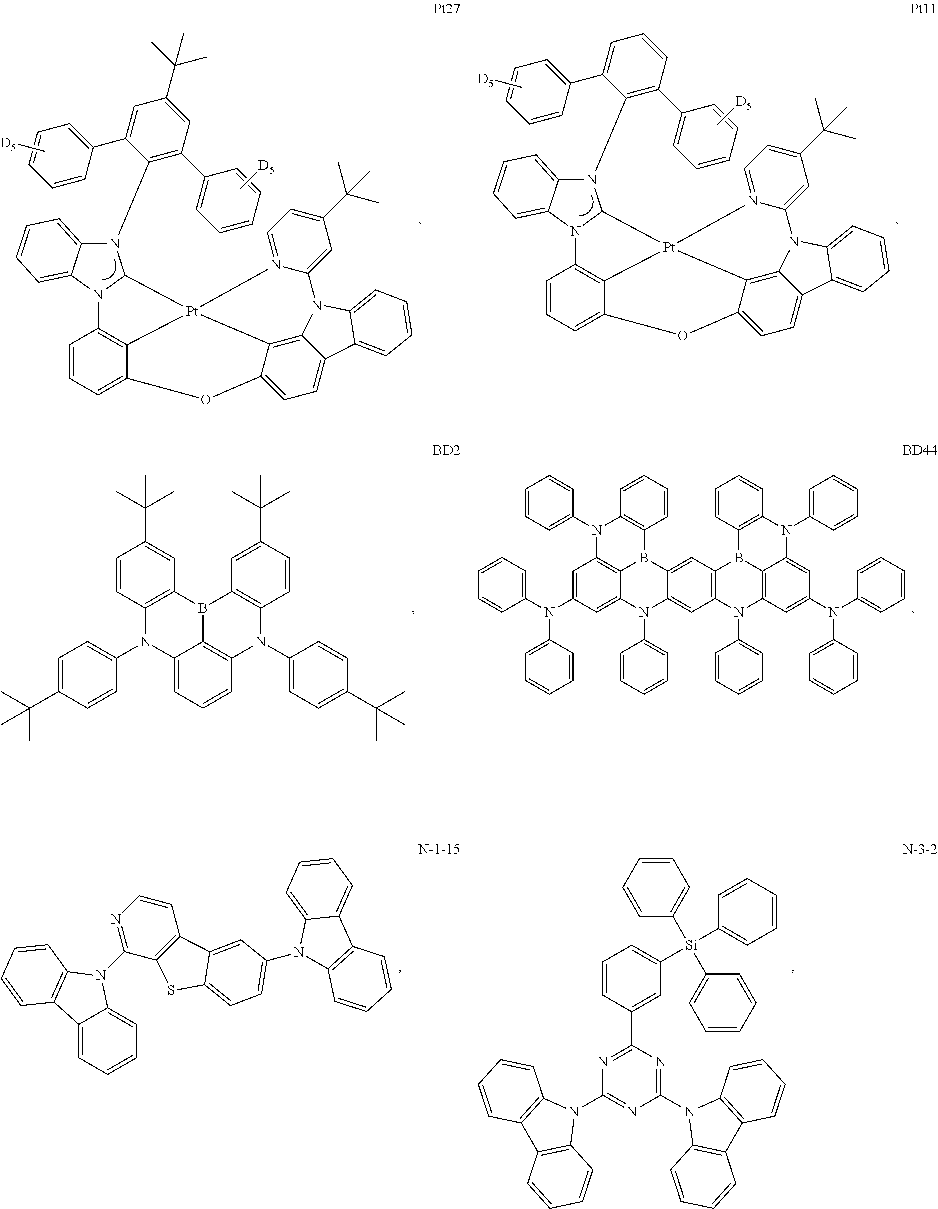

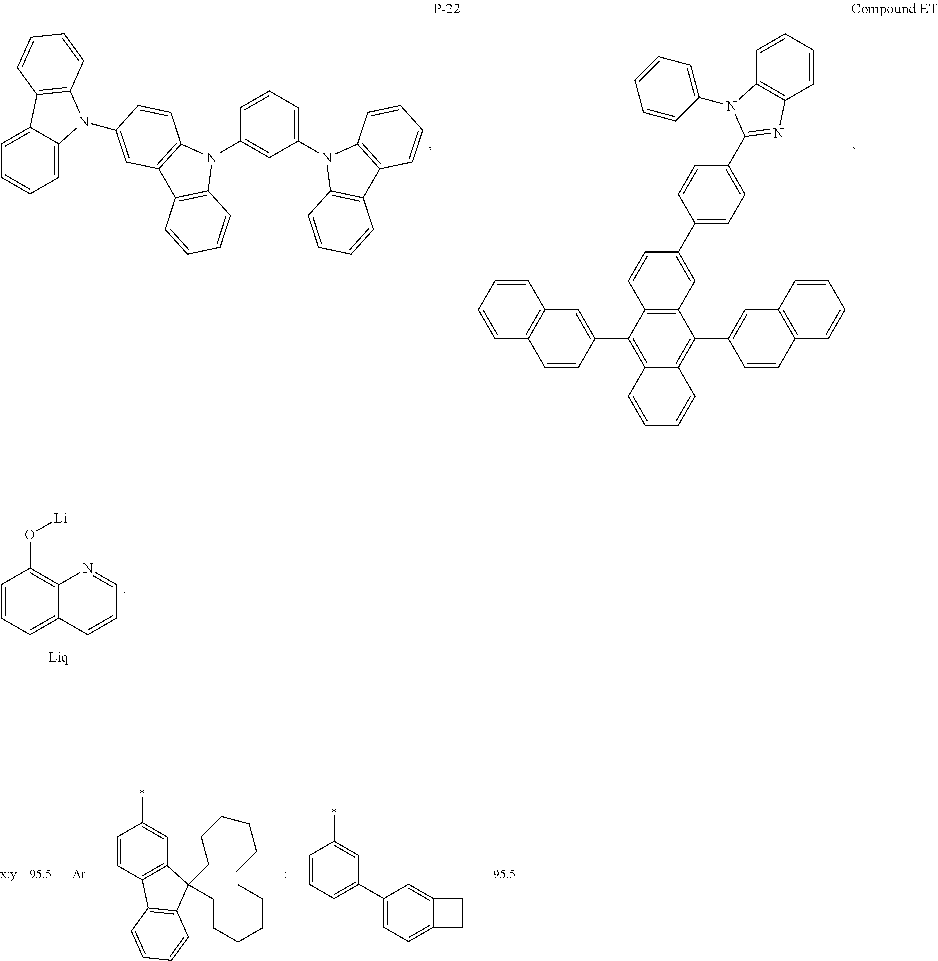

The CIE values, maximum emission wavelengths (λₘₐₓ), full widths at half maximum (FWHM) and external quantum efficiency (EQE) of Examples 1 to 8 and Comparative Examples 1 to 4 were measured at 1000 cd/m². To more intuitively show the comparison of data, the external quantum efficiency of Comparative Example 1 was set to 1.00, and the external quantum efficiency of Examples 1 to 8 and Comparative Examples 2 to 4 was converted relative to the corresponding data of Comparative Example 1. The relevant data are shown in Table 2.

TABLE 2
Device data

| | | λₘₐₓ | FWHM | |
|---|---|---|---|---|
| Device No. | CIE (x, y) | [nm] | [nm] | EQE |
| Example 1 | 0.132, 0.101 | 463 | 25.0 | 2.41 |
| Example 2 | 0.132, 0.103 | 463 | 25.1 | 2.37 |
| Example 3 | 0.120, 0.104 | 470 | 18.8 | 3.88 |
| Example 4 | 0.120, 0.105 | 470 | 18.5 | 3.88 |
| Example 5 | 0.139, 0.125 | 462 | 25.2 | 2.83 |
| Example 6 | 0.138, 0.136 | 463 | 26.1 | 3.04 |
| Example 7 | 0.123, 0.112 | 470 | 18.4 | 3.66 |
| Example 8 | 0.122, 0.114 | 470 | 18.2 | 3.55 |
| Comparative | 0.134, 0.091 | 462 | 26.7 | 1.00 |
| Example 1 | | | | |
| Comparative | 0.119, 0.100 | 470 | 17.8 | 2.53 |
| Example 2 | | | | |
| Comparative | 0.144, 0.118 | 461 | 26.1 | 1.02 |
| Example 3 | | | | |
| Comparative | 0.122, 0.111 | 470 | 17.5 | 2.60 |
| Example 4 | | | | |

Compound BD2 is used as a light-emitting material in the emissive layer of Examples 1 and 2 and Comparative Example 1. The only difference is that the platinum metal complex is used as the phosphorescence sensitizer in Examples 1 and 2 and no platinum metal complex is used in Comparative Example 1. Compared with Comparative Example 1, the maximum emission wavelengths of Examples 1 and 2 are basically consistent with that of Comparative Example 1, the full widths at half maximum of Examples 1 and 2 are basically equivalent to that of Comparative Example 1 and are both relatively narrow, and what is important is that the external quantum efficiency (EQE) of Examples 1 and 2 is significantly improved by 1.41 times and 1.37 times, respectively. Similarly, Compound BD44 is used as a light-emitting material in the emissive layer of Examples 3 and 4 and Comparative Example 2. The only difference is that whether a platinum metal complex is used as a phosphorescence sensitizer. Compared with Comparative Example 2, the maximum emission wavelengths of Examples 3 and 4 are consistent with that of Comparative Example 2, the full widths at half maximum of Examples 3 and 4 are basically equivalent to that of Comparative Example 2 and are both relatively narrow, and the EQE of Examples 3 and 4 is significantly improved by 53%. These data prove that when the hole injection layer and the hole transport layer comprise the polymers, the organic electroluminescent device of the present disclosure comprising the first host compound, the second host compound, the platinum metal complex and the thermally activated delayed fluorescence compound represented by a structure of Formula 1 in the emissive layer can maintain a relatively narrow full width at half maximum and significantly improve the device efficiency compared with the normal TADF device without a platinum metal complex as a phosphorescence sensitizer, thereby exhibiting very excellent device performance.

After the first host compound is replaced, the device performance of the present disclosure is still significantly improved compared with that of the normal TADF device without the phosphorescence sensitizer. Compared with Comparative Example 3, the maximum emission wavelengths of Examples 5 and 6 are basically consistent with that of Comparative Example 3, the full widths at half maximum of Examples 5 and 6 are basically equivalent to that of Comparative Example 3 and are both relatively narrow, and the EQE of Examples 5 and 6 is significantly improved by 1.77 times and 1.98 times, respectively. Compared with Comparative Example 4, the maximum emission wavelengths of Examples 7 and 8 are consistent with that of Comparative Example 4, the full widths at half maximum of Examples 7 and 8 are basically equivalent to that of Comparative Example 4 and are both relatively narrow, and the EQE of Examples 7 and 8 is significantly improved by 40.8% and 36.5%, respectively. These data further prove that when the hole injection layer and the hole transport layer comprise the polymers, the organic electroluminescent device of the present disclosure comprising the first host compound, the second host compound, the platinum metal complex and the thermally activated delayed fluorescence compound represented by the structure of Formula 1 in the emissive layer can maintain a relatively narrow full width at half maximum and significantly improve the device efficiency compared with the normal TADF device without a phosphorescence sensitizer, thereby exhibiting very excellent device performance.

The emissive layer of the organic electroluminescent device of the present disclosure is prepared through the solution method. Therefore, the organic functional layer between the anode and the emissive layer, for example, the first organic layer, needs to comprise the polymer and cannot only comprise small molecules, otherwise an interface/film of the organic functional layer between the anode and the emissive layer may be destroyed in a process of preparing the device through the solution method. The organic electroluminescent device of the present disclosure not only has the advantages of a low cost and a simple process brought through the solution method but also can maintain a relatively narrow full width at half maximum and significantly improve the device efficiency compared with the normal TADF device without the platinum metal complex as the phosphorescence sensitizer, thereby exhibiting very excellent device performance. Therefore, the organic electroluminescent device has a broad application prospect.

On the one hand, the emissive layer in the organic electroluminescent device of the present disclosure comprising the first host compound, the second host compound, the platinum metal complex and the thermally activated delayed fluorescence compound is prepared through the solution method, thereby solving the problem that four evaporation sources are needed when the emissive layer is prepared through the evaporation method. Therefore, the organic electroluminescent device has the advantages of a low cost and a simple process. Moreover, the organic functional layer (for example, the first organic layer) between the anode and the emissive layer in the organic electroluminescent device of the present disclosure comprises the polymer. Therefore, the interface/film of the organic functional layer is not destroyed in the process of preparing the device through the solution method, fully exhibiting the advantages of preparing the organic electroluminescent device of the present disclosure through the solution method. On the other hand, the emissive layer in the organic electroluminescent device of the present disclosure comprises the first host compound, the second host compound, the platinum metal complex and the thermally activated delayed fluorescence compound represented by the structure of Formula 1, thereby achieving an exciton utilization rate of 100% in a manner of co-doping the platinum metal complex and the thermally activated delayed fluorescence compound in the host. Compared with the normal TADF device without the phosphorescence sensitizer, the organic electroluminescent device of the present disclosure can maintain a relatively narrow full width at half maximum and significantly improve the device efficiency, thereby exhibiting very excellent device performance. Therefore, the organic electroluminescent device of the present disclosure has a broad application prospect.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. An organic electroluminescent device, comprising:
an anode,
a cathode,
a light-emitting layer disposed between the anode and the cathode and a first organic layer disposed between the anode and the light-emitting layer;
wherein the first organic layer comprises a polymer;
the light-emitting layer is prepared through a solution method and comprises a first host compound, a second host compound, a platinum metal complex and a thermally activated delayed fluorescence compound;
the thermally activated delayed fluorescence compound has a structure represented by Formula 1: 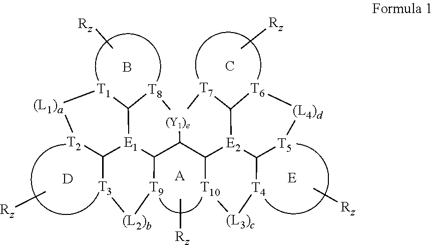
wherein,
the ring A, the ring B, the ring C, the ring D and the ring E are each independently selected from an unsaturated carbocyclic ring having 5 to 30 carbon atoms or an unsaturated heterocyclic ring having 3 to 30 carbon atoms;
Y₁, E₁ and E₂ are each independently selected from B, N, P, P═O, P═S, As, As═O, As═S, SiR′ or GeR′;
T₁ to T₈ are each independently selected from C, CR_{z} or N;
T₉ and T₁₀ are each independently selected from C, CR_{z}, CRₜ or N;
L₁, L₂, L₃ and L₄ are, at each occurrence identically or differently, selected from a single bond, O, S, Se, BRᵥ or NRᵥ;
a, b, c, d and e are each independently selected from 0 or 1;
when e is 1, b is 0 and c is 0, T₉ and T₁₀ are each independently selected from CRₜ or N;
R_{z} represents, at each occurrence identically or differently, mono-substitution, multiple substitutions or non-substitution;
Rₜ is, at each occurrence identically or differently, selected from a small-steric-hindrance group;
Rᵥ, R_{z} and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″ and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₜ, Rᵥ, R_{z}, R′ and R″ can be optionally joined to form a ring.

2. The organic electroluminescent device according to claim 1, wherein the ring A, the ring B, the ring C, the ring D and the ring E are each independently selected from a five-membered unsaturated carbocyclic ring, an aromatic ring having 6 to 30 carbon atoms or a heteroaromatic ring having 3 to 30 carbon atoms;
preferably, the ring A, the ring B, the ring C, the ring D and the ring E are each independently selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring or a silole ring; and
more preferably, the ring A, the ring B, the ring C, the ring D and the ring E are selected from a benzene ring.

3. The organic electroluminescent device according to claim 1, wherein the thermally activated delayed fluorescence compound has a structure represented by Formula 1-1 or Formula 1-2: 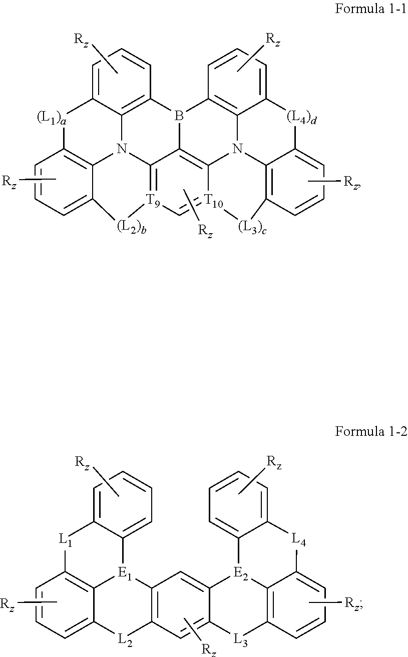
wherein,
a, b, c and d are each independently selected from 0 or 1;
T₉ and T₁₀ are each independently selected from C, CR_{z} or CRₜ;
when b is 0 and c is 0, T₉ and T₁₀ are each independently selected from CRₜ;
E₁ and E₂ are each independently selected from B or N;
L₁, L₂, L₃ and L₄ are, at each occurrence identically or differently, selected from a single bond, O, S, BRᵥ or NRᵥ;
R_{z} represents, at each occurrence identically or differently, mono-substitution, multiple substitutions or non-substitution;
Rₜ is, at each occurrence identically or differently, selected from a small-steric-hindrance group;
Rᵥ and R_{z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″ and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₜ, Rᵥ, R_{z} and R″ can be optionally joined to form a ring.

4. The organic electroluminescent device according to claim 1, wherein a is 0, b is 0, c is 0, and d is 0; or a is 1, b is 0, c is 0, and d is 1; or a is 0, b is 1, c is 0, and d is 1.

5. The organic electroluminescent device according to claim 3, wherein L₁, L₂, L₃ and L₄ are, at each occurrence identically or differently, selected from a single bond, O, BRᵥ or NRᵥ, and the Rᵥ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms or substituted and unsubstituted arylgermanyl having 6 to 20 carbon atoms; and
preferably, in Formula 1-1, L₁, L₂, L₃ and L₄ are, at each occurrence identically or differently, selected from a single bond; in Formula 1-2, L₁, L₂, L₃ and L₄ are, at each occurrence identically or differently, selected from O or NRᵥ, and the Rᵥ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms and substituted or unsubstituted heteroaryl having 3 to 30 carbon atoms.

6. The organic electroluminescent device according to claim 1, wherein the Ry is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group and combinations thereof; and
preferably, the R_{z} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, a cyano group and combinations thereof.

7. The organic electroluminescent device according to claim 1, wherein the thermally activated delayed fluorescence compound has a plurality of R_{z}, and at least one of the plurality of R_{z} is selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms and combinations thereof.

8. The organic electroluminescent device according to claim 1, wherein the Rₜ is, at each occurrence identically or differently, selected from the group consisting of: hydrogen, deuterium, halogen, unsubstituted alkyl having 1 to 6 carbon atoms, unsubstituted cycloalkyl having 3 to 6 ring carbon atoms, unsubstituted heteroalkyl having 1 to 6 carbon atoms, an unsubstituted heterocyclic group having 3 to 6 ring atoms, unsubstituted alkylsilyl having 3 to 6 carbon atoms, unsubstituted amino having 0 to 6 carbon atoms, phenyl and combinations thereof;
preferably, the Rₜ is, at each occurrence identically or differently, selected from the group consisting of: hydrogen, deuterium, halogen, unsubstituted alkyl having 1 to 6 carbon atoms, unsubstituted cycloalkyl having 3 to 6 ring carbon atoms, unsubstituted amino having 0 to 6 carbon atoms and combinations thereof; and
more preferably, Rₜ is, at each occurrence identically or differently, selected from hydrogen, deuterium or halogen.

9. The organic electroluminescent device according to claim 1, wherein the thermally activated delayed fluorescence compound is selected from the group consisting of Compound BD1 to Compound BD53: 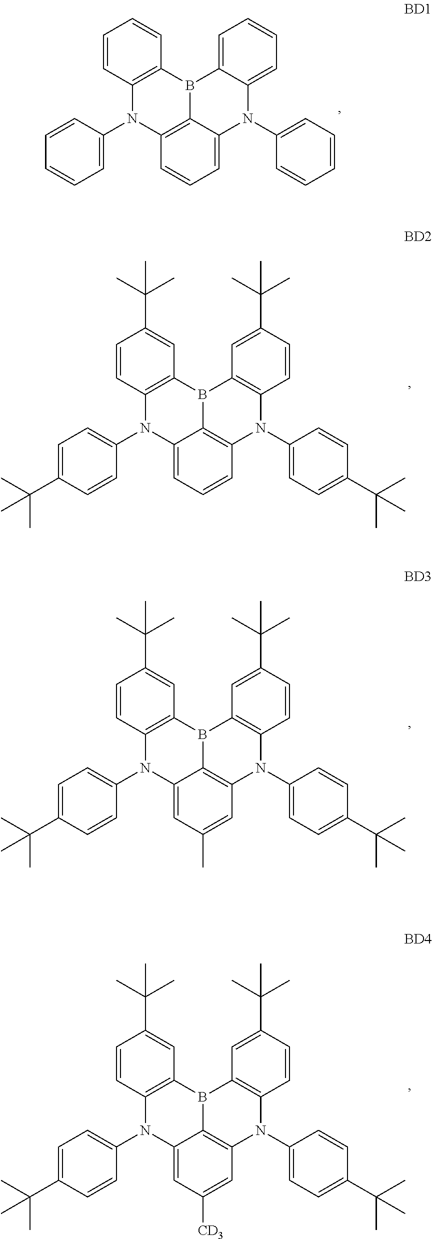 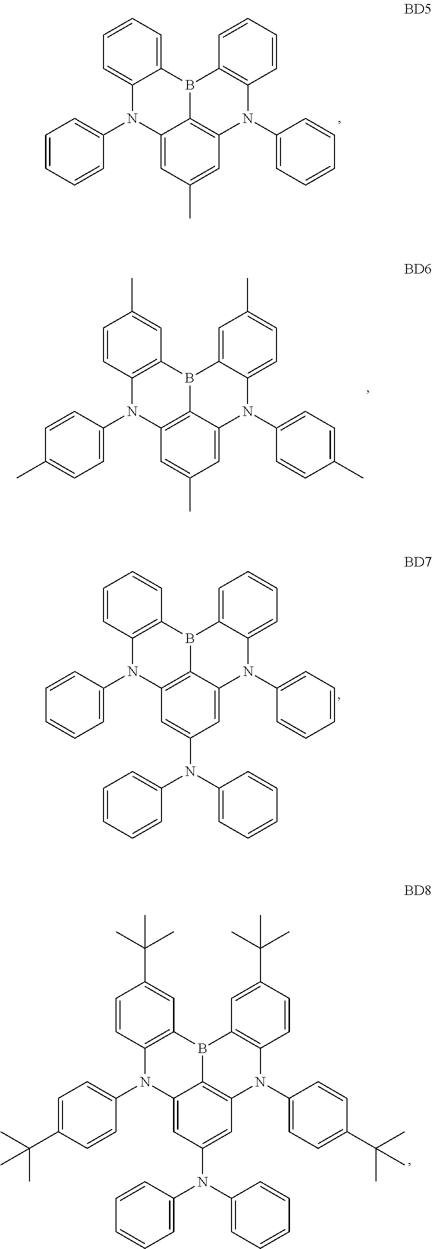 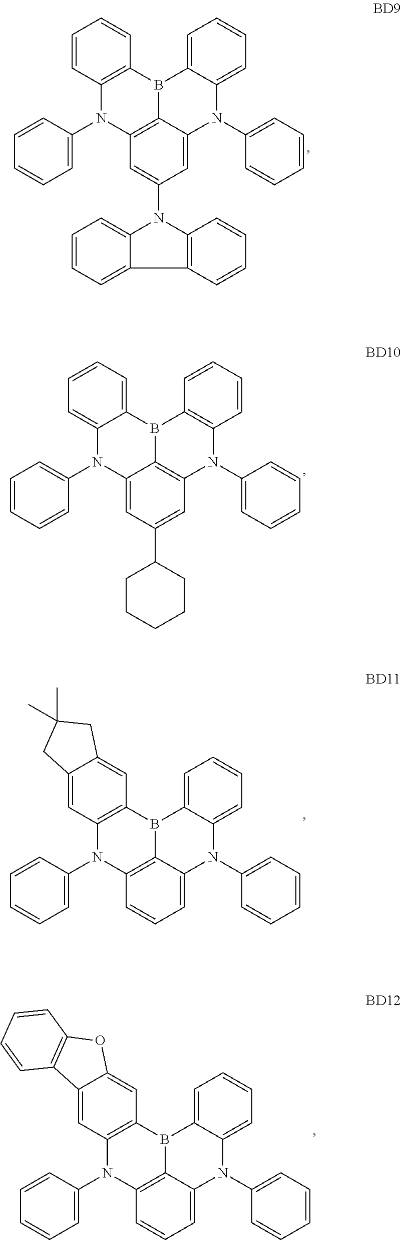 [SMILES: c1ccc(N2c3ccccc3B3c4ccccc4N(c4ccccc4)c4cc(-n5c6ccccc6c6ccccc65)cc2c43)cc1 ; c1ccc(N2c3ccccc3B3c4ccccc4N(c4ccccc4)c4cc(C5CCCCC5)cc2c43)cc1 ; CC1(C)Cc2cc3c(cc2C1)N(c1ccccc1)c1cccc2c1B3c1ccccc1N2c1ccccc1 ; c1ccc(N2c3ccccc3B3c4cc5oc6ccccc6c5cc4N(c4ccccc4)c4cccc2c43)cc1] 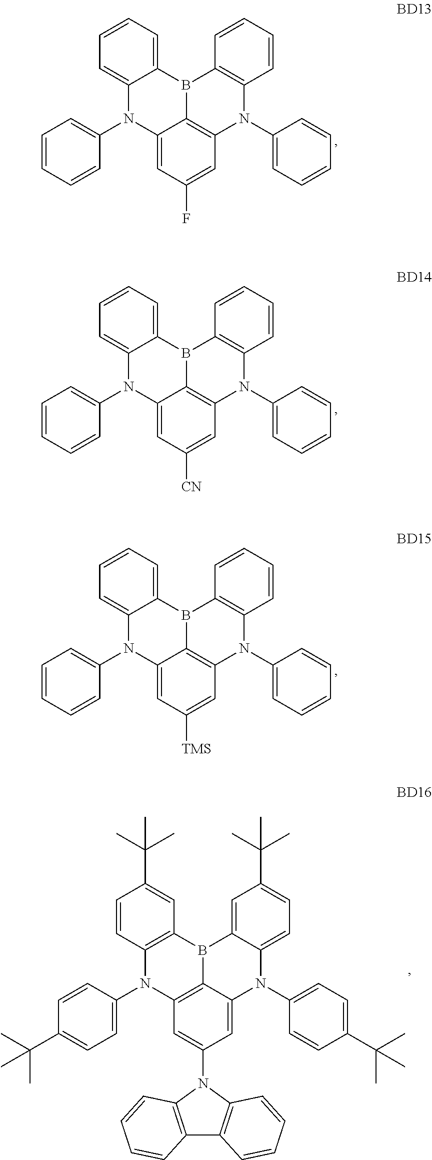 [SMILES: Fc1cc2c3c(c1)N(c1ccccc1)c1ccccc1B3c1ccccc1N2c1ccccc1 ; N#Cc1cc2c3c(c1)N(c1ccccc1)c1ccccc1B3c1ccccc1N2c1ccccc1 ; C[Si](C)(C)c1cc2c3c(c1)N(c1ccccc1)c1ccccc1B3c1ccccc1N2c1ccccc1 ; CC(C)(C)c1ccc(N2c3ccc(C(C)(C)C)cc3B3c4cc(C(C)(C)C)ccc4N(c4ccc(C(C)(C)C)cc4)c4cc(-n5c6ccccc6c6ccccc65)cc2c43)cc1] 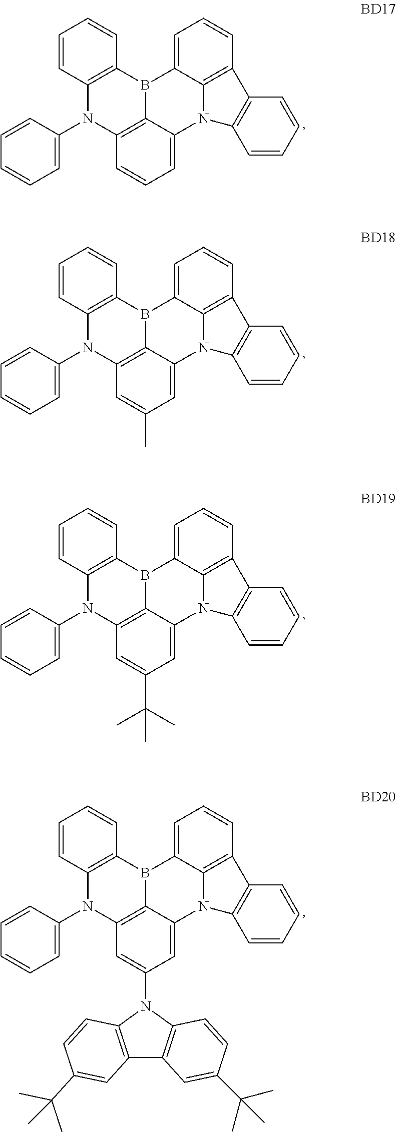 [SMILES: c1ccc(N2c3ccccc3B3c4c2cccc4-n2c4ccccc4c4cccc3c42)cc1 ; Cc1cc2c3c(c1)-n1c4ccccc4c4cccc(c41)B3c1ccccc1N2c1ccccc1 ; CC(C)(C)c1cc2c3c(c1)-n1c4ccccc4c4cccc(c41)B3c1ccccc1N2c1ccccc1 ; CC(C)(C)c1ccc2c(c1)c1cc(C(C)(C)C)ccc1n2-c1cc2c3c(c1)-n1c4ccccc4c4cccc(c41)B3c1ccccc1N2c1ccccc1] 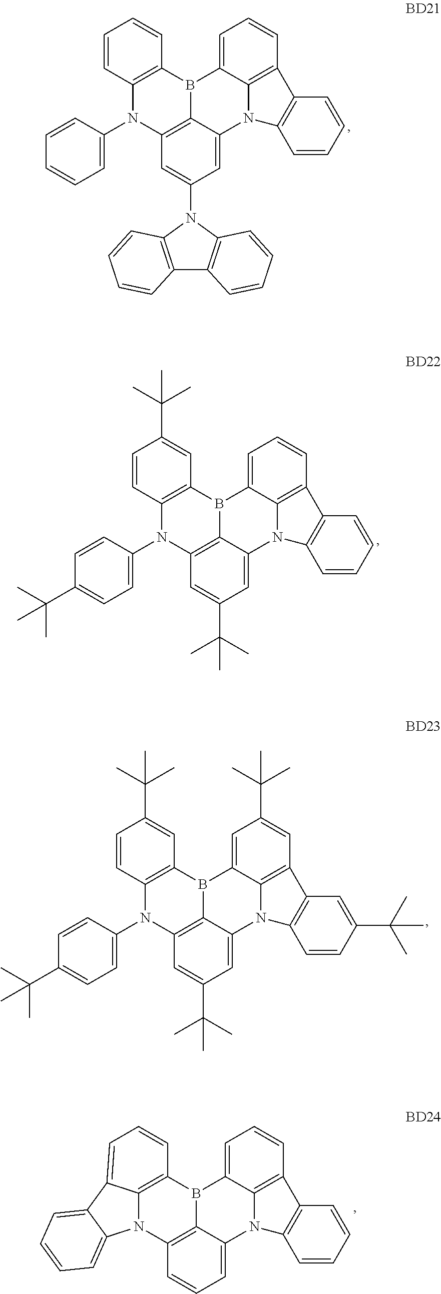 [SMILES: c1ccc(N2c3ccccc3B3c4c2cc(-n2c5ccccc5c5ccccc52)cc4-n2c4ccccc4c4cccc3c42)cc1 ; CC(C)(C)c1ccc(N2c3ccc(C(C)(C)C)cc3B3c4c2cc(C(C)(C)C)cc4-n2c4ccccc4c4cccc3c42)cc1 ; CC(C)(C)c1ccc(N2c3ccc(C(C)(C)C)cc3B3c4c2cc(C(C)(C)C)cc4-n2c4ccc(C(C)(C)C)cc4c4cc(C(C)(C)C)cc3c42)cc1 ; c1cc2c3c(c1)-n1c4ccccc4c4cccc(c41)B3c1cccc3c4ccccc4n-2c13] 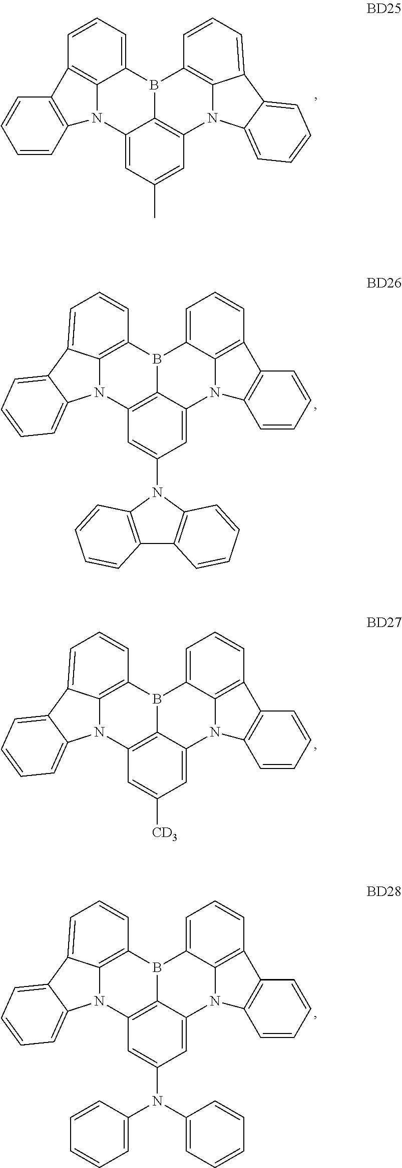 [SMILES: Cc1cc2c3c(c1)-n1c4ccccc4c4cccc(c41)B3c1cccc3c4ccccc4n-2c13 ; c1ccc2c(c1)c1ccccc1n2-c1cc2c3c(c1)-n1c4ccccc4c4cccc(c41)B3c1cccc3c4ccccc4n-2c13 ; [2H]C([2H])([2H])c1cc2c3c(c1)-n1c4ccccc4c4cccc(c41)B3c1cccc3c4ccccc4n-2c13 ; c1ccc(N(c2ccccc2)c2cc3c4c(c2)-n2c5ccccc5c5cccc(c52)B4c2cccc4c5ccccc5n-3c24)cc1] 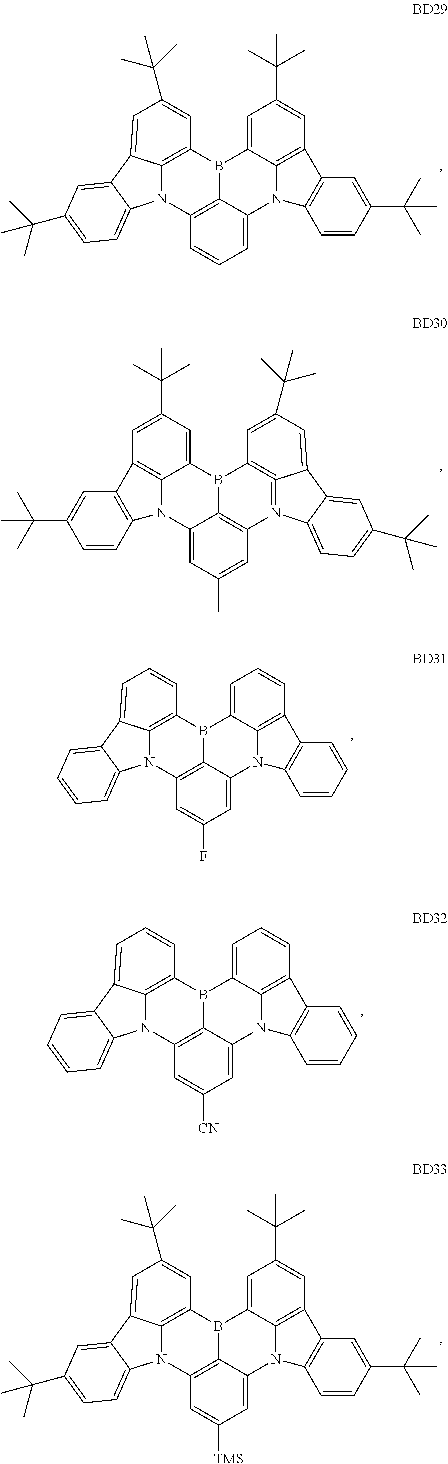 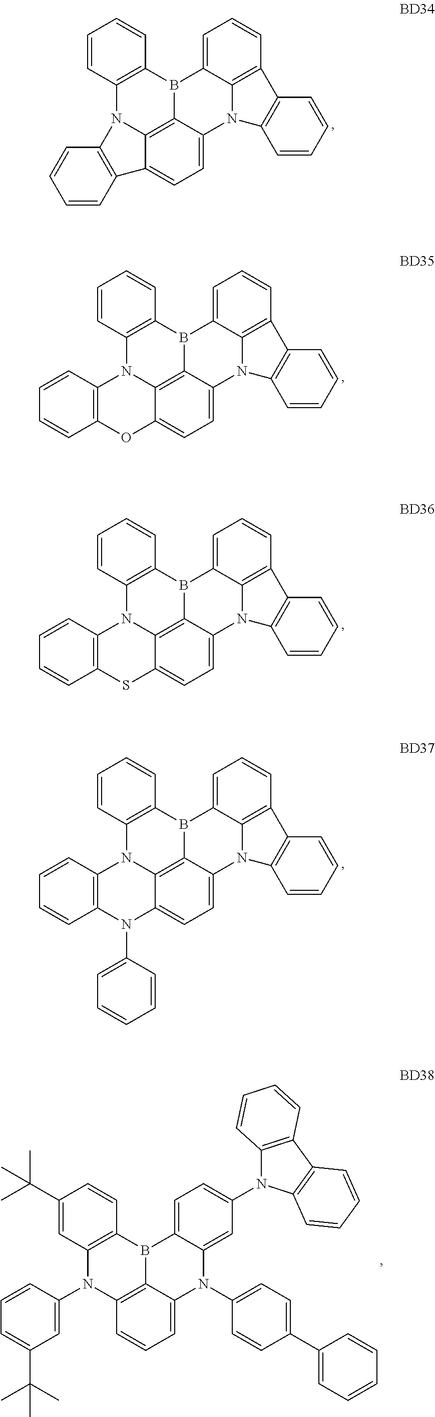 [SMILES: c1ccc2c(c1)B1c3cccc4c5ccccc5n(c34)-c3ccc4c5ccccc5n-2c4c31 ; c1ccc2c(c1)Oc1ccc3c4c1N2c1ccccc1B4c1cccc2c4ccccc4n-3c12 ; c1ccc2c(c1)Sc1ccc3c4c1N2c1ccccc1B4c1cccc2c4ccccc4n-3c12 ; c1ccc(N2c3ccccc3N3c4ccccc4B4c5c(ccc2c53)-n2c3ccccc3c3cccc4c32)cc1 ; CC(C)(C)c1cccc(N2c3cc(C(C)(C)C)ccc3B3c4ccc(-n5c6ccccc6c6ccccc65)cc4N(c4ccc(-c5ccccc5)cc4)c4cccc2c43)c1] 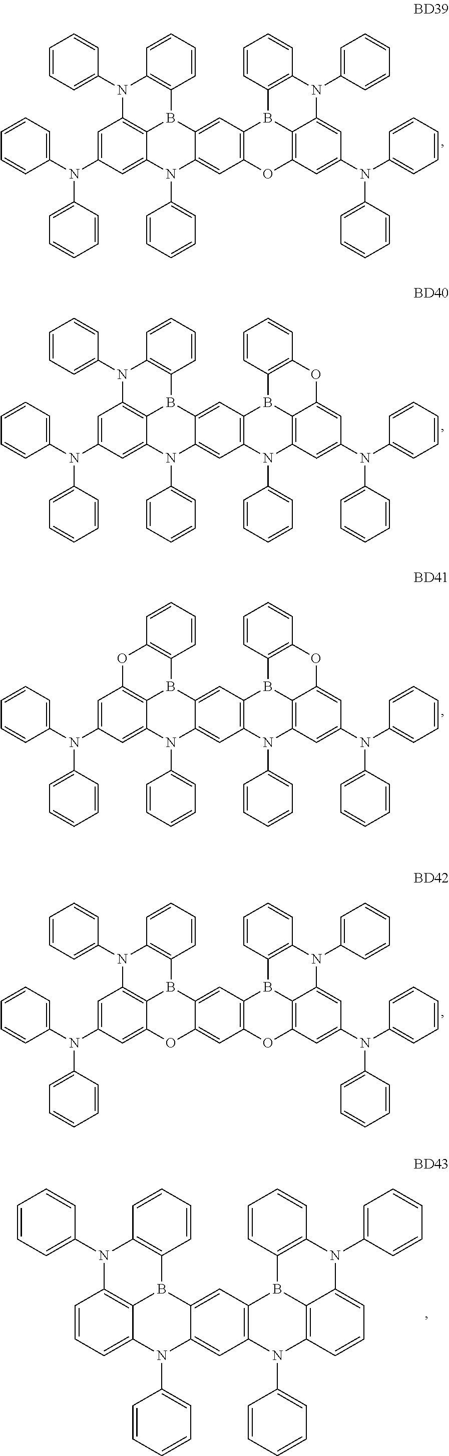 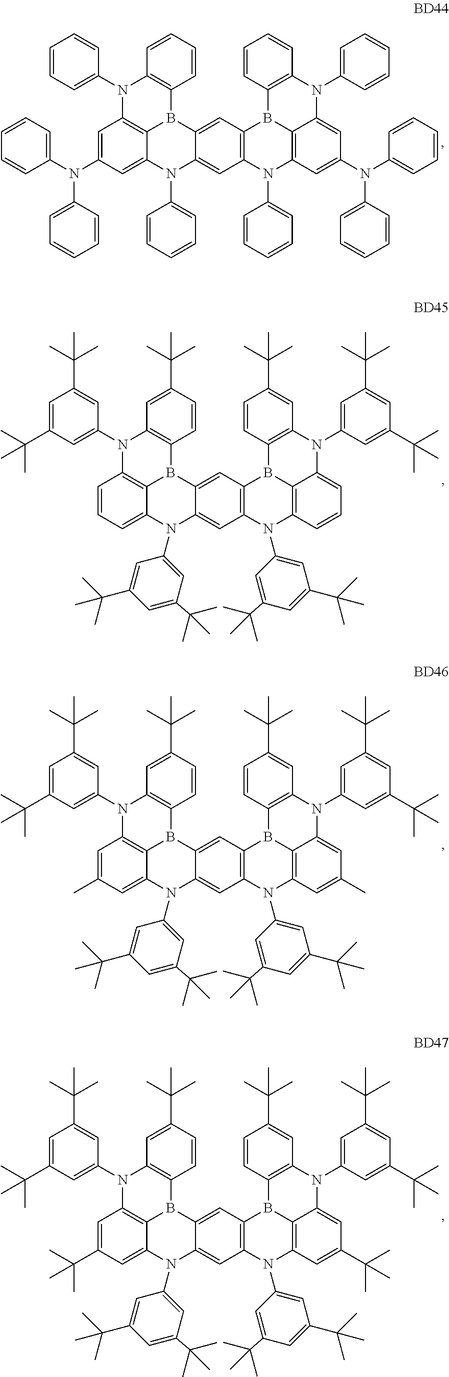 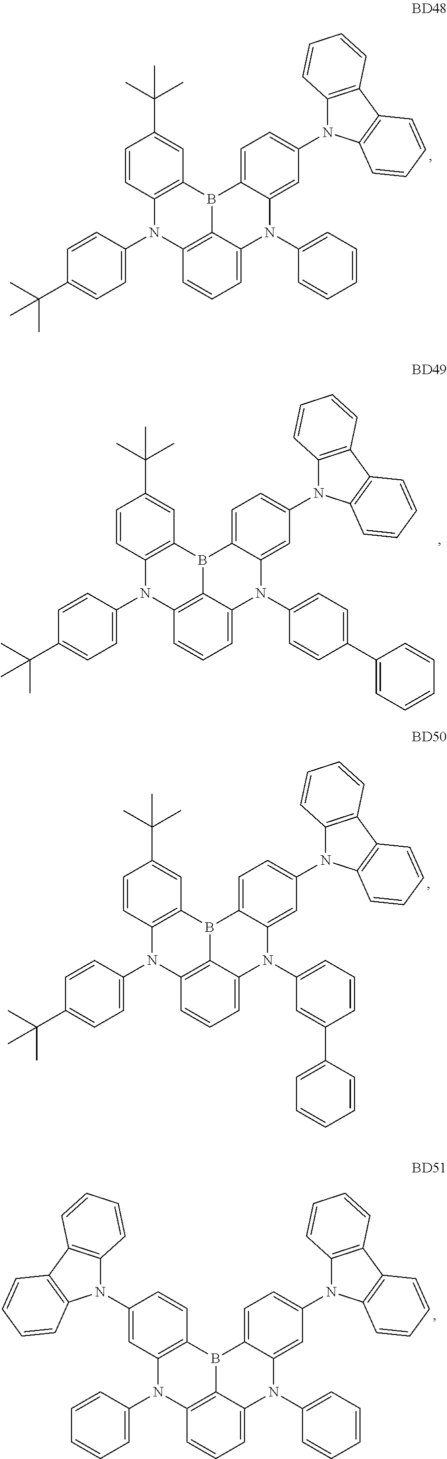 [SMILES: CC(C)(C)c1ccc(N2c3ccc(C(C)(C)C)cc3B3c4ccc(-n5c6ccccc6c6ccccc65)cc4N(c4ccccc4)c4cccc2c43)cc1 ; CC(C)(C)c1ccc(N2c3ccc(C(C)(C)C)cc3B3c4ccc(-n5c6ccccc6c6ccccc65)cc4N(c4ccc(-c5ccccc5)cc4)c4cccc2c43)cc1 ; CC(C)(C)c1ccc(N2c3ccc(C(C)(C)C)cc3B3c4ccc(-n5c6ccccc6c6ccccc65)cc4N(c4cccc(-c5ccccc5)c4)c4cccc2c43)cc1 ; c1ccc(N2c3cc(-n4c5ccccc5c5ccccc54)ccc3B3c4ccc(-n5c6ccccc6c6ccccc65)cc4N(c4ccccc4)c4cccc2c43)cc1] 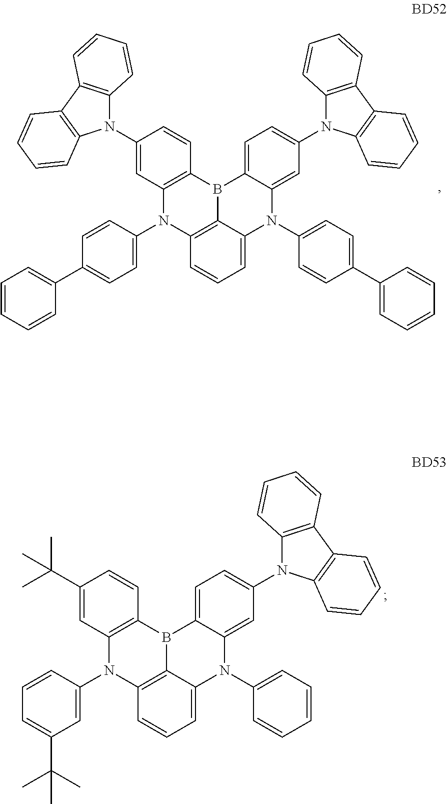 [SMILES: c1ccc(-c2ccc(N3c4cc(-n5c6ccccc6c6ccccc65)ccc4B4c5ccc(-n6c7ccccc7c7ccccc76)cc5N(c5ccc(-c6ccccc6)cc5)c5cccc3c54)cc2)cc1 ; CC(C)(C)c1cccc(N2c3cc(C(C)(C)C)ccc3B3c4ccc(-n5c6ccccc6c6ccccc65)cc4N(c4ccccc4)c4cccc2c43)c1]
wherein optionally, hydrogens in Compound BD1 to Compound BD53 can be partially or fully substituted with deuterium.

10. The organic electroluminescent device according to claim 1, wherein the platinum metal complex has a structure represented by Formula 2: 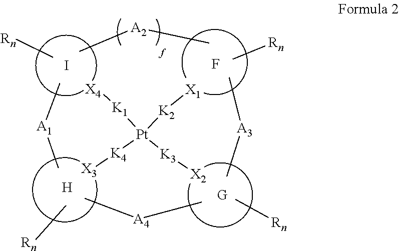
wherein in Formula 2,
the ring F, the ring G, the ring H and the ring I are each independently selected from an unsaturated carbocyclic ring having 5 to 30 carbon atoms, an unsaturated heterocyclic ring having 1 to 30 carbon atoms or a combination thereof;
f is selected from 0 or 1;
A₁ to A₄ are, at each occurrence identically or differently, selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof, wherein y is, at each occurrence identically or differently, selected from 1, 2, 3, 4 or 5;
X₁ to X₄ are each independently selected from C or N;
K₁ to K₄ are each independently selected from a single bond, O or S;
Rₙ represents, at each occurrence identically or differently, mono-substitution, multiple substitutions or non-substitution;
R_{q} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{q} and Rₙ can be optionally joined to form a ring;
preferably, the platinum metal complex has a structure represented by Formula 2-1: 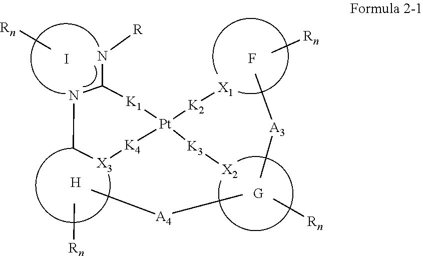
wherein in Formula 2-1,
the ring F, the ring G and the ring H are each independently selected from an unsaturated carbocyclic ring having 5 to 30 carbon atoms, an unsaturated heterocyclic ring having 3 to 30 carbon atoms or a combination thereof, and the ring I is selected from an unsaturated heterocyclic ring having 1 to 30 carbon atoms;
A₃ and A₄ are each independently selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof, wherein y is, at each occurrence identically or differently, selected from 1, 2, 3, 4 or 5;
K₁ to K₄ are each independently selected from a single bond, O or S;
X₁ to X₃ are each independently selected from C or N;
Rₙ represents, at each occurrence identically or differently, mono-substitution, multiple substitutions or non-substitution;
R, R_{q} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R, R_{q} and Rₙ can be optionally joined to form a ring.

11. The organic electroluminescent device according to claim 10, wherein the ring F, the ring G and the ring H are each independently selected from a five-membered unsaturated carbocyclic ring, an aromatic ring having 6 to 30 carbon atoms or a heteroaromatic ring having 3 to 30 carbon atoms, and the ring I is selected from an unsaturated heterocyclic ring having 3 to 30 carbon atoms;
preferably, the ring F, the ring G and the ring H are each independently selected from a five-membered unsaturated carbocyclic ring, an aromatic ring having 6 to 18 carbon atoms or a heteroaromatic ring having 3 to 18 carbon atoms, and the ring I is selected from an unsaturated heterocyclic ring having 3 to 18 carbon atoms; and
more preferably, the ring F, the ring G and the ring H are each independently selected from a benzene ring, a pyridine ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring or a silole ring, and the ring I is selected from an imidazolecarbene ring or a benzimidazolecarbene ring.

12. The organic electroluminescent device according to claim 10, wherein the platinum metal complex has a structure represented by one of Formula 3-1 to Formula 3-18: 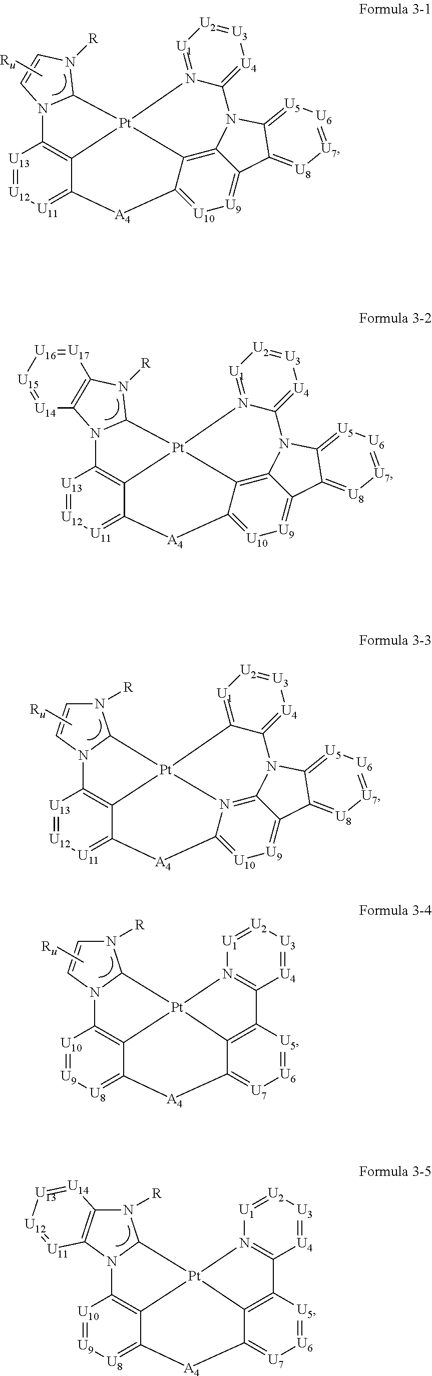 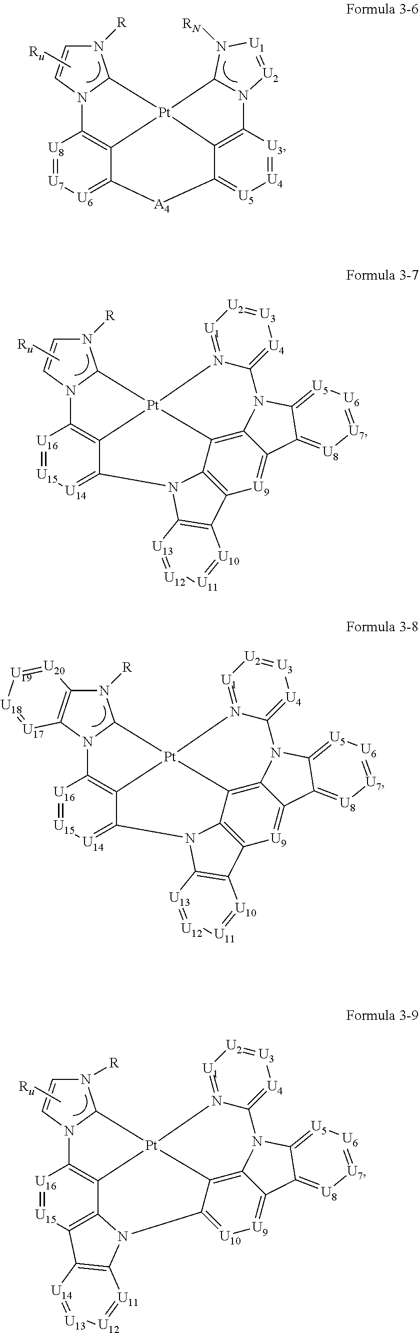 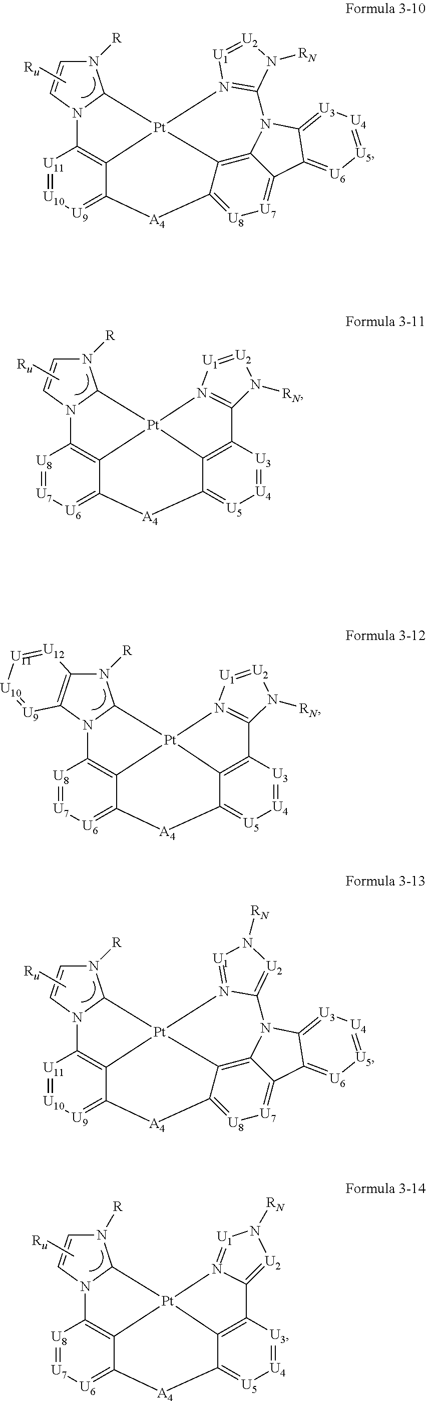 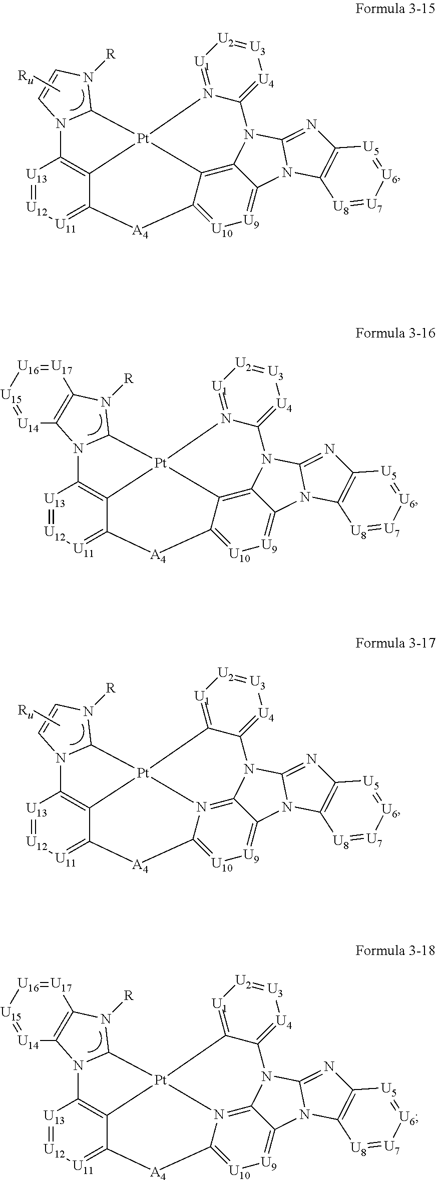
wherein,
A₄ is, at each occurrence identically or differently, selected from a single bond, O, S, Se, (SiR_{q}R_{q})_{y}, PR_{q}, NR_{q}, substituted or unsubstituted arylene having 6 to 30 carbon atoms, substituted or unsubstituted heteroarylene having 3 to 30 carbon atoms or a combination thereof, wherein y is, at each occurrence identically or differently, selected from 1, 2 or 3;
U₁ to U₂₀ are, at each occurrence identically or differently, selected from CRₙ or N;
Rᵤ represents, at each occurrence identically or differently, mono-substitution, multiple substitutions or non-substitution;
R, R_{N}, R_{q}, Rᵤ and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R, R_{N}, R_{q}, Rᵤ and Rₙ can be optionally joined to form a ring; and
preferably, the platinum metal complex has a structure represented by Formula 3-1 or Formula 3-2.

13. The organic electroluminescent device according to claim 12, wherein R has a structure represented by Formula 4: 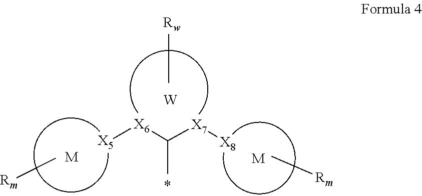
wherein in Formula 4,
the ring M and the ring W are, at each occurrence identically or differently, selected from an unsaturated carbocyclic ring having 5 to 30 carbon atoms, an unsaturated heterocyclic ring having 3 to 30 carbon atoms or a combination thereof;
X₅ to X₈ are, at each occurrence identically or differently, selected from C or N;
“*” represents a position where Formula 4 is joined;
Rₘ and R_{w} represent, at each occurrence identically or differently, mono-substitution, multiple substitutions or non-substitution;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents Rₘ and R_{w} can be optionally joined to form a ring; and
preferably, at least one R_{w} on the ring W in Formula 4 is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

14. The organic electroluminescent device according to claim 1, wherein the platinum metal complex has a structure represented by Pt(Lₐ)(L_{b}), wherein Lₐ and L_{b} are a first ligand and a second ligand coordinated to the metal Pt, respectively, and the Lₐ is selected from the group consisting of Lₐ1-1 to Lₐ1-25 and Lₐ2-1 to Lₐ2-6: 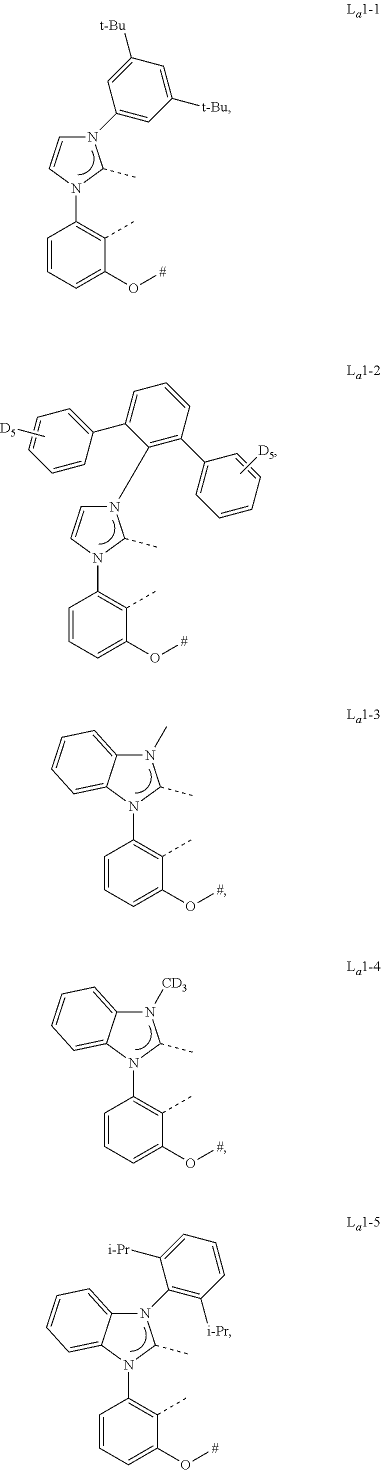 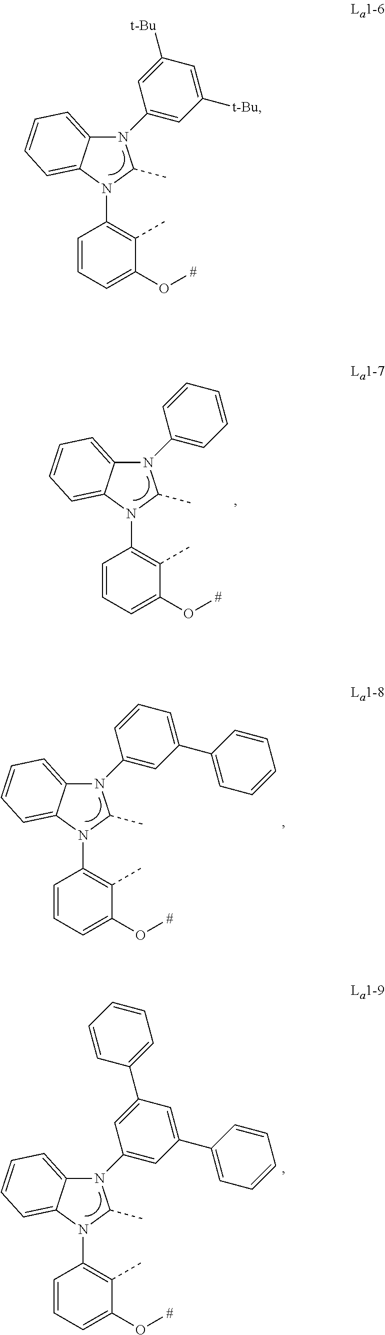 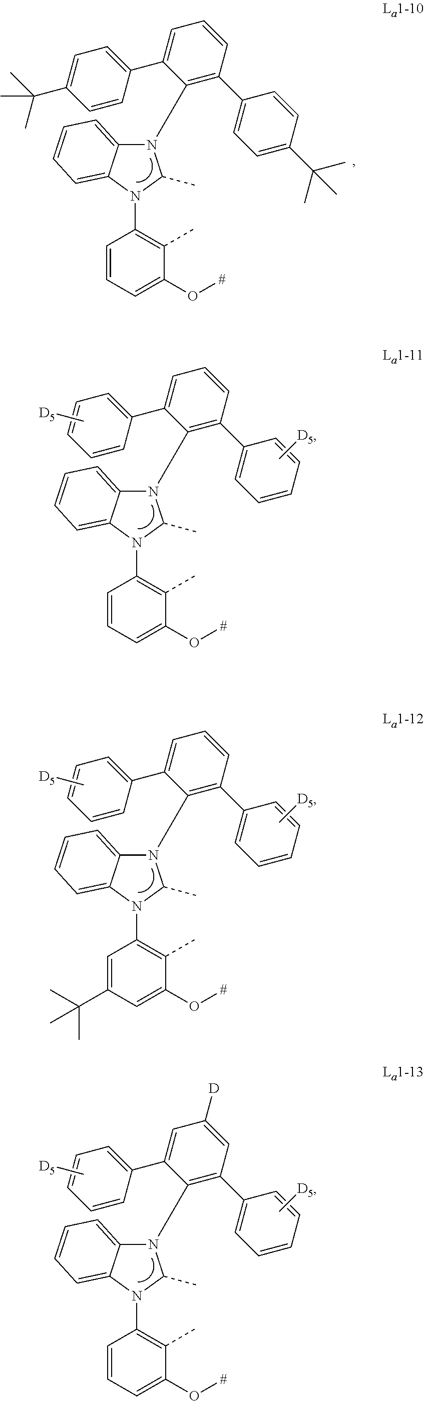 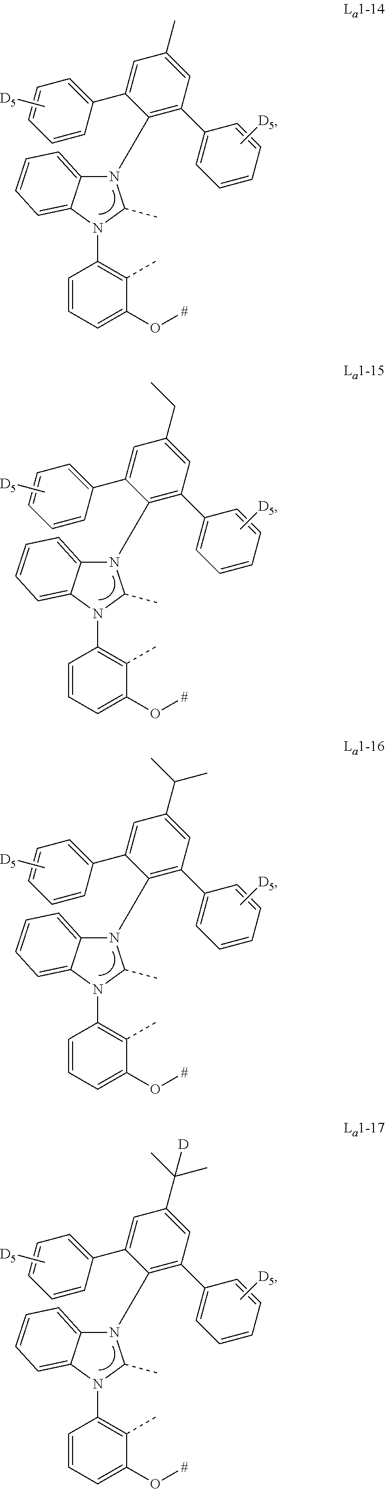 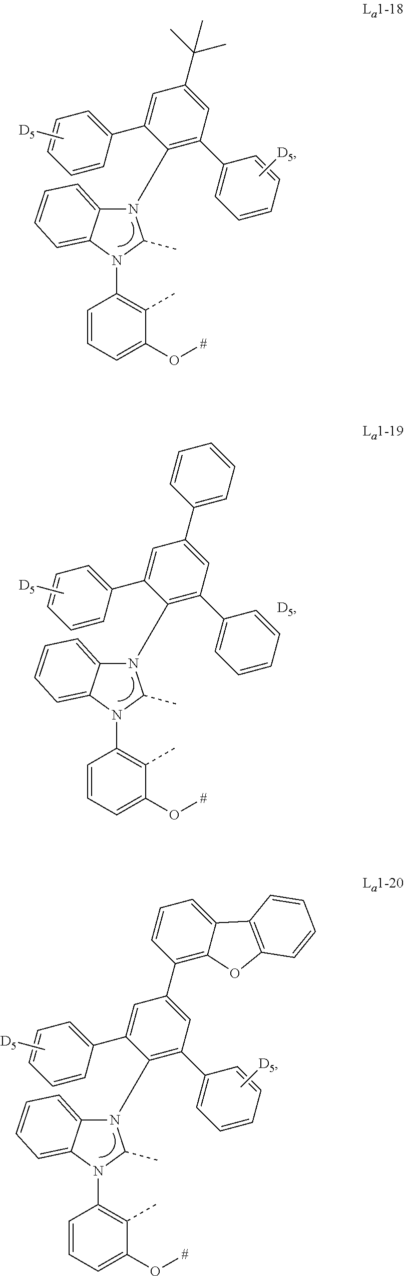 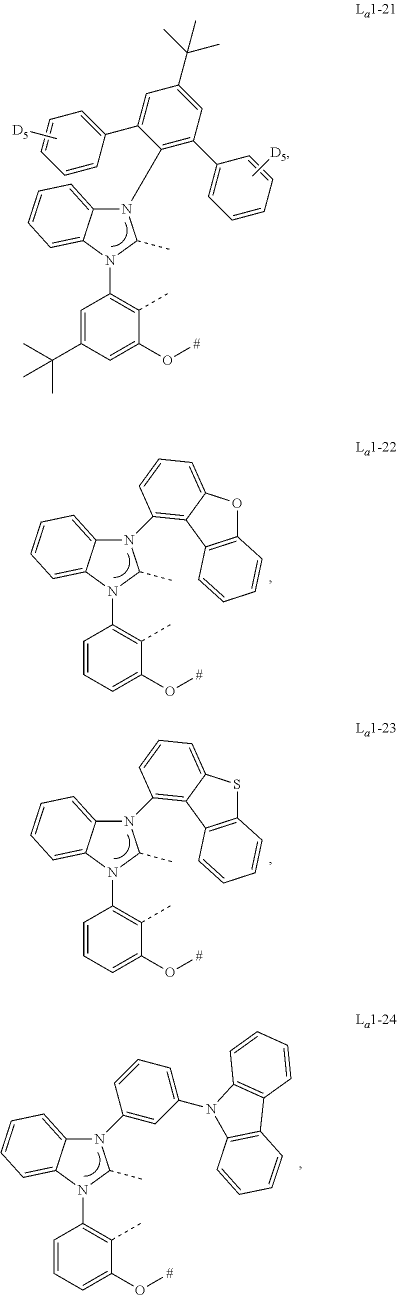 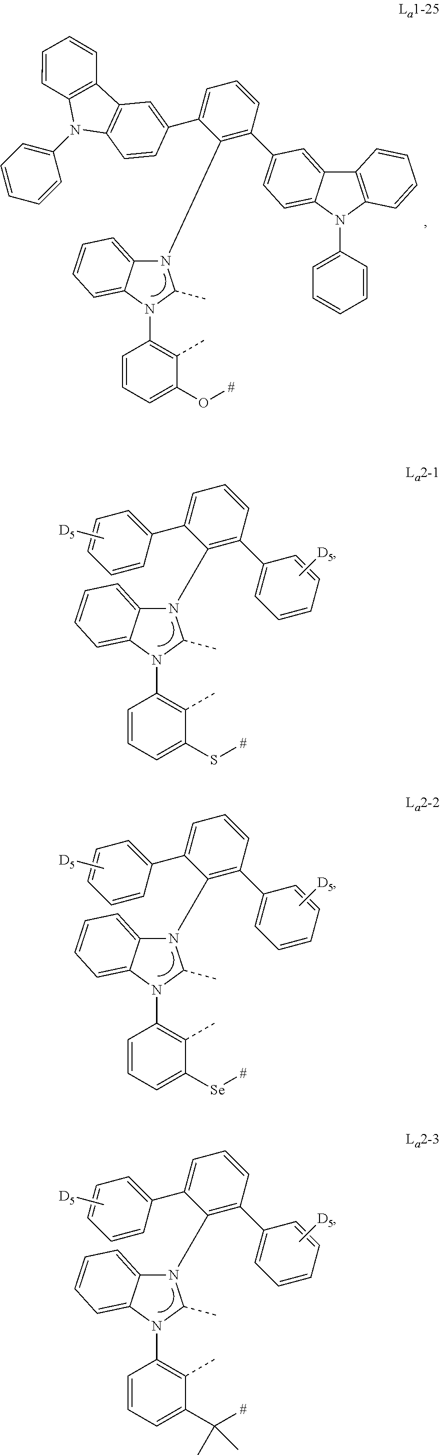 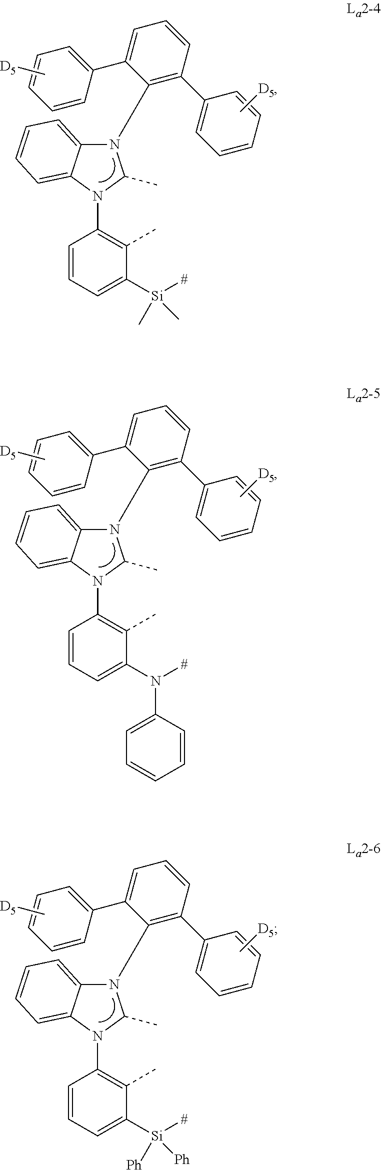
wherein “#” in each of the structures of Lₐ1-1 to Lₐ1-25 and Lₐ2-1 to Lₐ2-6 represents a position where L_{b} is joined;
the L_{b} is selected from the group consisting of L_{b}1-1 to L_{b}1-8 and L_{b}2-1 to L_{b}2-22: 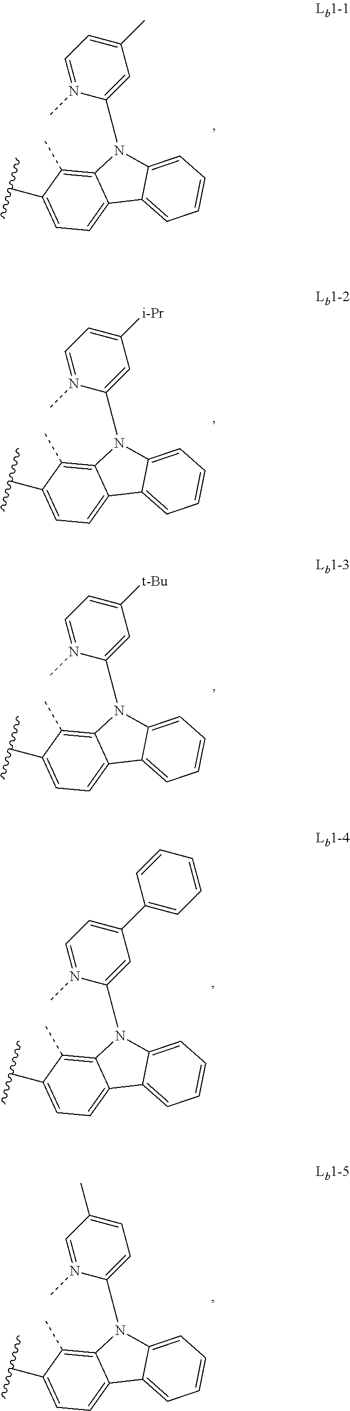 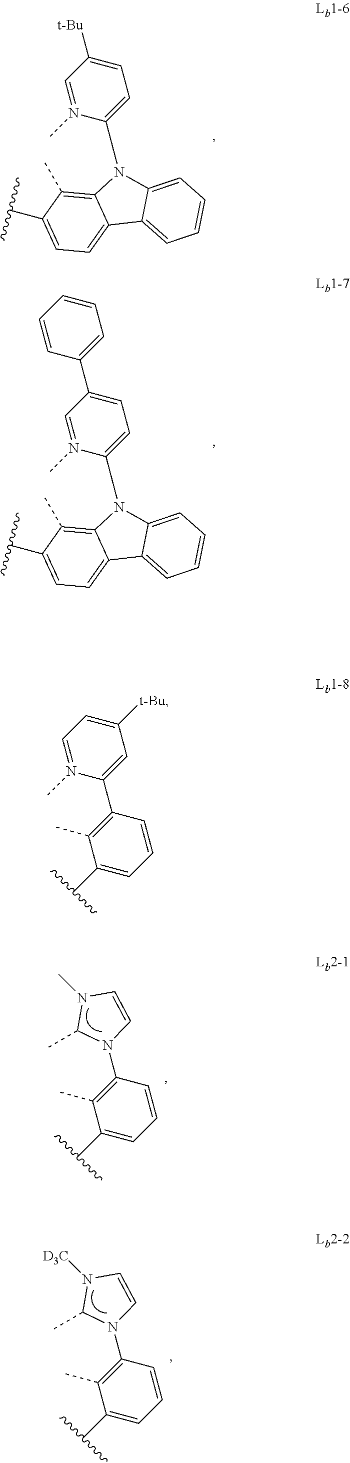 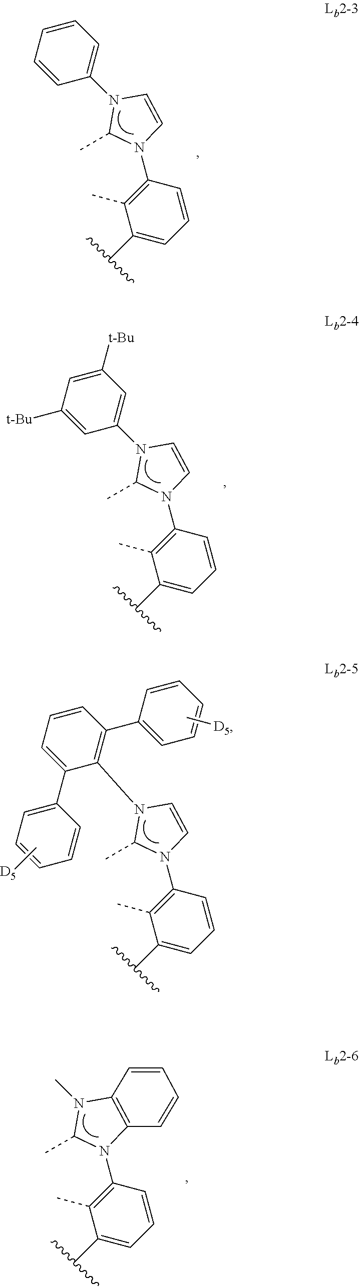 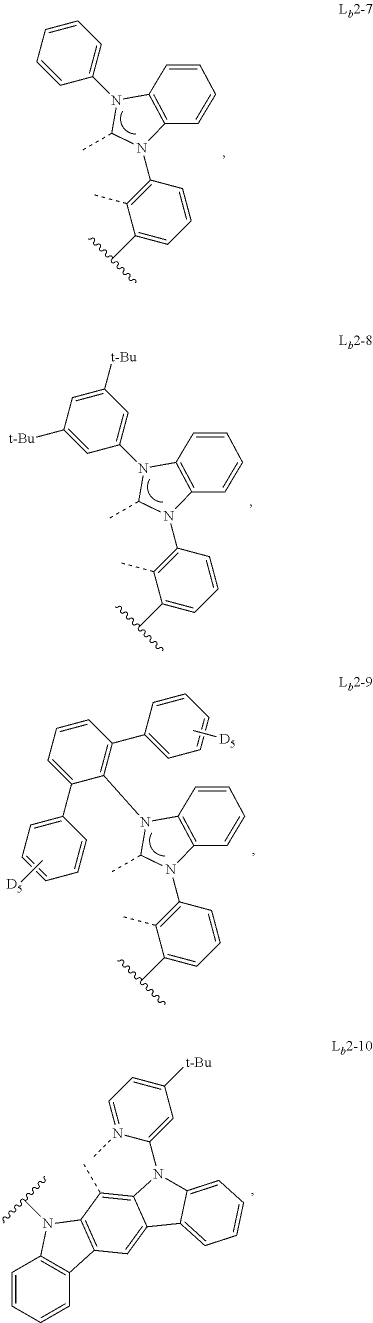 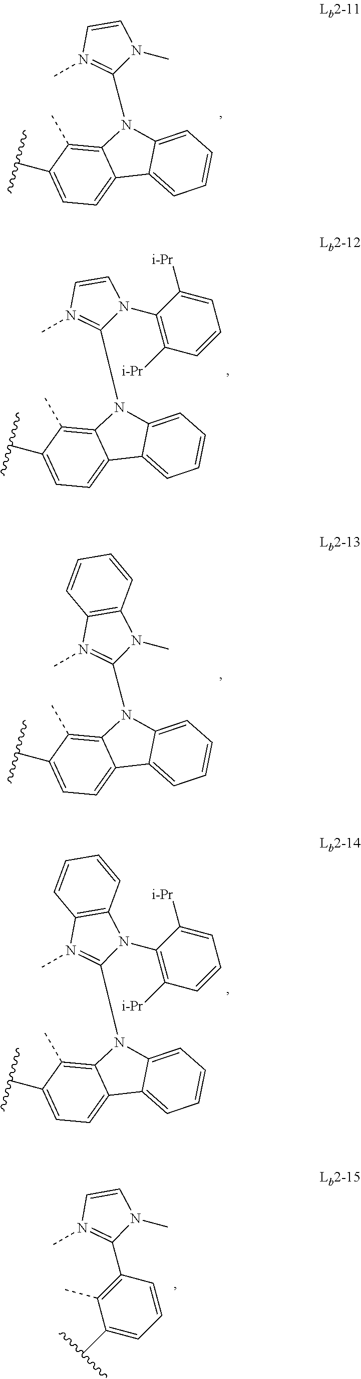 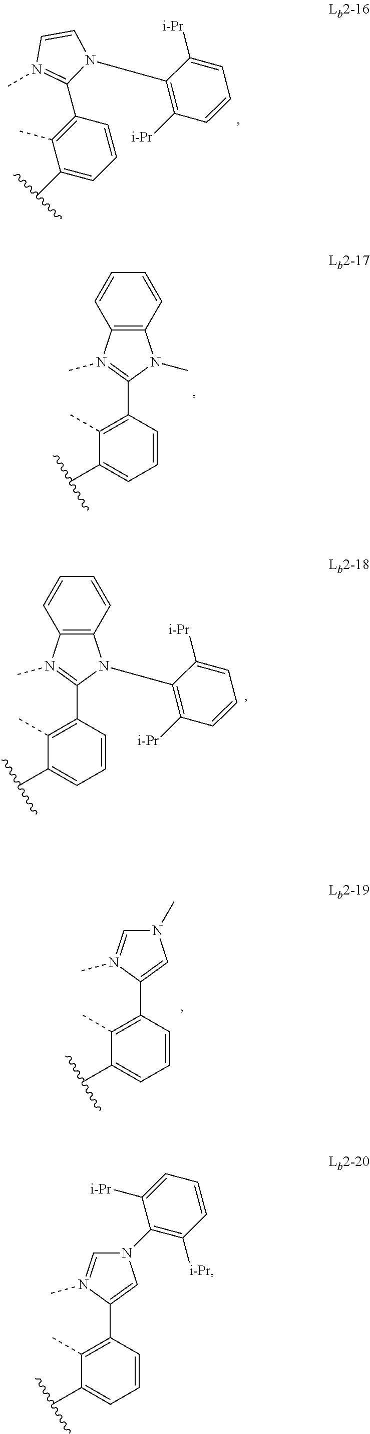 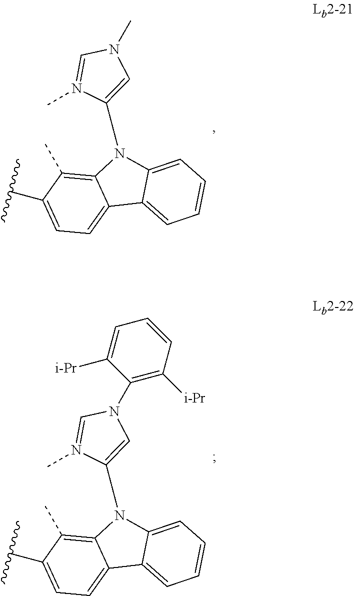
wherein “ [symbol] ” in each of the structures of L_{b}1-1 to L_{b}1-8 and L_{b}2-1 to L_{b}2-22 represents a position where “#” in Lₐ is joined;
in the structures, “t-Bu” represents t-butyl, and “i-Pr” represents isopropyl;
preferably, the platinum metal complex is selected from the group consisting of Pt1 to Pt81, wherein Pt1 to Pt81 each have the structure represented by Pt(Lₐ)(L_{b}), wherein Lₐ and L_{b} are selected from the structures shown in the following table, respectively:

| Platinum | | | Platinum | | |
|---|---|---|---|---|---|
| Metal | | | Metal | | |
| Complex No. | Lₐ | L_{b} | Complex No. | Lₐ | L_{b} |
| Pt1 | Lₐ1-6 | L_{b}1-1 | Pt2 | Lₐ1-6 | L_{b}1-2 |
| Pt3 | Lₐ1-6 | L_{b}1-3 | Pt4 | Lₐ1-6 | L_{b}1-4 |
| Pt5 | Lₐ1-6 | L_{b}1-5 | Pt6 | Lₐ1-6 | L_{b}1-6 |
| Pt7 | Lₐ1-6 | L_{b}1-7 | Pt8 | Lₐ1-6 | L_{b}1-8 |
| Pt9 | Lₐ1-11 | L_{b}1-1 | Pt10 | Lₐ1-11 | L_{b}1-2 |
| Pt11 | Lₐ1-11 | L_{b}1-3 | Pt12 | Lₐ1-11 | L_{b}1-4 |
| Pt13 | Lₐ1-11 | L_{b}1-5 | Pt14 | Lₐ1-11 | L_{b}1-6 |
| Pt15 | Lₐ1-11 | L_{b}1-7 | Pt16 | Lₐ1-11 | L_{b}1-8 |
| Pt17 | Lₐ1-12 | L_{b}1-1 | Pt18 | Lₐ1-12 | L_{b}1-2 |
| Pt19 | Lₐ1-12 | L_{b}1-3 | Pt20 | Lₐ1-12 | L_{b}1-4 |
| Pt21 | Lₐ1-12 | L_{b}1-5 | Pt22 | Lₐ1-12 | L_{b}1-6 |
| Pt23 | Lₐ1-12 | L_{b}1-7 | Pt24 | Lₐ1-12 | L_{b}1-8 |
| Pt25 | Lₐ1-18 | L_{b}1-1 | Pt26 | Lₐ1-18 | L_{b}1-2 |
| Pt27 | Lₐ1-18 | L_{b}1-3 | Pt28 | Lₐ1-18 | L_{b}1-4 |
| Pt29 | Lₐ1-18 | L_{b}1-5 | Pt30 | Lₐ1-18 | L_{b}1-6 |
| Pt31 | Lₐ1-18 | L_{b}1-7 | Pt32 | Lₐ1-18 | L_{b}1-8 |
| Pt33 | Lₐ1-18 | L_{b}2-1 | Pt34 | Lₐ1-18 | L_{b}2-2 |
| Pt35 | Lₐ1-18 | L_{b}2-3 | Pt36 | Lₐ1-18 | L_{b}2-4 |
| Pt37 | Lₐ1-18 | L_{b}2-5 | Pt38 | Lₐ1-18 | L_{b}2-6 |
| Pt39 | Lₐ1-18 | L_{b}2-7 | Pt40 | Lₐ1-18 | L_{b}2-8 |
| Pt41 | Lₐ1-18 | L_{b}2-9 | Pt42 | Lₐ1-18 | L_{b}2-10 |
| Pt43 | Lₐ1-18 | L_{b}2-11 | Pt44 | Lₐ1-18 | L_{b}2-12 |
| Pt45 | Lₐ1-18 | L_{b}2-13 | Pt46 | Lₐ1-18 | L_{b}2-14 |
| Pt47 | Lₐ1-18 | L_{b}2-15 | Pt48 | Lₐ1-18 | L_{b}2-16 |
| Pt49 | Lₐ1-18 | L_{b}2-17 | Pt50 | Lₐ1-18 | L_{b}2-18 |
| Pt51 | Lₐ1-18 | L_{b}2-19 | Pt52 | Lₐ1-18 | L_{b}2-20 |
| Pt53 | Lₐ1-18 | L_{b}2-21 | Pt54 | Lₐ1-18 | L_{b}2-22 |
| Pt55 | Lₐ1-1 | L_{b}1-3 | Pt56 | Lₐ1-2 | L_{b}1-3 |
| Pt57 | Lₐ1-3 | L_{b}1-3 | Pt58 | Lₐ1-4 | L_{b}1-3 |
| Pt59 | Lₐ1-5 | L_{b}1-3 | Pt60 | Lₐ1-7 | L_{b}1-3 |
| Pt61 | Lₐ1-8 | L_{b}1-3 | Pt62 | Lₐ1-9 | L_{b}1-3 |
| Pt63 | Lₐ1-10 | L_{b}1-3 | Pt64 | Lₐ1-13 | L_{b}1-3 |
| Pt65 | Lₐ1-14 | L_{b}1-3 | Pt66 | Lₐ1-15 | L_{b}1-3 |
| Pt67 | Lₐ1-16 | L_{b}1-3 | Pt68 | Lₐ1-17 | L_{b}1-3 |
| Pt69 | Lₐ1-19 | L_{b}1-3 | Pt70 | Lₐ1-20 | L_{b}1-3 |
| Pt71 | Lₐ1-21 | L_{b}1-3 | Pt72 | Lₐ1-22 | L_{b}1-3 |
| Pt73 | Lₐ1-23 | L_{b}1-3 | Pt74 | Lₐ1-24 | L_{b}1-3 |
| Pt75 | Lₐ1-25 | L_{b}1-3 | Pt76 | Lₐ2-1 | L_{b}1-3 |
| Pt77 | Lₐ2-2 | L_{b}1-3 | Pt78 | Lₐ2-3 | L_{b}1-3 |
| Pt79 | Lₐ2-4 | L_{b}1-3 | Pt80 | Lₐ2-5 | L_{b}1-3. |
| Pt81 | Lₐ2-6 | L_{b}1-3 | | | |

15. The organic electroluminescent device according to claim 1, wherein the first host compound has a structure represented by one of Formula 5 to Formula 7: 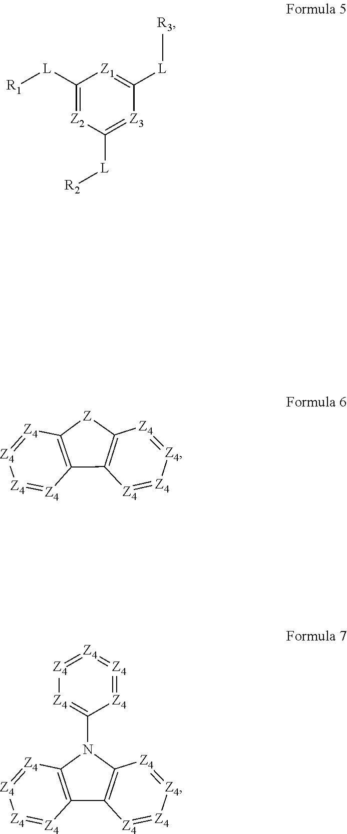
wherein in Formula 5, Z₁ to Z₃ are, at each occurrence identically or differently, selected from CR₄ or N, and at least one of Z₁ to Z₃ is N;
L is, at each occurrence identically or differently, selected from the group consisting of: a single bond, substituted or unsubstituted arylene having 6 to 30 carbon atoms, substituted or unsubstituted heteroarylene having 3 to 30 carbon atoms and combinations thereof;
in Formula 6 and Formula 7, Z₄ is, at each occurrence identically or differently, selected from CR₄ or N, and at least one Z₄ is N;
Z is, at each occurrence identically or differently, selected from O or S;
R₁ to R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R₄ can be optionally joined to form a ring;
preferably, the first host compound has a structure represented by Formula 5-1 or Formula 6-1: 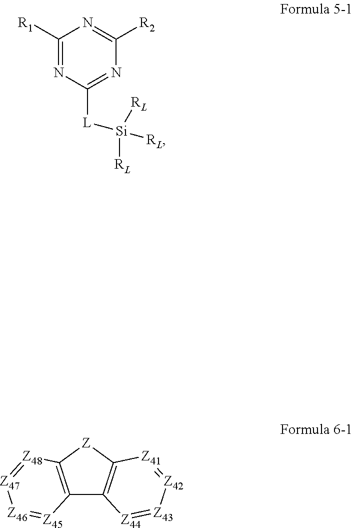
wherein in Formula 5-1,
R₁ and R₂ are each independently selected from substituted or unsubstituted heteroaryl having 3 to 30 carbon atoms;
L is selected from a single bond, substituted or unsubstituted arylene having 6 to 30 carbon atoms, substituted or unsubstituted heteroarylene having 3 to 30 carbon atoms or a combination thereof;
in Formula 6-1,
Z is selected from O or S;
Z₄₁ to Z₄₈ are, at each occurrence identically or differently, selected from CR₄, CR₄′ or N, at least one of Z₄₁ to Z₄₈ is selected from N, and at least one of Z₄₁ to Z₄₈ is selected from CR₄′;
R₄′ is, at each occurrence identically or differently, selected from substituted or unsubstituted aryl having 6 to 30 carbon atoms, substituted or unsubstituted heteroaryl having 3 to 30 carbon atoms or a combination thereof;
R_{L} and R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R₄ can be optionally joined to form a ring;
more preferably, the first host compound is selected from the group consisting of Compound N-1-1 to Compound N-1-60, Compound N-2-1 to Compound N-2-35 and Compound N-3-1 to Compound N-3-9: 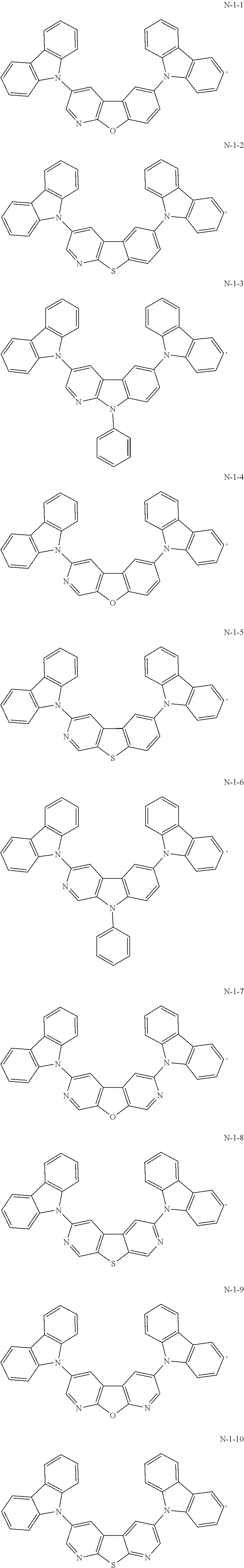 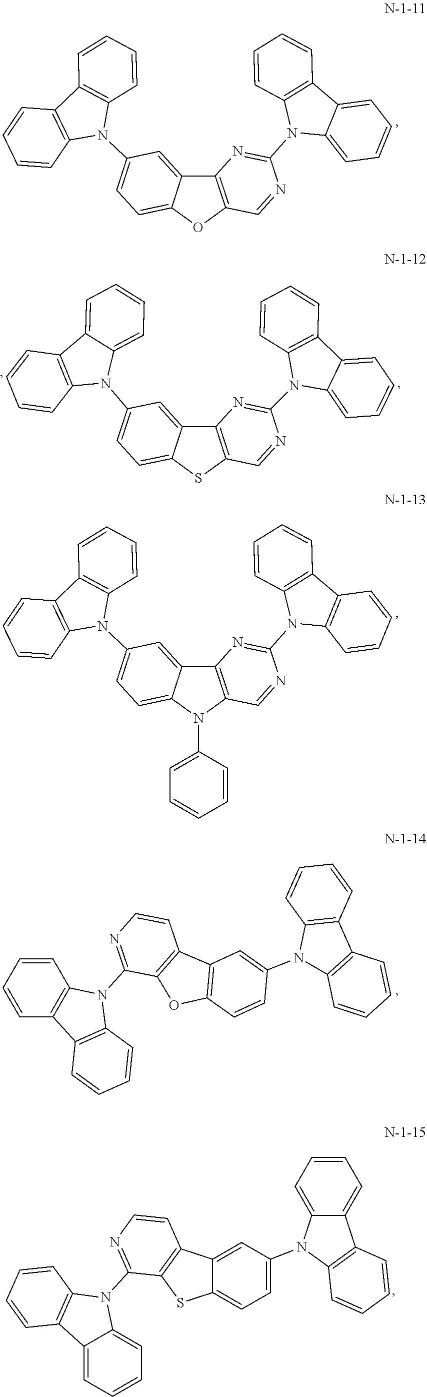 [SMILES: c1ccc2c(c1)c1ccccc1n2-c1ccc2oc3cnc(-n4c5ccccc5c5ccccc54)nc3c2c1 ; c1ccc2c(c1)c1ccccc1n2-c1ccc2sc3cnc(-n4c5ccccc5c5ccccc54)nc3c2c1 ; c1ccc(-n2c3ccc(-n4c5ccccc5c5ccccc54)cc3c3nc(-n4c5ccccc5c5ccccc54)ncc32)cc1 ; c1ccc2c(c1)c1ccccc1n2-c1ccc2oc3c(-n4c5ccccc5c5ccccc54)nccc3c2c1 ; c1ccc2c(c1)c1ccccc1n2-c1ccc2sc3c(-n4c5ccccc5c5ccccc54)nccc3c2c1] 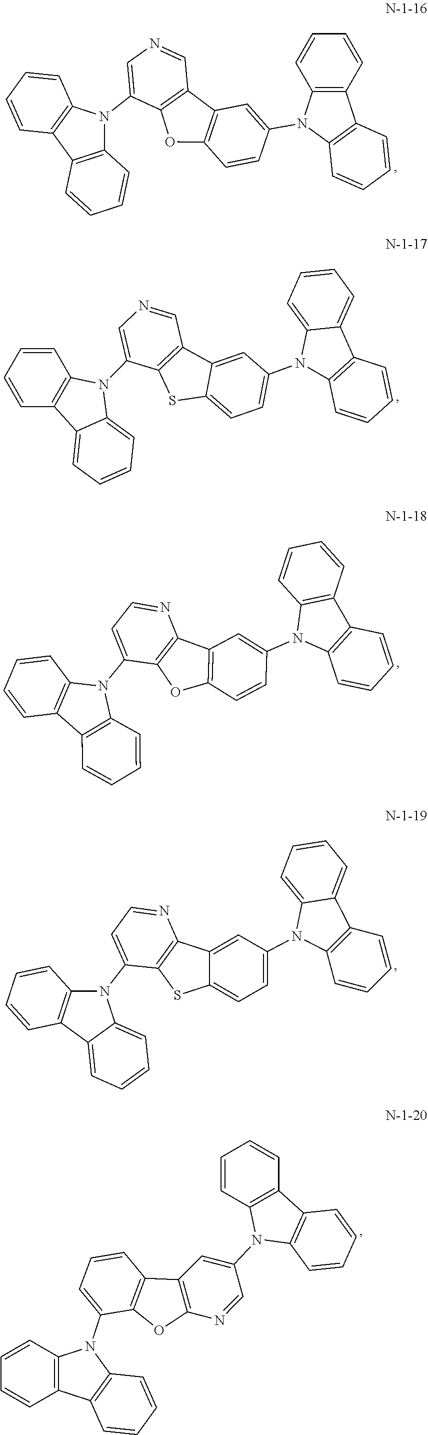 [SMILES: c1ccc2c(c1)c1ccccc1n2-c1ccc2oc3c(-n4c5ccccc5c5ccccc54)cncc3c2c1 ; c1ccc2c(c1)c1ccccc1n2-c1ccc2sc3c(-n4c5ccccc5c5ccccc54)cncc3c2c1 ; c1ccc2c(c1)c1ccccc1n2-c1ccc2oc3c(-n4c5ccccc5c5ccccc54)ccnc3c2c1 ; c1ccc2c(c1)c1ccccc1n2-c1ccc2sc3c(-n4c5ccccc5c5ccccc54)ccnc3c2c1 ; c1cc(-n2c3ccccc3c3ccccc32)c2oc3ncc(-n4c5ccccc5c5ccccc54)cc3c2c1] 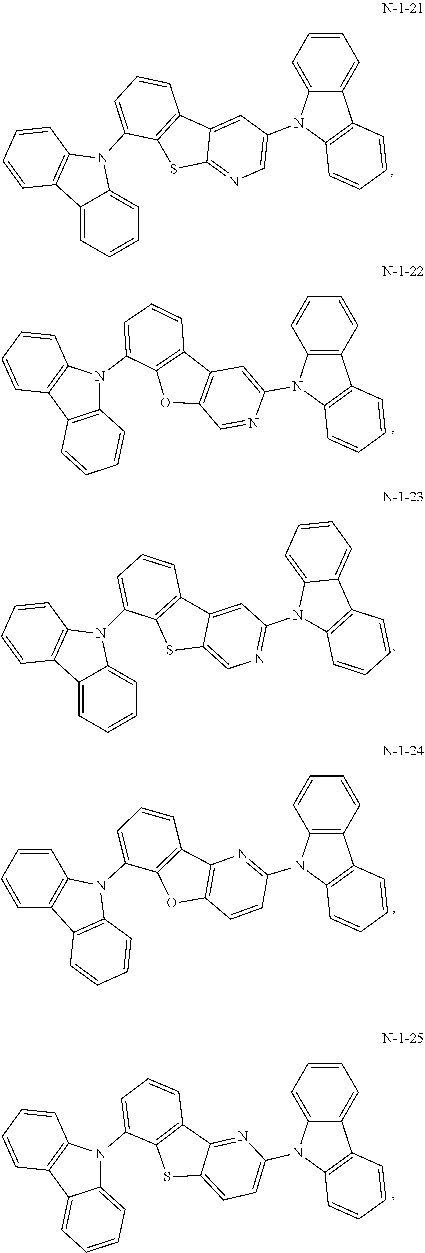 [SMILES: c1cc(-n2c3ccccc3c3ccccc32)c2sc3ncc(-n4c5ccccc5c5ccccc54)cc3c2c1 ; c1cc(-n2c3ccccc3c3ccccc32)c2oc3cnc(-n4c5ccccc5c5ccccc54)cc3c2c1 ; c1cc(-n2c3ccccc3c3ccccc32)c2sc3cnc(-n4c5ccccc5c5ccccc54)cc3c2c1 ; c1cc(-n2c3ccccc3c3ccccc32)c2oc3ccc(-n4c5ccccc5c5ccccc54)nc3c2c1 ; c1cc(-n2c3ccccc3c3ccccc32)c2sc3ccc(-n4c5ccccc5c5ccccc54)nc3c2c1] 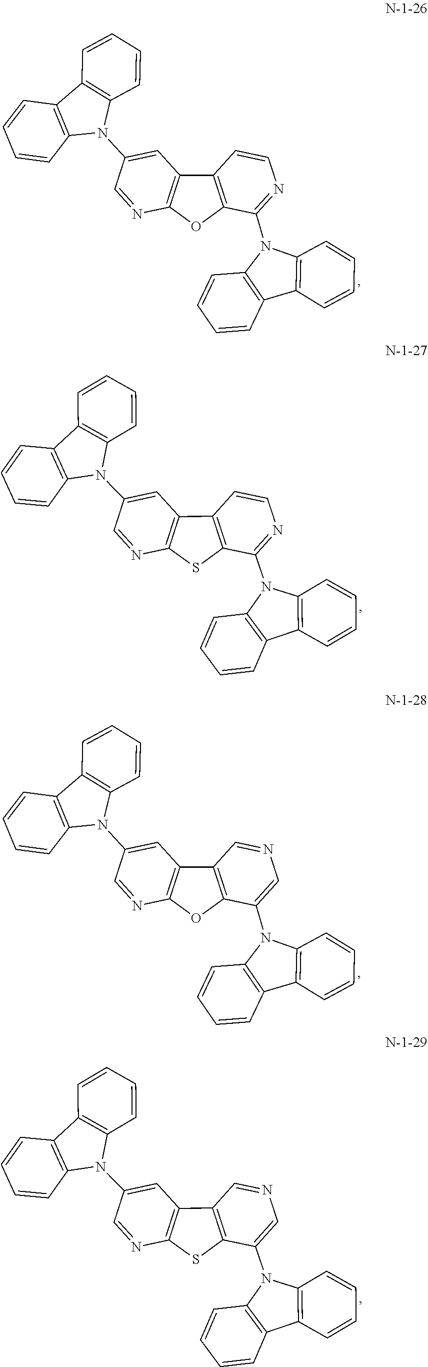 [SMILES: c1ccc2c(c1)c1ccccc1n2-c1cnc2oc3c(-n4c5ccccc5c5ccccc54)nccc3c2c1 ; c1ccc2c(c1)c1ccccc1n2-c1cnc2sc3c(-n4c5ccccc5c5ccccc54)nccc3c2c1 ; c1ccc2c(c1)c1ccccc1n2-c1cnc2oc3c(-n4c5ccccc5c5ccccc54)cncc3c2c1 ; c1ccc2c(c1)c1ccccc1n2-c1cnc2sc3c(-n4c5ccccc5c5ccccc54)cncc3c2c1] 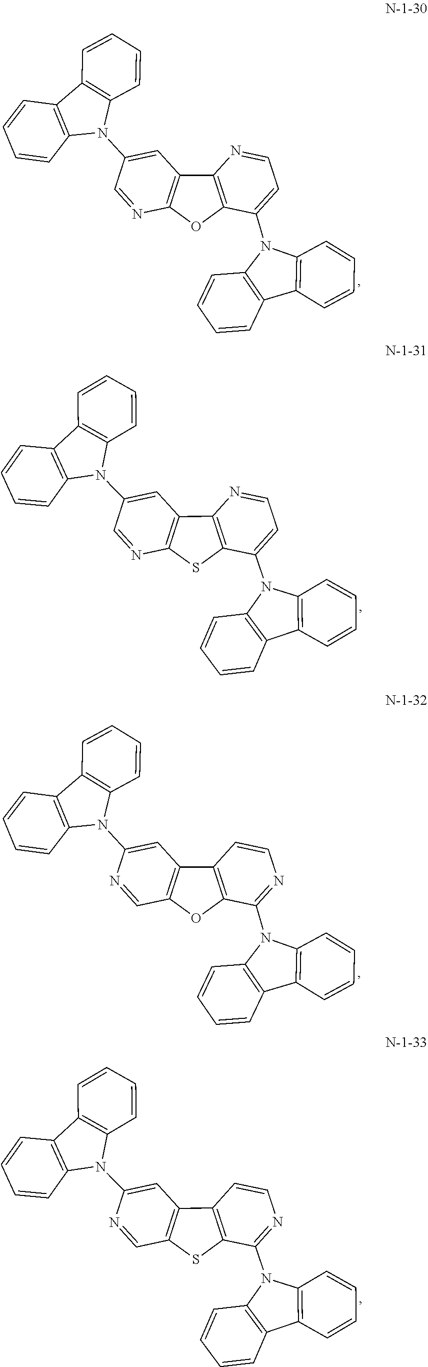 [SMILES: c1ccc2c(c1)c1ccccc1n2-c1cnc2oc3c(-n4c5ccccc5c5ccccc54)ccnc3c2c1 ; c1ccc2c(c1)c1ccccc1n2-c1cnc2sc3c(-n4c5ccccc5c5ccccc54)ccnc3c2c1 ; c1ccc2c(c1)c1ccccc1n2-c1cc2c(cn1)oc1c(-n3c4ccccc4c4ccccc43)nccc12 ; c1ccc2c(c1)c1ccccc1n2-c1cc2c(cn1)sc1c(-n3c4ccccc4c4ccccc43)nccc12] 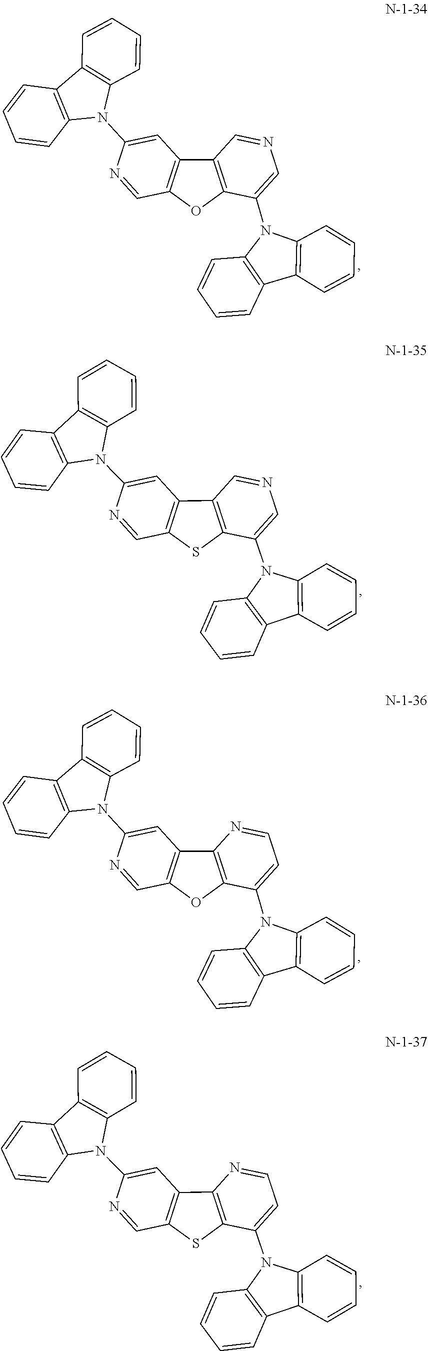 [SMILES: c1ccc2c(c1)c1ccccc1n2-c1cc2c(cn1)oc1c(-n3c4ccccc4c4ccccc43)cncc12 ; c1ccc2c(c1)c1ccccc1n2-c1cc2c(cn1)sc1c(-n3c4ccccc4c4ccccc43)cncc12 ; c1ccc2c(c1)c1ccccc1n2-c1cc2c(cn1)oc1c(-n3c4ccccc4c4ccccc43)ccnc12 ; c1ccc2c(c1)c1ccccc1n2-c1cc2c(cn1)sc1c(-n3c4ccccc4c4ccccc43)ccnc12] 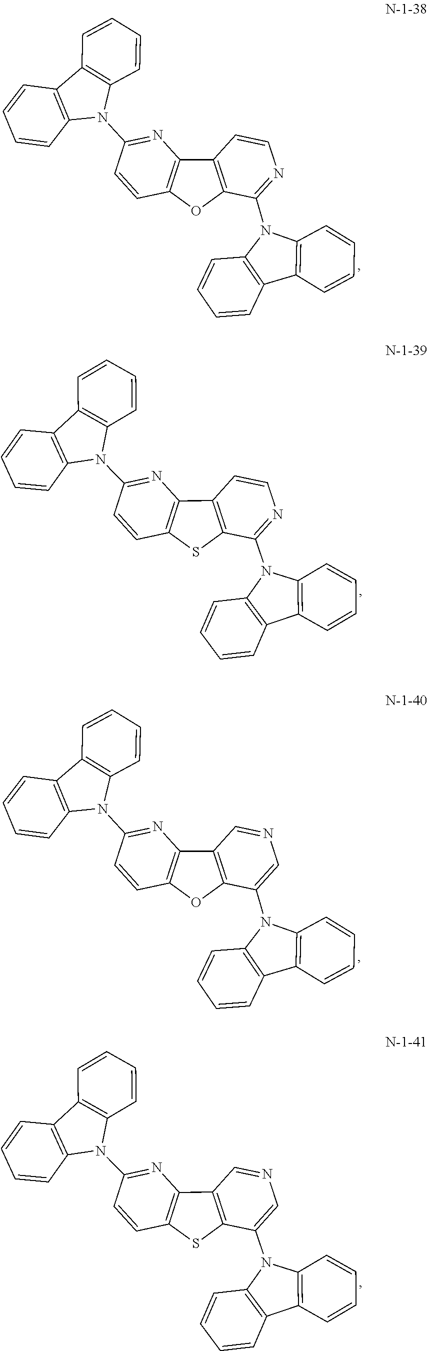 [SMILES: c1ccc2c(c1)c1ccccc1n2-c1ccc2oc3c(-n4c5ccccc5c5ccccc54)nccc3c2n1 ; c1ccc2c(c1)c1ccccc1n2-c1ccc2sc3c(-n4c5ccccc5c5ccccc54)nccc3c2n1 ; c1ccc2c(c1)c1ccccc1n2-c1ccc2oc3c(-n4c5ccccc5c5ccccc54)cncc3c2n1 ; c1ccc2c(c1)c1ccccc1n2-c1ccc2sc3c(-n4c5ccccc5c5ccccc54)cncc3c2n1] 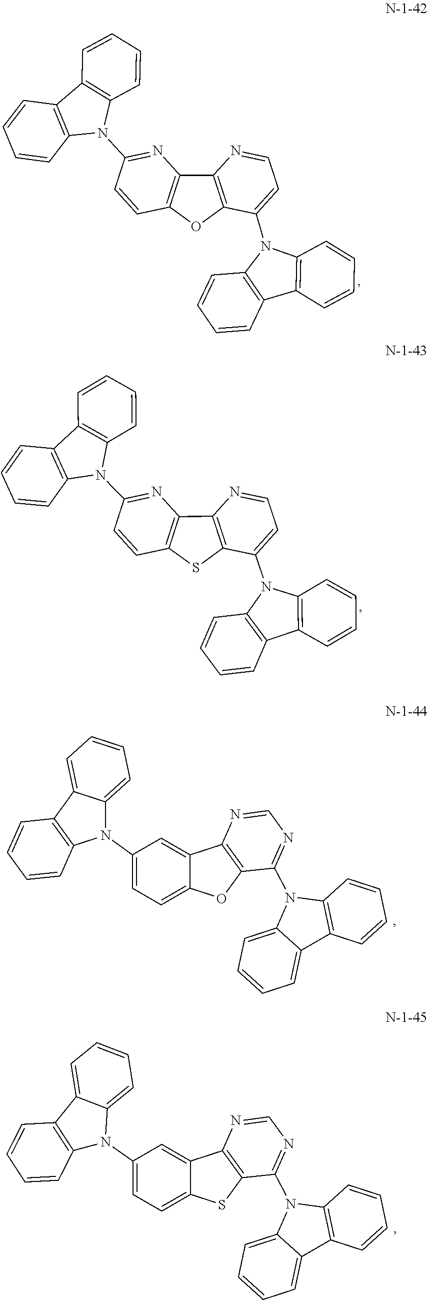 [SMILES: c1ccc2c(c1)c1ccccc1n2-c1ccc2oc3c(-n4c5ccccc5c5ccccc54)ccnc3c2n1 ; c1ccc2c(c1)c1ccccc1n2-c1ccc2sc3c(-n4c5ccccc5c5ccccc54)ccnc3c2n1 ; c1ccc2c(c1)c1ccccc1n2-c1ccc2oc3c(-n4c5ccccc5c5ccccc54)ncnc3c2c1 ; c1ccc2c(c1)c1ccccc1n2-c1ccc2sc3c(-n4c5ccccc5c5ccccc54)ncnc3c2c1] 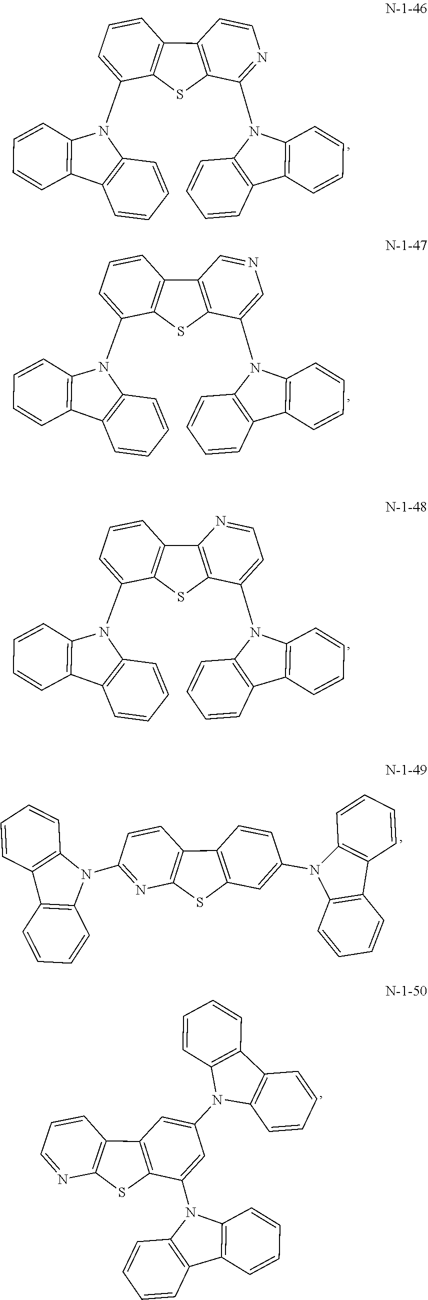 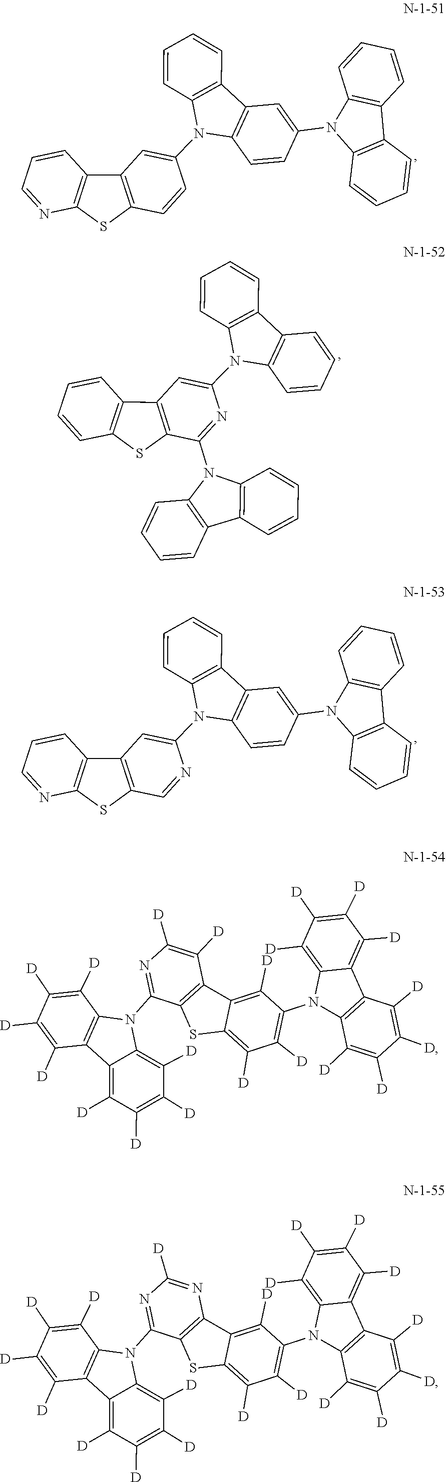 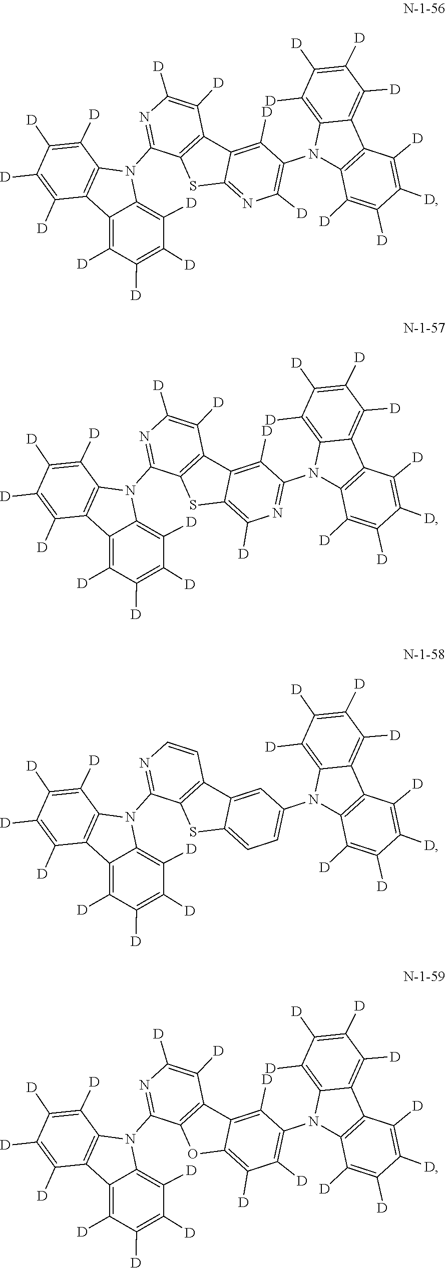 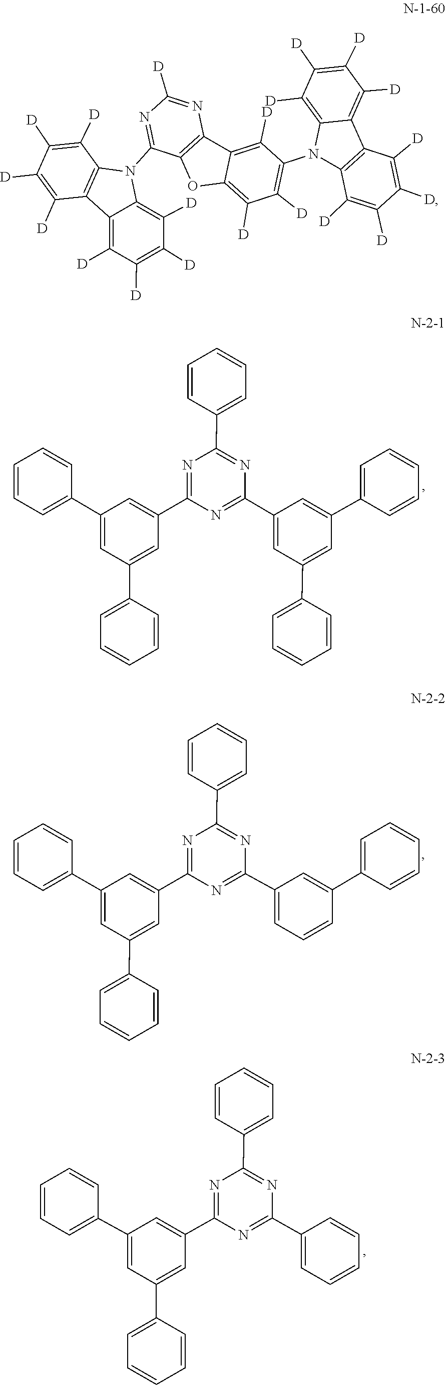 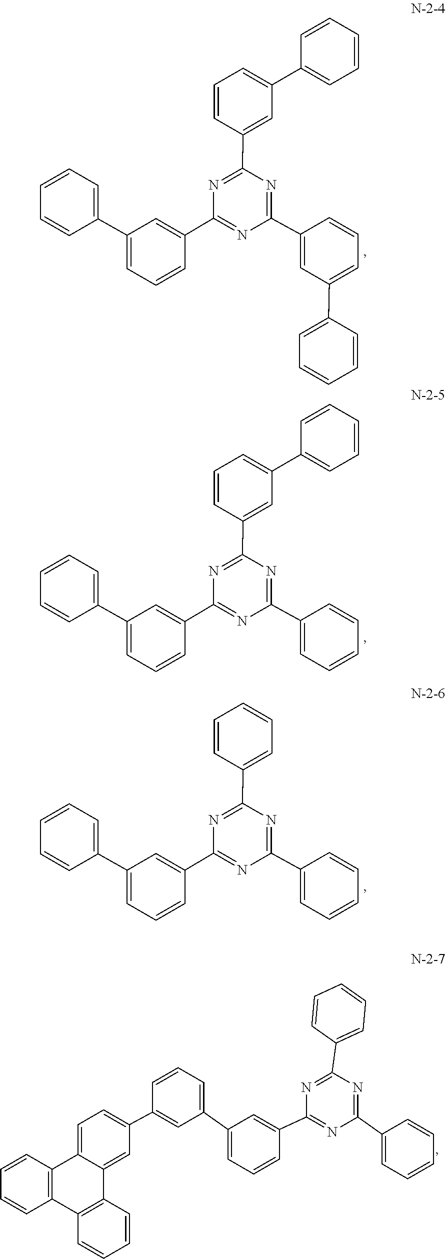 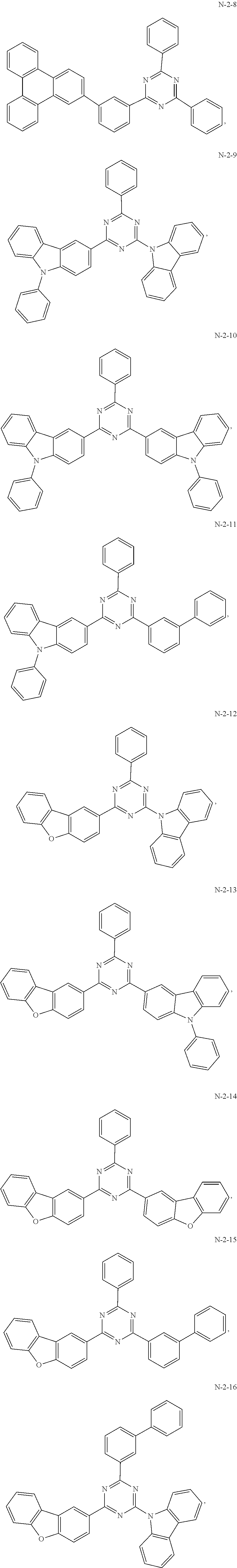 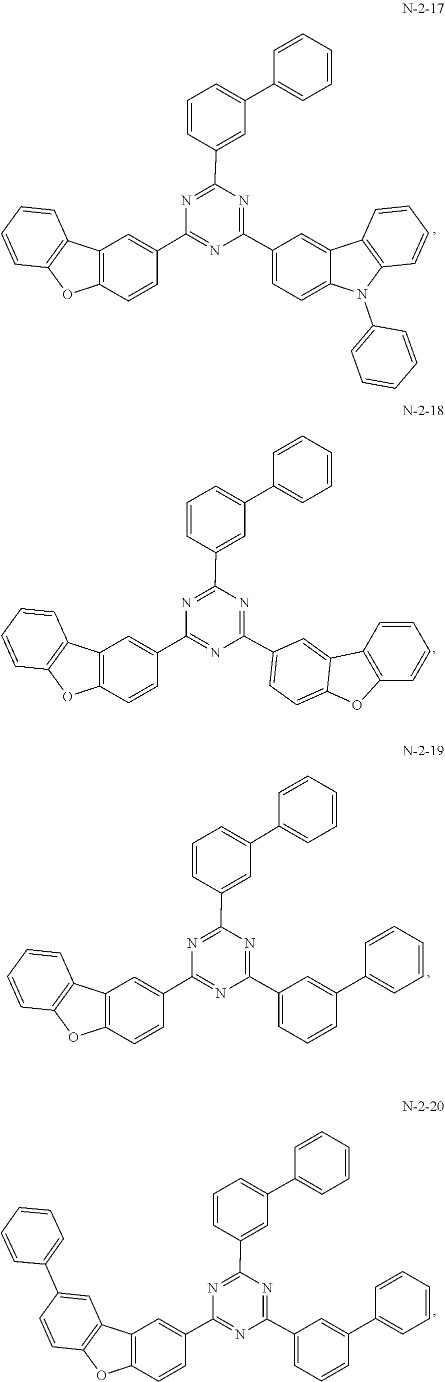 [SMILES: c1ccc(-c2cccc(-c3nc(-c4ccc5oc6ccccc6c5c4)nc(-c4ccc5c(c4)c4ccccc4n5-c4ccccc4)n3)c2)cc1 ; c1ccc(-c2cccc(-c3nc(-c4ccc5oc6ccccc6c5c4)nc(-c4ccc5oc6ccccc6c5c4)n3)c2)cc1 ; c1ccc(-c2cccc(-c3nc(-c4cccc(-c5ccccc5)c4)nc(-c4ccc5oc6ccccc6c5c4)n3)c2)cc1 ; c1ccc(-c2cccc(-c3nc(-c4cccc(-c5ccccc5)c4)nc(-c4ccc5oc6ccc(-c7ccccc7)cc6c5c4)n3)c2)cc1] 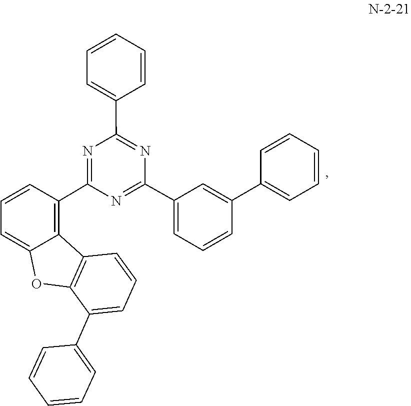 [SMILES: c1ccc(-c2cccc(-c3nc(-c4ccccc4)nc(-c4cccc5oc6c(-c7ccccc7)cccc6c45)n3)c2)cc1] 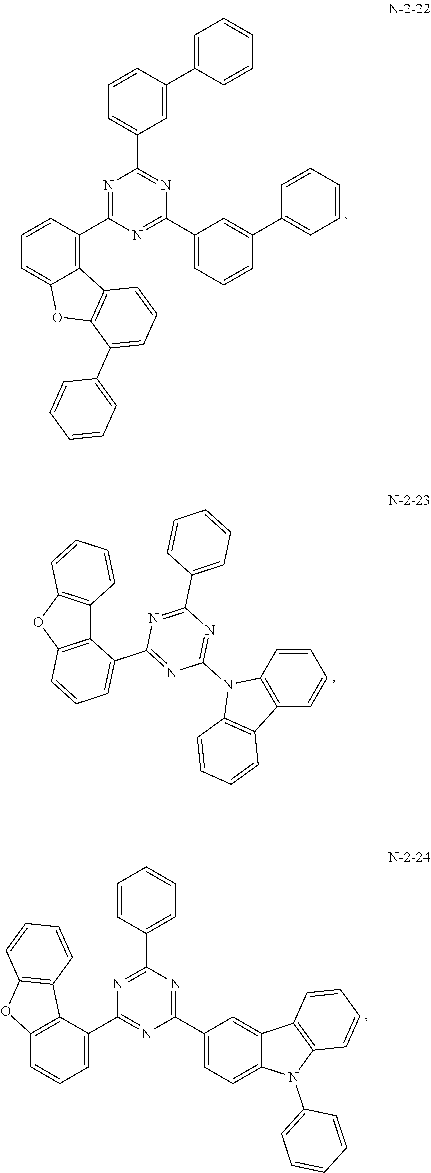 [SMILES: c1ccc(-c2cccc(-c3nc(-c4cccc(-c5ccccc5)c4)nc(-c4cccc5oc6c(-c7ccccc7)cccc6c45)n3)c2)cc1 ; c1ccc(-c2nc(-c3cccc4oc5ccccc5c34)nc(-n3c4ccccc4c4ccccc43)n2)cc1 ; c1ccc(-c2nc(-c3ccc4c(c3)c3ccccc3n4-c3ccccc3)nc(-c3cccc4oc5ccccc5c34)n2)cc1] 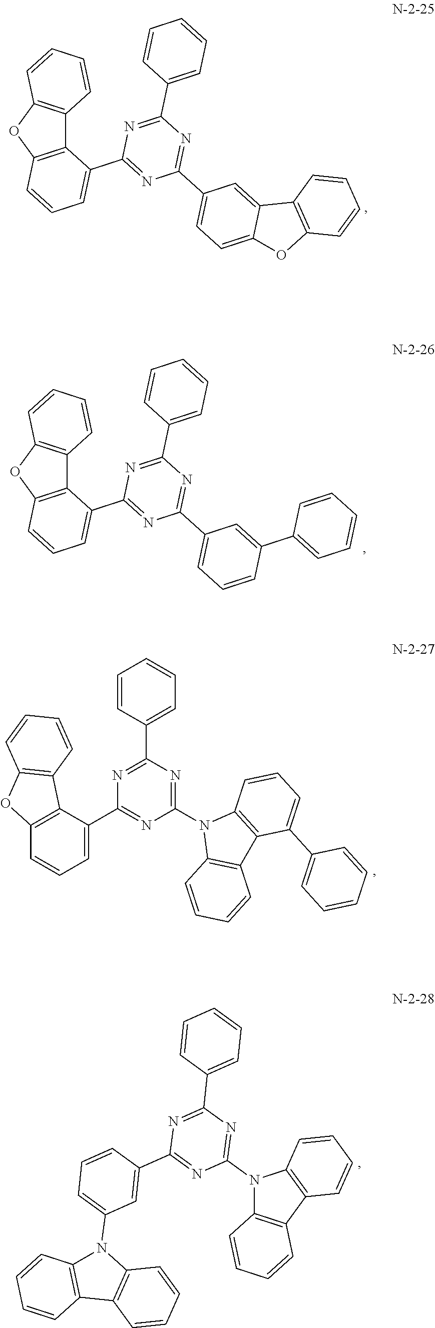 [SMILES: c1ccc(-c2nc(-c3ccc4oc5ccccc5c4c3)nc(-c3cccc4oc5ccccc5c34)n2)cc1 ; c1ccc(-c2cccc(-c3nc(-c4ccccc4)nc(-c4cccc5oc6ccccc6c45)n3)c2)cc1 ; c1ccc(-c2nc(-c3cccc4oc5ccccc5c34)nc(-n3c4ccccc4c4c(-c5ccccc5)cccc43)n2)cc1 ; c1ccc(-c2nc(-c3cccc(-n4c5ccccc5c5ccccc54)c3)nc(-n3c4ccccc4c4ccccc43)n2)cc1] 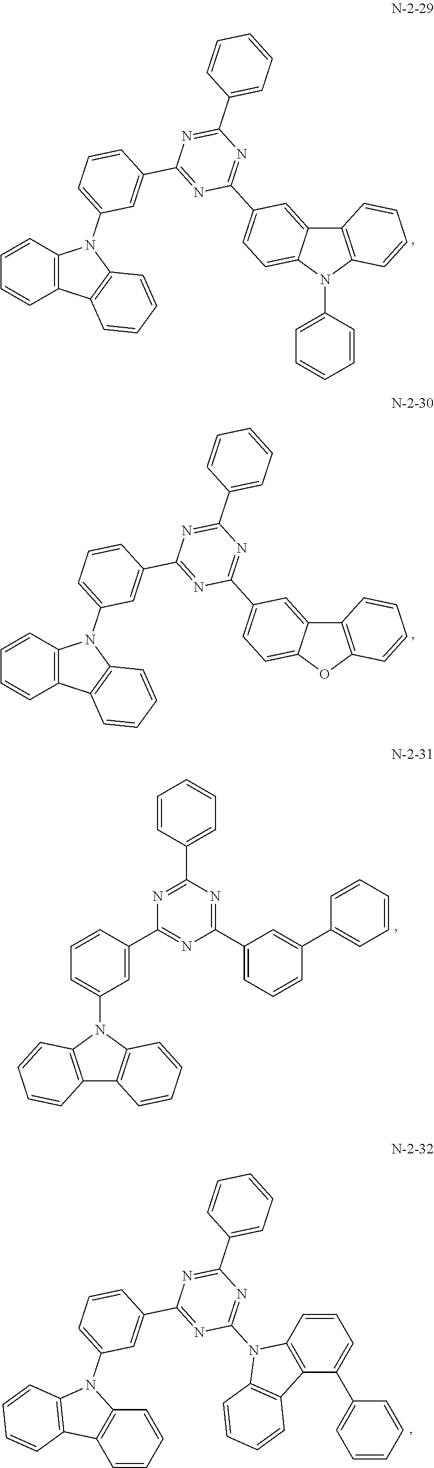 [SMILES: c1ccc(-c2nc(-c3cccc(-n4c5ccccc5c5ccccc54)c3)nc(-c3ccc4c(c3)c3ccccc3n4-c3ccccc3)n2)cc1 ; c1ccc(-c2nc(-c3cccc(-n4c5ccccc5c5ccccc54)c3)nc(-c3ccc4oc5ccccc5c4c3)n2)cc1 ; c1ccc(-c2cccc(-c3nc(-c4ccccc4)nc(-c4cccc(-n5c6ccccc6c6ccccc65)c4)n3)c2)cc1 ; c1ccc(-c2nc(-c3cccc(-n4c5ccccc5c5ccccc54)c3)nc(-n3c4ccccc4c4c(-c5ccccc5)cccc43)n2)cc1] 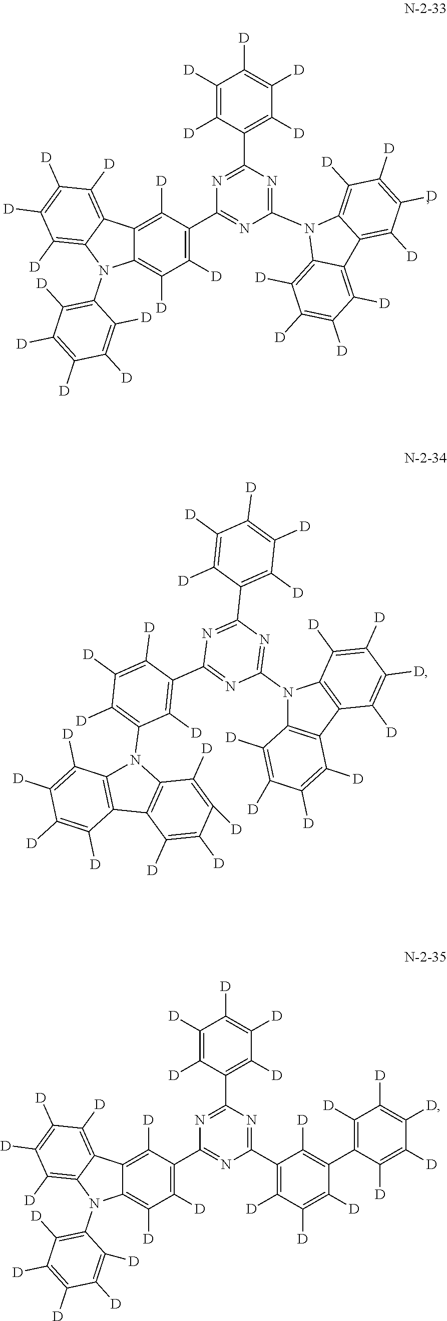 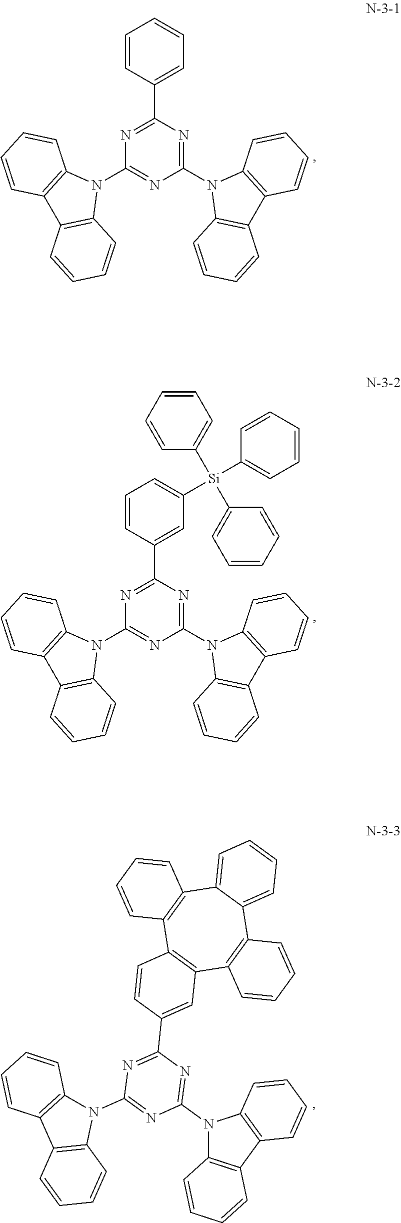 [SMILES: c1ccc(-c2nc(-n3c4ccccc4c4ccccc43)nc(-n3c4ccccc4c4ccccc43)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc2c(c1)-c1ccccc1-c1ccc(-c3nc(-n4c5ccccc5c5ccccc54)nc(-n4c5ccccc5c5ccccc54)n3)cc1-c1ccccc1-2] 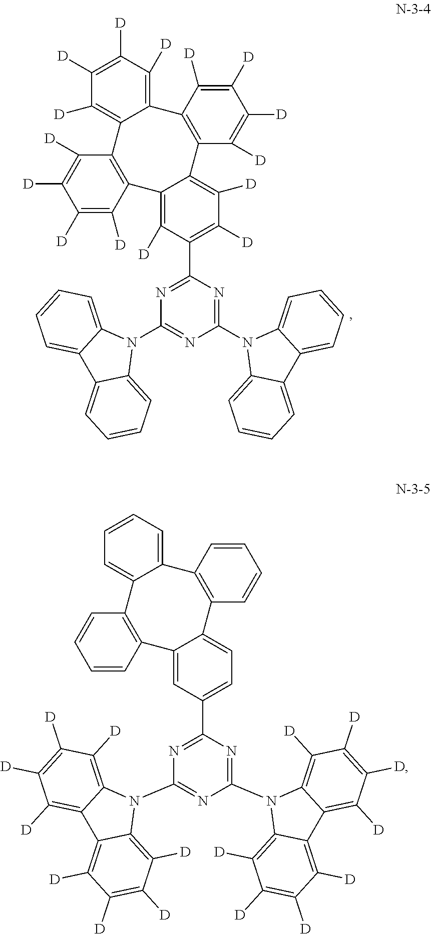 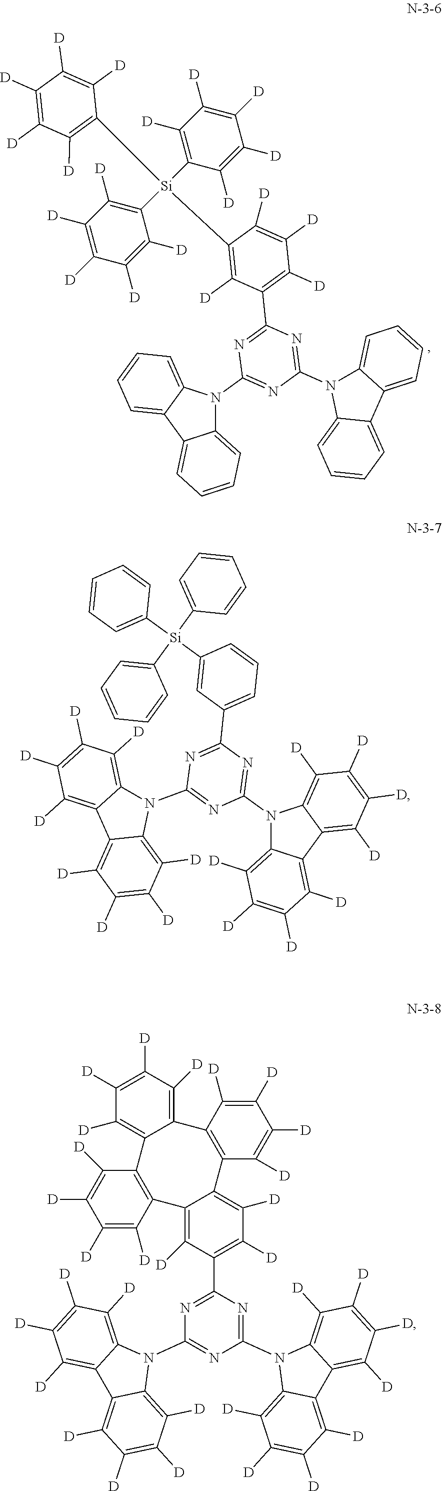 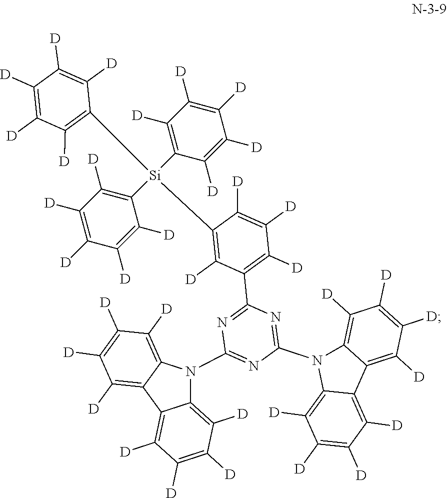
wherein optionally, hydrogens in the structures of Compound N-1-1 to Compound N-1-53, Compound N-1-58, Compound N-2-1 to Compound N-2-32 and Compound N-3-1 to Compound N-3-7 can be partially or fully substituted with deuterium.

16. The organic electroluminescent device according to claim 1, wherein the second host compound has a structure represented by Formula 8: 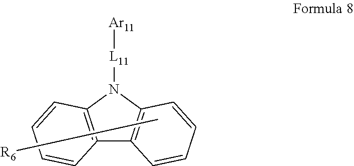
wherein in Formula 8,
L₁₁ is selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R₆ can be optionally joined to form a ring;
preferably, the second host compound has a structure represented by Formula 8-1 or Formula 8-2: 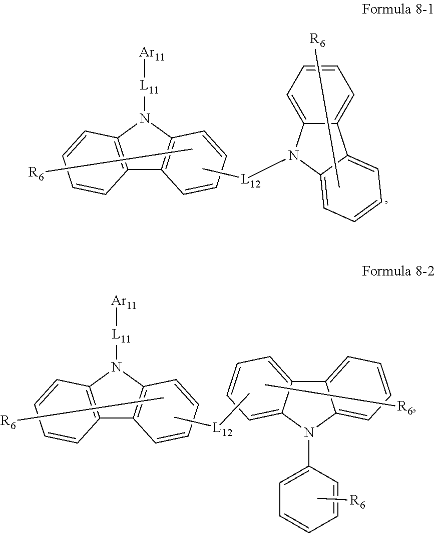
wherein L₁₁ and L₁₂ are selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R₆ can be optionally joined to form a ring;
more preferably, the second host compound is selected from the group consisting of Compound P-1 to Compound P-39: 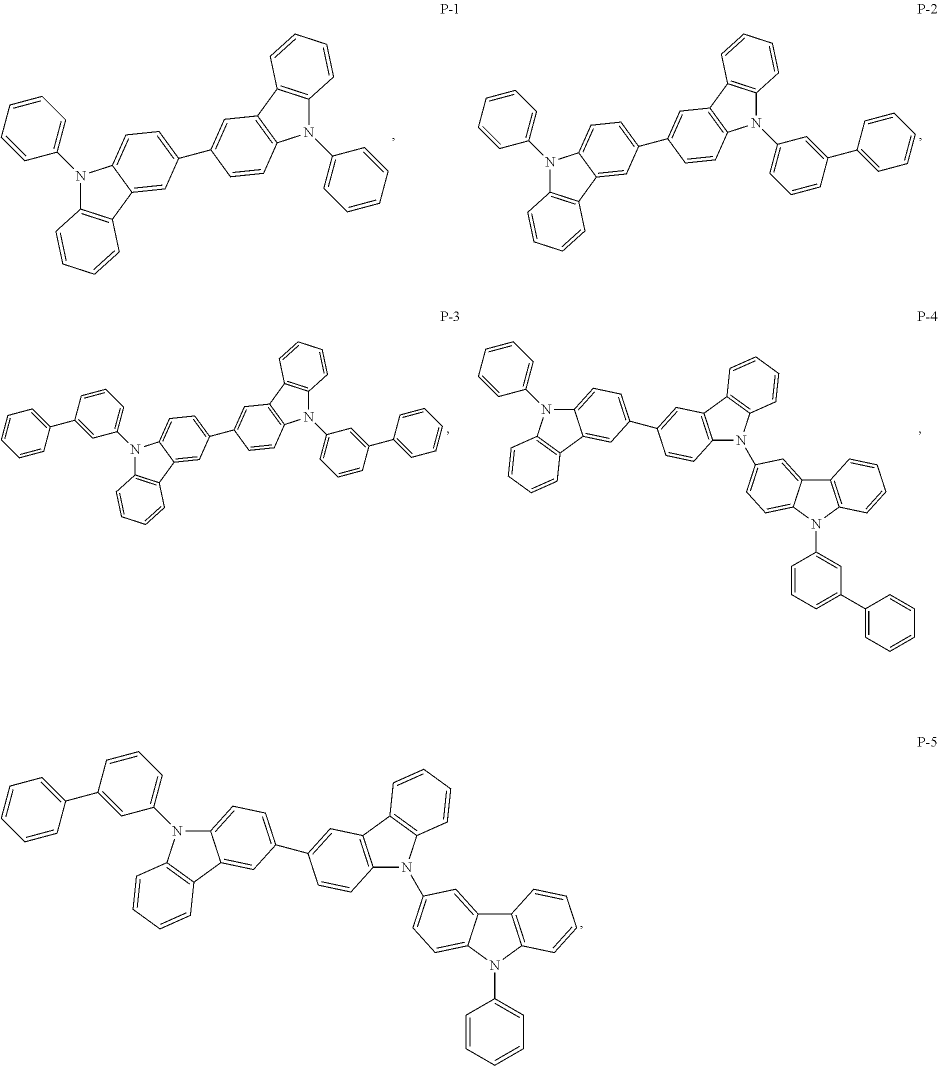 [SMILES: c1ccc(-n2c3ccccc3c3cc(-c4ccc5c(c4)c4ccccc4n5-c4ccccc4)ccc32)cc1 ; c1ccc(-c2cccc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-n5c6ccccc6c6cc(-c7ccc8c(c7)c7ccccc7n8-c7ccccc7)ccc65)ccc43)c2)cc1 ; c1ccc(-c2cccc(-n3c4ccccc4c4cc(-c5ccc6c(c5)c5ccccc5n6-c5ccc6c(c5)c5ccccc5n6-c5ccccc5)ccc43)c2)cc1] 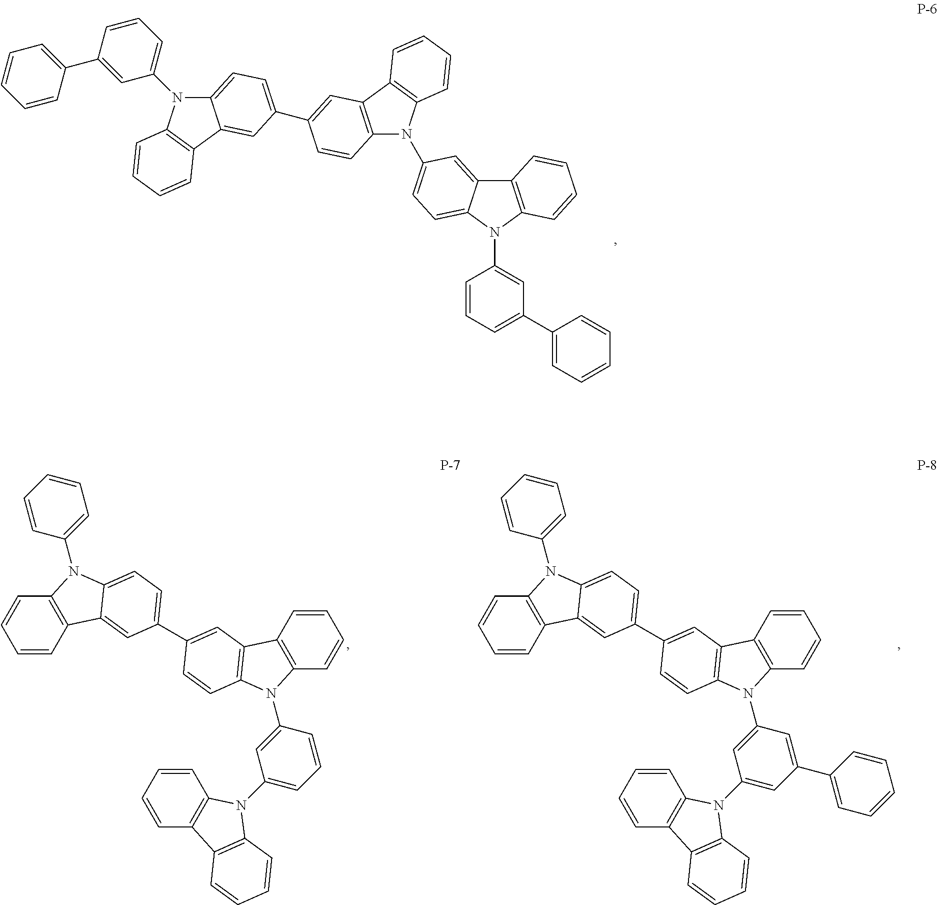 [SMILES: c1ccc(-c2cccc(-n3c4ccccc4c4cc(-c5ccc6c(c5)c5ccccc5n6-c5ccc6c(c5)c5ccccc5n6-c5cccc(-c6ccccc6)c5)ccc43)c2)cc1 ; c1ccc(-n2c3ccccc3c3cc(-c4ccc5c(c4)c4ccccc4n5-c4cccc(-n5c6ccccc6c6ccccc65)c4)ccc32)cc1 ; c1ccc(-c2cc(-n3c4ccccc4c4ccccc43)cc(-n3c4ccccc4c4cc(-c5ccc6c(c5)c5ccccc5n6-c5ccccc5)ccc43)c2)cc1] 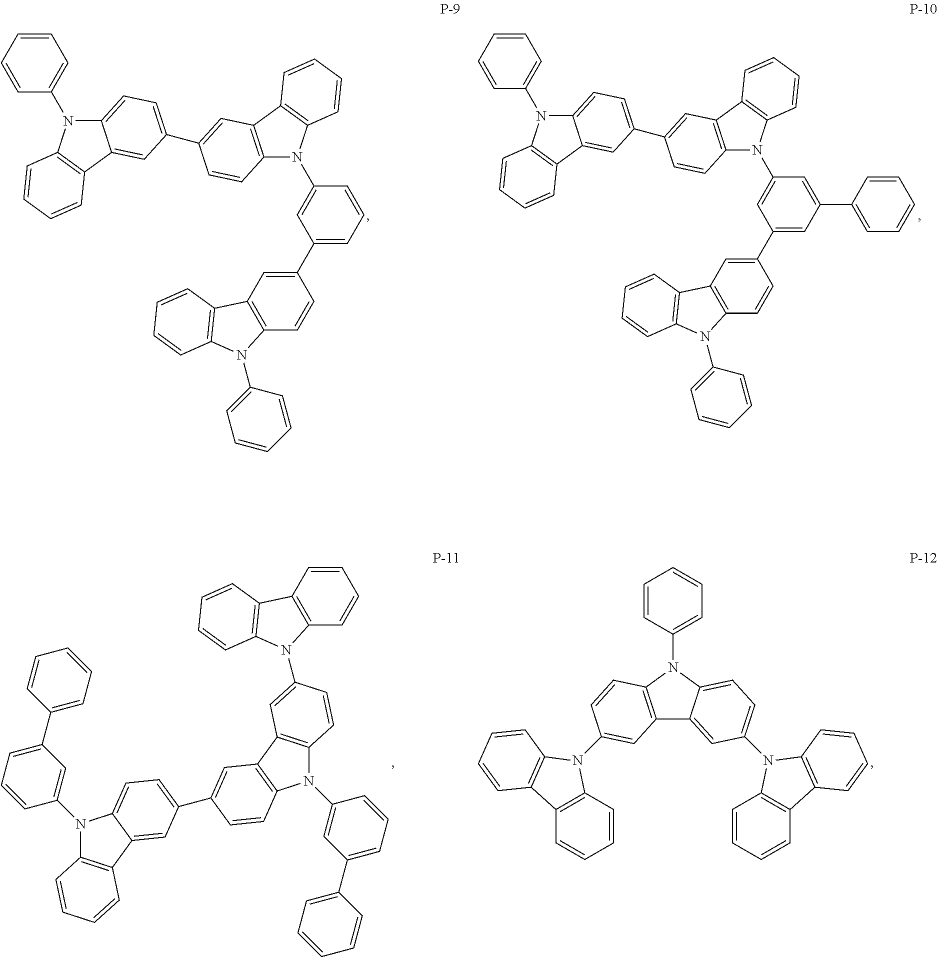 [SMILES: c1ccc(-n2c3ccccc3c3cc(-c4cccc(-n5c6ccccc6c6cc(-c7ccc8c(c7)c7ccccc7n8-c7ccccc7)ccc65)c4)ccc32)cc1 ; c1ccc(-c2cc(-c3ccc4c(c3)c3ccccc3n4-c3ccccc3)cc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-c5ccc6c(c5)c5cc(-n7c8ccccc8c8ccccc87)ccc5n6-c5cccc(-c6ccccc6)c5)ccc43)c2)cc1 ; c1ccc(-n2c3ccc(-n4c5ccccc5c5ccccc54)cc3c3cc(-n4c5ccccc5c5ccccc54)ccc32)cc1] 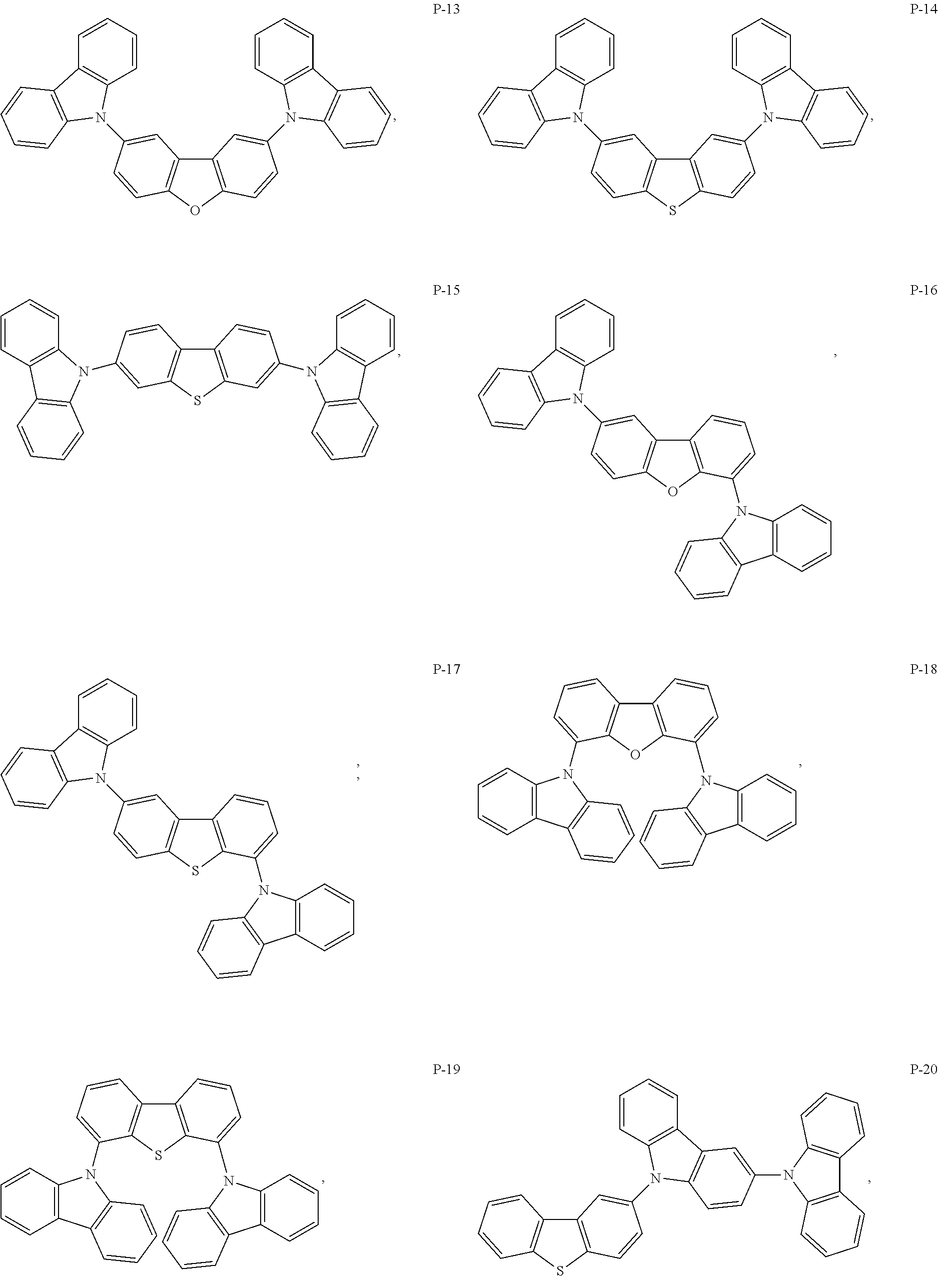 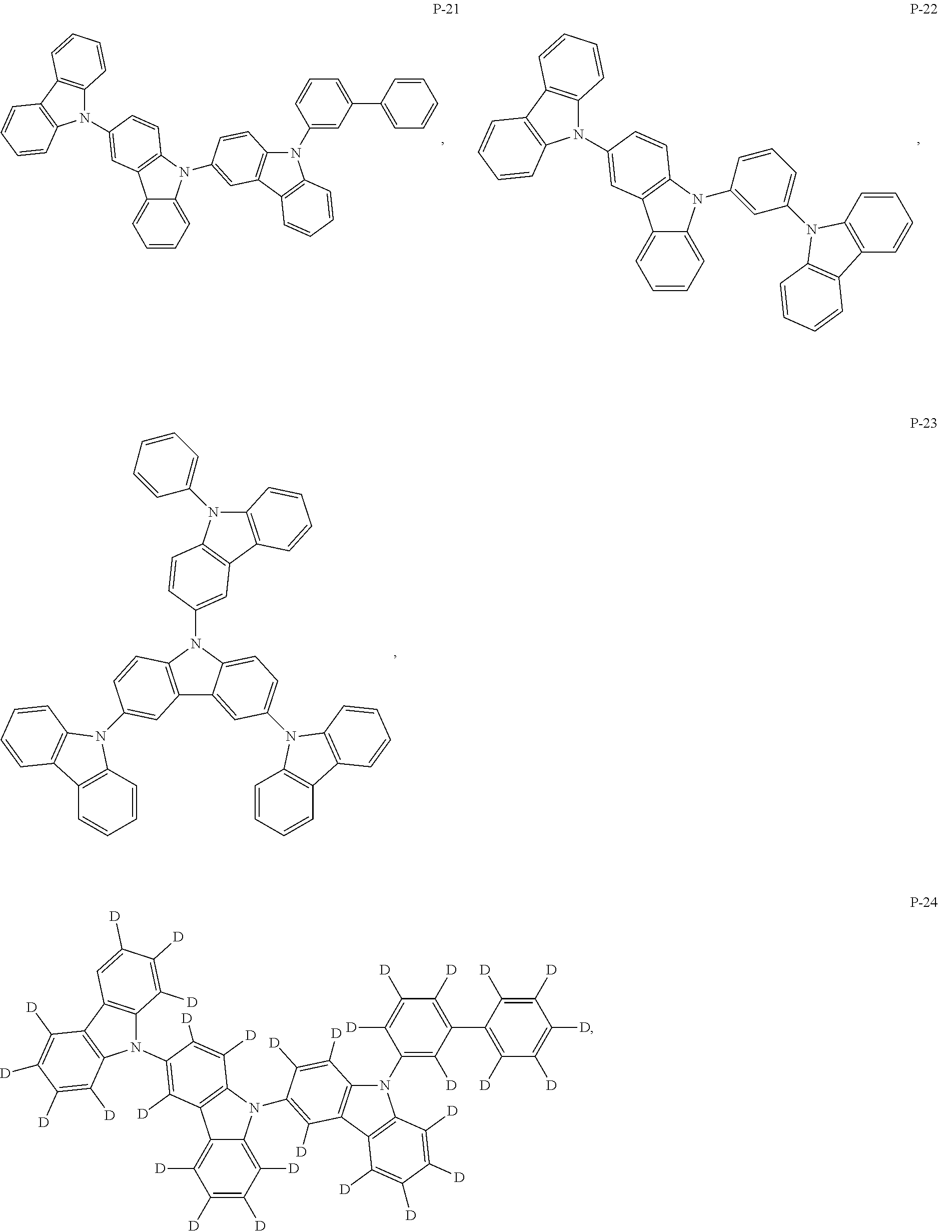 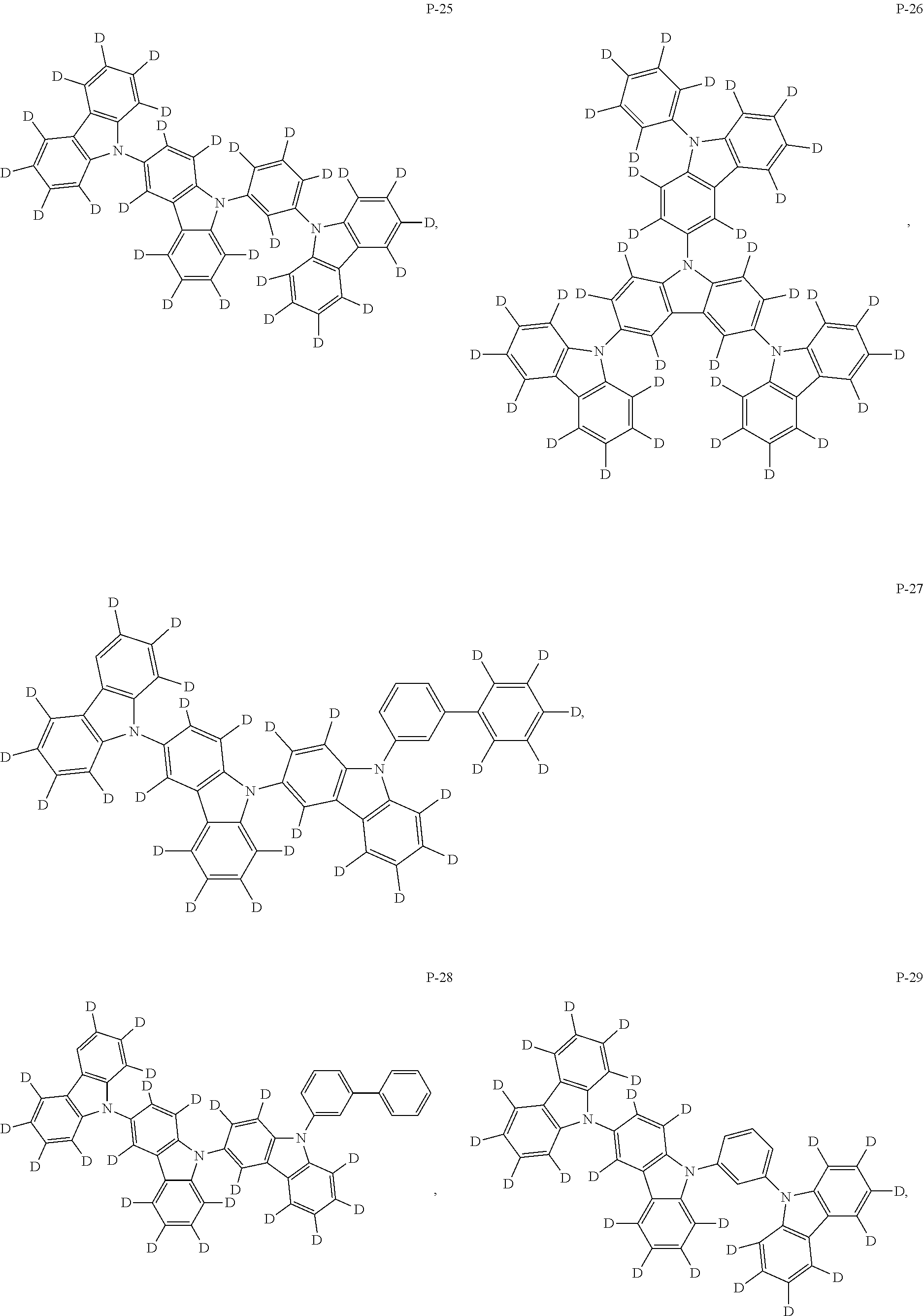 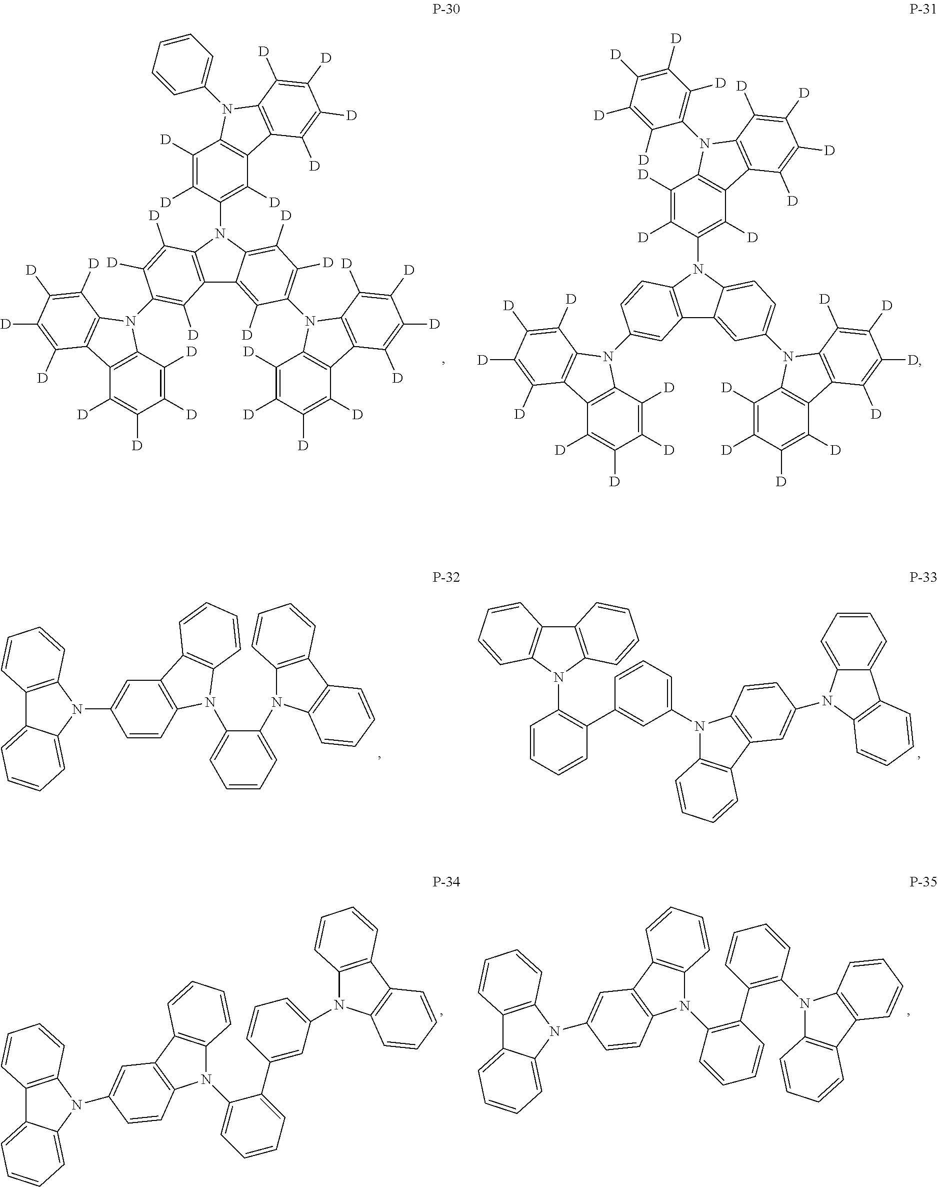 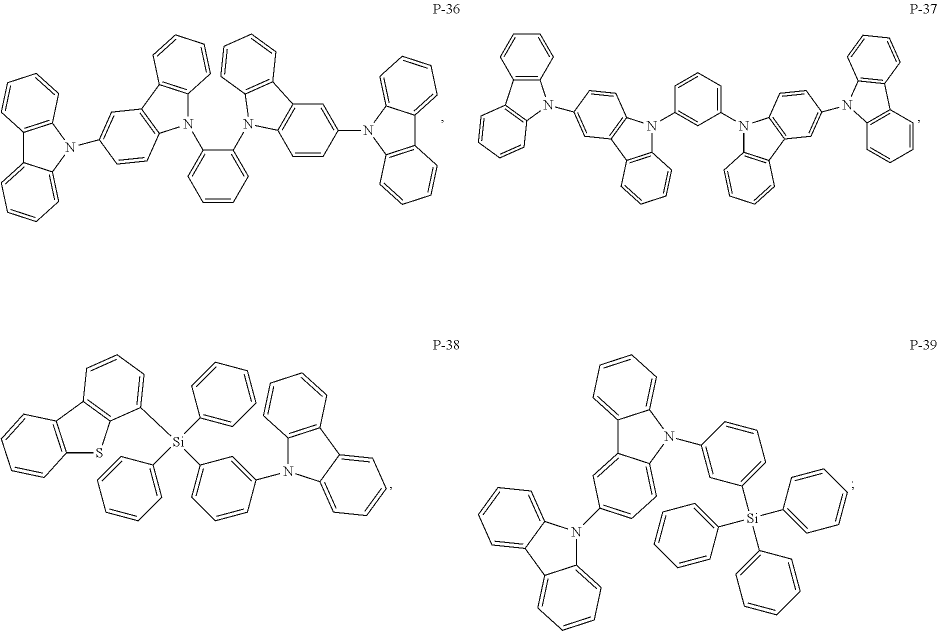 [SMILES: c1ccc(-n2c3ccccc3c3cc(-n4c5ccccc5c5ccccc54)ccc32)c(-n2c3ccccc3c3cc(-n4c5ccccc5c5ccccc54)ccc32)c1 ; c1cc(-n2c3ccccc3c3cc(-n4c5ccccc5c5ccccc54)ccc32)cc(-n2c3ccccc3c3cc(-n4c5ccccc5c5ccccc54)ccc32)c1 ; c1ccc([Si](c2ccccc2)(c2cccc(-n3c4ccccc4c4ccccc43)c2)c2cccc3c2sc2ccccc23)cc1 ; c1ccc([Si](c2ccccc2)(c2ccccc2)c2cccc(-n3c4ccccc4c4cc(-n5c6ccccc6c6ccccc65)ccc43)c2)cc1]
wherein optionally, hydrogens in the structures of Compound P-1 to Compound P-23 and Compound P-27 to Compound P-39 can be partially or fully substituted with deuterium.

17. The organic electroluminescent device according to claim 1, wherein the first host compound and the second host compound are host materials, the platinum metal complex is a phosphorescence sensitizer, and the thermally activated delayed fluorescence compound is a light-emitting material.

18. The organic electroluminescent device according to claim 1, wherein a weight of the first host compound and the second host compound accounts for 65% to 98.9% of a total weight of a material of the light-emitting layer, a weight of the platinum metal complex accounts for 1% to 30% of the total weight of the material of the light-emitting layer, and a weight of the thermally activated delayed fluorescence compound accounts for 0.1% to 5% of the total weight of the material of the light-emitting layer;
preferably, the weight of the first host compound and the second host compound accounts for 82% to 94.5% of the total weight of the material of the light-emitting layer, the weight of the platinum metal complex accounts for 5% to 15% of the total weight of the material of the light-emitting layer, and the weight of the thermally activated delayed fluorescence compound accounts for 0.5% to 3% of the total weight of the material of the light-emitting layer; and
more preferably, the weight of the first host compound and the second host compound accounts for 86.5% to 91.5% of the total weight of the material of the light-emitting layer, the weight of the platinum metal complex accounts for 8% to 12% of the total weight of the material of the light-emitting layer, and the weight of the thermally activated delayed fluorescence compound accounts for 0.5% to 1.5% of the total weight of the material of the light-emitting layer.

19. The organic electroluminescent device according to claim 1, wherein the first organic layer is a hole injection layer or a hole transport layer.

20. The organic electroluminescent device according to claim 1, wherein the polymer is a polymer with hole transport performance, and preferably, the polymer comprises a triarylamine structure.

21. A display device, comprising the organic electroluminescent device according to claim 1.

22. An organic light-emitting ink, comprising a solvent, a first host compound, a second host compound, a platinum metal complex and a thermally activated delayed fluorescence compound;
wherein the thermally activated delayed fluorescence compound has a structure represented by Formula 1: 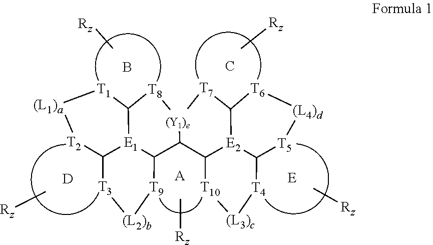
wherein,
the ring A, the ring B, the ring C, the ring D and the ring E are each independently selected from an unsaturated carbocyclic ring having 5 to 30 carbon atoms or an unsaturated heterocyclic ring having 3 to 30 carbon atoms;
Y₁, E₁ and E₂ are each independently selected from B, N, P, P═O, P═S, As, As═O, As═S, SiR′ or GeR′;
T₁ to T₈ are each independently selected from C, CR_{z} or N;
T₉ and T₁₀ are each independently selected from C, CR_{z}, CR; or N;
L₁, L₂, L₃ and L₄ are, at each occurrence identically or differently, selected from a single bond, O, S, Se, BRᵥ or NRᵥ;
a, b, c, d and e are each independently selected from 0 or 1;
when e is 1, b is 0 and c is 0, T₉ and T₁₀ are each independently selected from CRₜ or N;
R_{z} represents, at each occurrence identically or differently, mono-substitution, multiple substitutions or non-substitution;
Rₜ is, at each occurrence identically or differently, selected from a small-steric-hindrance group;
Rᵥ, R_{z} and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″ and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₜ, Rᵥ, R_{z}, R′ and R″ can be optionally joined to form a ring.
